(19) United States
(12) Patent Application Publication
(10) Pub. No.: US 2024/0244887 A1
(43) Pub. Date: Jul. 18, 2024

(54) Method For Manufacturing Display Device, Display Device, Display Module, and Electronic Device

(71) Applicant: Semiconductor Energy Laboratory Co., Ltd., Kanagawa-ken (JP)

(72) Inventors: Yasutaka NAKAZAWA, Tochigi (JP); Naoto GOTO, Tochigi (JP); Kenichi OKAZAKI, Atsugi (JP); Takayuki OHIDE, Isehara (JP)

(73) Assignee: Semiconductor Energy Laboratory Co., Ltd., Kanagawa-ken (JP)

(21) Appl. No.: 18/390,937

(22) Filed: Dec. 20, 2023

(30) Foreign Application Priority Data
Dec. 26, 2022 (JP) 2022-208115

(51) Int. Cl. H10K 59/122; H10K 59/12; H10K 59/80

(52) U.S. Cl. CPC H10K 59/122; H10K 59/1201; H10K 59/80515

(57) ABSTRACT

A method for manufacturing a novel display device that is highly convenient, useful, or reliable is to be provided. A first film is formed over a first electrode and a second electrode in a second step in the manufacturing method; a second film is formed over the first film in a third step; a third film is formed over the second film by a CVD method in a fourth step; part of the third film located above the second electrode is removed by an etching method to form a first layer overlapping with the first electrode in a fifth step; and part of the second film and part of the first film each located above the second electrode are removed by an etching method using the first layer to form a second layer and a first unit each overlapping with the first electrode in a sixth step.

### BACKGROUND OF THE INVENTION

### 1. Field of the Invention

One embodiment of the present invention relates to a method for manufacturing a display device, a display device, a display module, an electronic device, or a semiconductor device.

Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specific examples of the technical field of one embodiment of the present invention disclosed in this specification include a semiconductor device, a display device, a light-emitting apparatus, a power storage device, a memory device, a method for driving any of them, and a method for manufacturing any of them.

### 2. Description of the Related Art

In recent years, higher resolution has been required for display panels. Examples of devices that require high-resolution display panels include a smartphone, a tablet terminal, and a laptop computer. Furthermore, higher resolution has been required for a stationary display device such as a television device or a monitor device along with a higher definition. A device absolutely required to have the highest resolution display panel is a device for virtual reality (VR) or augmented reality (AR).

Examples of the display device that can be used for a display panel include, typically, a liquid crystal display device, a light-emitting device including a light-emitting element such as an organic electroluminescent (EL) element or a light-emitting diode (LED), and electronic paper performing display by an electrophoretic method or the like.

An organic EL element generally has a structure in which, for example, a layer containing a light-emitting organic compound is provided between a pair of electrodes. By voltage application to this element, the light-emitting organic compound can emit light. A display device including such an organic EL element needs no backlight which is necessary for a liquid crystal display device and the like and thus can have advantages such as thinness, lightweight, high contrast, and low power consumption. Patent Document 1, for example, discloses an example of a display device using an organic EL element.

Patent Document 2 discloses a display device using an organic EL device for VR.

As an organic thin film with an excellent electron-injection property and electron-transport property when used as an electron-injection layer of an organic EL element, for example, a single film containing a hexahydropyrimidopyrimidine compound and a second material transporting an electron, and a stacked film of a film containing a hexahydropyrimidopyrimidine compound and a film containing the second material are known (Patent Document 3).

### REFERENCE

[Patent Document 1] Japanese Published Patent Application No. 2002-324673
[Patent Document 2] International Publication No. WO2018/087625
[Patent Document 3] PCT International Publication No. WO2021/045178

### SUMMARY OF THE INVENTION

An object of one embodiment of the present invention is to provide a method for manufacturing a novel display device that is highly convenient, useful, or reliable. Another object is to provide a novel display device that is highly convenient, useful, or reliable. Another object is to provide a novel display module that is highly convenient, useful, or reliable. Another object is to provide a novel electronic device that is highly convenient, useful, or reliable. Another object is to provide a method for manufacturing a novel display device, a novel display module, a novel electronic device, or a novel semiconductor device.

Note that the description of these objects does not preclude the existence of other objects. One embodiment of the present invention does not need to achieve all these objects. Other objects will be apparent from and can be derived from the description of the specification, the drawings, the claims, and the like.

(1) One embodiment of the present invention is a method for manufacturing a display device including first to seventeenth steps.

In the first step, a first electrode, a second electrode, and a first gap between the first electrode and the second electrode are formed over an insulating film.

In the second step, a first film is formed over the first electrode and the second electrode.

In the third step, a second film is formed over the first film.

In the fourth step, a third film is formed over the second film by a CVD method.

In the fifth step, a part of the third film over the second electrode is removed by an etching method to form a first layer overlapping with the first electrode.

In the sixth step, a part of the second film and a part of the first film each over the second electrode are removed by an etching method using the first layer to form a second layer and a first unit each overlapping with the first electrode.

In the seventh step, a fourth film is formed over the first layer and the second electrode.

In the eighth step, a fifth film is formed over the fourth film.

In the ninth step, a sixth film is formed over the fifth film.

In the tenth step, a part of the sixth film over the first layer is removed by an etching method to form a third layer overlapping with the second electrode.

In the eleventh step, a part of the fifth film and a part of the fourth film each over the first layer and the first gap are removed by an etching method using the third layer to form a fourth layer and a second unit each overlapping with the second electrode and a second gap overlapping with the first gap.

In the twelfth step, a fifth layer that is in contact with the insulating film in the first gap and covers the first unit and the second unit is formed.

In the thirteenth step, a sixth layer is formed. The sixth layer fills the first gap and the second gap and has a first opening portion overlapping with the first electrode and a second opening portion overlapping with the second electrode.

In the fourteenth step, the fifth layer and the first layer each in a portion overlapping with the first opening portion and the fifth layer and the third layer each in a portion overlapping with the second opening portion are removed by an etching method using the sixth layer.

In the fifteenth step, the second layer in a portion overlapping with the first opening portion and the fourth layer in a portion overlapping with the second opening portion are removed by an etching method using the sixth layer.

In the sixteenth step, a seventh layer is formed over the first unit and the second unit.

In the seventeenth step, a conductive film is formed over the seventh layer.

Thus, the throughput can be improved as compared with a case where the third film is formed by an ALD method, for example. In addition, a manufacturing apparatus can be increased in size as compared with the case where the third film is formed by an ALD method, for example. In addition, a substrate used for a workpiece can be increased in size as compared with the case where the third film is formed by an ALD method, for example. In addition, the productivity can be increased as compared with the case where the third film is formed by an ALD method, for example. Moreover, the second gap can be formed between the first unit and the second unit. Occurrence of a phenomenon in which one of light-emitting devices adjacent to each other in the display device emits light with unintended luminance in accordance with light emission of the other of the light-emitting devices can be suppressed. The light-emitting devices adjacent to each other in the display device can be individually driven. Occurrence of a cross talk phenomenon between light-emitting devices can be suppressed. The resolution of the display device can be increased. The aperture ratio of a pixel of the display device can be increased. As a result, a method for manufacturing a novel display device that is highly convenient, useful, or reliable can be provided.

(2) Another embodiment of the present invention is the method for manufacturing a display device, in which the second to fourth steps are performed in treatment chambers which are connected to each other with a transfer chamber in which a pressure is reduced.

With this method, the amount of impurities entering the light-emitting device during the manufacturing steps from a clean room or the like can be reduced. For example, the amount of oxygen, water, boron, or the like entering an interface of deposited layers from the clean room or the like and accumulated can be reduced. Moreover, a phenomenon of lowering the reliability due to impurities can be prevented. As a result, a method for manufacturing a novel display device that is highly convenient, useful, or reliable can be provided.

(3) Another embodiment of the present invention is the method for manufacturing a display device, in which the fifth layer that is in contact with the insulating film in the first gap and covers the first unit and the second unit is formed by a CVD method in the twelfth step.

With this method, the throughput can be improved as compared with a case where the third film and the fifth layer are formed by an ALD method, for example. In addition, a manufacturing apparatus can be increased in size as compared with the case where the third film and the fifth layer are formed by an ALD method, for example. In addition, a substrate used for a workpiece can be increased in size as compared with the case where the third film and the fifth layer are formed by an ALD method, for example. In addition, the productivity can be increased as compared with the case where the third film and the fifth layer are formed by an ALD method, for example. As a result, a method for manufacturing a novel display device that is highly convenient, useful, or reliable can be provided.

(4) Another embodiment of the present invention is the method for manufacturing a display device, in which the fifth layer and the first layer each in a portion overlapping with the first opening portion and the fifth layer and the third layer each in a portion overlapping with the second opening portion are removed by a wet etching method using the sixth layer in the fourteenth step, and an eighteenth step is included between the fourteenth step and the fifteenth step. In the eighteenth step, the sixth layer is made to have fluidity so as to be in contact with the second layer.

With this method, a step difference between the sixth layer and the second layer can be made small. In addition, a step difference between the sixth layer and the first unit can be made small. The step can be made close to a flat surface. A phenomenon in which a cut or a split is generated due to the step difference in the conductive film can be prevented. As a result, a method for manufacturing a novel display device that is highly convenient, useful, or reliable can be provided.

(5) Another embodiment of the present invention is a display device including a first light-emitting device, a second light-emitting device, a first layer, a second layer, and a fifth layer.

The first light-emitting device includes a first electrode, a fourth electrode, and a first unit. The first unit is positioned between the first electrode and the fourth electrode and contains a first light-emitting material.

The second light-emitting device includes a second electrode, a fifth electrode, and a second unit. The second electrode is adjacent to the first electrode. The second electrode and the first electrode are configured to have a first gap therebetween. The second unit is positioned between the second electrode and the fifth electrode and contains a second light-emitting material. The second unit and the first unit are configured to have a second gap therebetween, and the second gap overlaps with the first gap.

The fifth layer overlaps with the first gap and has an opening portion overlapping with the first electrode.

The first layer is positioned between the fifth layer and the first unit, and the second layer is positioned between the first layer and the first unit.

The distribution of boron ranging from a central plane of the fifth layer to a central plane of the first layer has a first concentration profile.

The distribution of boron ranging from the central plane of the first layer to a central plane of the second layer has a second concentration profile. The second concentration profile has a peak lower than a peak in the first concentration profile.

With this structure, the amount of impurities entering the light-emitting device during the manufacturing steps from a clean room or the like can be reduced. For example, the amount of oxygen, water, boron, or the like entering an interface of deposited layers from the clean room or the like and accumulated can be reduced. Moreover, a phenomenon of lowering the reliability due to impurities can be prevented. As a result, a novel display device that is highly convenient, useful, or reliable can be provided.

(6) Another embodiment of the present invention is the display device including a sixth layer.

The sixth layer fills the first gap and the second gap and has a first opening portion and a second opening portion.

The first opening portion overlaps with the first electrode, and the second opening portion overlaps with the second electrode.

The sixth layer is in contact with the second layer.

With this structure, a step difference between the sixth layer and the second layer can be made small. In addition, a step difference between the sixth layer and the first unit can be made small. The step can be made close to a flat surface. A phenomenon in which a cut or a split is generated due to the step difference in the conductive film can be prevented. As a result, a novel display device that is highly convenient, useful, or reliable can be provided.

(7) Another embodiment of the present invention is a display module including the display device and at least one of a connector and an integrated circuit.

(8) Another embodiment of the present invention is an electronic device including the display device and at least one of a battery, a camera, a speaker, and a microphone.

Although the block diagram in drawings attached to this specification shows components classified based on their functions in independent blocks, it is difficult to classify actual components based on their functions completely, and one component can have a plurality of functions.

Note that the light-emitting apparatus in this specification includes, in its category, an image display device that uses a light-emitting device. The light-emitting apparatus may also include, in its category, a module in which a light-emitting device is provided with a connector such as an anisotropic conductive film or a tape carrier package (TCP), a module in which a printed wiring board is provided at the end of a TCP, and a module in which an integrated circuit (IC) is directly mounted on a light-emitting device by a chip on glass (COG) method. Furthermore, a lighting device or the like may include the light-emitting apparatus.

One embodiment of the present invention can provide a method for manufacturing a novel display device that is highly convenient, useful, or reliable. Another embodiment of the present invention can provide a novel display device that is highly convenient, useful, or reliable. Another embodiment of the present invention can provide a novel display module that is highly convenient, useful, or reliable. Another embodiment of the present invention can provide a novel electronic device that is highly convenient, useful, or reliable. A method for manufacturing a novel display device can be provided. A novel display device can be provided. A novel display module can be provided. A novel electronic device can be provided.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

FIGS. 1A to 1D illustrate structures of a display device of an embodiment.

FIG. 2 illustrates a structure of a display device of an embodiment.

FIGS. 3A to 3C illustrate a structure of a display device of an embodiment.

FIG. 4 illustrates a method for manufacturing a display device of an embodiment.

FIG. 5 illustrates a method for manufacturing a display device of an embodiment.

FIG. 6 illustrates a method for manufacturing a display device of an embodiment.

FIGS. 7A and 7B each illustrate a method for manufacturing a display device of an embodiment.

FIG. 8 illustrates a method for manufacturing a display device of an embodiment.

FIG. 9 illustrates a method for manufacturing a display device of an embodiment.

FIG. 10 illustrates a method for manufacturing a display device of an embodiment.

FIG. 11 illustrates a method for manufacturing a display device of an embodiment.

FIG. 12 illustrates a method for manufacturing a display device of an embodiment.

FIG. 13 illustrates a method for manufacturing a display device of an embodiment.

FIG. 14 illustrates a method for manufacturing a display device of an embodiment.

FIG. 15 illustrates a method for manufacturing a display device of an embodiment.

FIG. 16 illustrates a method for manufacturing a display device of an embodiment.

FIG. 17 illustrates a method for manufacturing a display device of an embodiment.

FIG. 18 illustrates a method for manufacturing a display device of an embodiment.

FIG. 19 illustrates a method for manufacturing a display device of an embodiment.

FIG. 20 illustrates a method for manufacturing a display device of an embodiment.

FIG. 21 illustrates a method for manufacturing a display device of an embodiment.

FIG. 22 illustrates a method for manufacturing a display device of an embodiment.

FIG. 23 illustrates a method for manufacturing a display device of an embodiment.

FIG. 24 illustrates a method for manufacturing a display device of an embodiment.

FIG. 25 illustrates a method for manufacturing a display device of an embodiment.

FIGS. 26A to 26D illustrate a method for manufacturing a display device of an embodiment.

FIG. 27 illustrates a structure of a light-emitting device of an embodiment.

FIGS. 28A and 28B each illustrate a structure of a light-emitting device of an embodiment.

FIGS. 29A to 29C illustrate a structure of a display device of an embodiment.

FIG. 30 illustrates a structure of a display device of an embodiment.

FIG. 31 illustrates a structure of a display module of an embodiment.

FIGS. 32A and 32B illustrate a structure of a display device of an embodiment.

FIG. 33 illustrates a structure of a display device of an embodiment.

FIG. 34 illustrates a structure of a display device of an embodiment.

FIG. 35 illustrates a structure of a display device of an embodiment.

FIG. 36 illustrates a structure of a display device of an embodiment.

FIG. 37 illustrates a structure of a display device of an embodiment.

FIG. 38 illustrates a structure of a display module of an embodiment.

FIGS. 39A to 39C illustrate a structure of a display device of an embodiment.

FIG. 40 illustrates a structure of a display device of an embodiment.

FIG. 41 illustrates a structure of a display device of an embodiment.

FIG. 42 illustrates a structure of a display device of an embodiment.

FIG. 43 illustrates a structure of a display device of an embodiment.

FIG. 44 illustrates a structure of a display device of an embodiment.

FIGS. 45A to 45D illustrate examples of electronic devices of an embodiment.

FIGS. 46A to 46F illustrate examples of electronic devices of an embodiment.

FIGS. 47A to 47G illustrate examples of electronic devices of an embodiment.

FIGS. 48A to 48C illustrate a structure of a workpiece of an example.

FIGS. 49A to 49D each illustrate a structure of a light-emitting device of an example.

FIG. 50 shows current density-luminance characteristics of light-emitting devices of an example.

FIG. 51 shows luminance-current efficiency characteristics of light-emitting devices of an example.

FIG. 52 shows voltage-luminance characteristics of light-emitting devices of an example.

FIG. 53 shows voltage-current density characteristics of light-emitting devices of an example.

FIG. 54 shows luminance-blue index characteristics of light-emitting devices of an example.

FIG. 55 shows emission spectra of light-emitting devices of an example.

FIGS. 56A to 56E illustrate structures of samples of an example.

FIG. 57 shows liquid chromatography-mass spectrometry results of samples.

FIG. 58 shows liquid chromatography-mass spectrometry results of samples.

FIG. 59 shows liquid chromatography-mass spectrometry results of samples.

FIGS. 60A to 60C illustrate a structure of a workpiece of an example.

FIG. 61 illustrates a structure of a light-emitting device of an example.

FIG. 62 illustrates a method for fabricating a workpiece of an example.

FIG. 63 illustrates a method for fabricating a workpiece of an example.

FIG. 64 illustrates a method for fabricating a workpiece of an example.

FIG. 65 illustrates a method for fabricating a workpiece of an example.

FIG. 66 illustrates a method for fabricating a workpiece of an example.

FIG. 67 illustrates a method for fabricating a workpiece of an example.

FIG. 68 illustrates a method for fabricating a workpiece of an example.

FIG. 69 illustrates a method for fabricating a workpiece of an example.

FIG. 70 illustrates a method for fabricating a workpiece of an example.

FIG. 71 is an optical micrograph showing a light-emitting state of a workpiece of an example.

FIGS. 72A and 72B are each an optical micrograph showing a light-emitting state of a workpiece of an example.

FIG. 73 is a scanning transmission electron microscope image showing a structure of a workpiece of an example.

FIG. 74 shows current density-luminance characteristics of light-emitting devices of an example.

FIG. 75 shows luminance-current efficiency characteristics of light-emitting devices of an example.

FIG. 76 shows voltage-luminance characteristics of light-emitting devices of an example.

FIG. 77 shows voltage-current density characteristics of light-emitting devices of an example.

FIG. 78 shows emission spectra of light-emitting devices of an example.

FIG. 79 is a photograph showing a display state of a display device of an example.

### DETAILED DESCRIPTION OF THE INVENTION

A method for manufacturing a display device of one embodiment of the present invention includes first to seventeenth steps. In the first step, a first electrode, a second electrode, and a first gap between the first electrode and the second electrode are formed over an insulating film; in the second step, a first film is formed over the first electrode and the second electrode; in the third step, a second film is formed over the first film; in the fourth step, a third film is formed over the second film by a CVD method; in the fifth step, a part of the third film over the second electrode is removed to form a first layer overlapping with the first electrode; and in the sixth step, a part of the second film and a part of the first film each over the second electrode are removed by an etching method using the first layer to form a second layer and a first unit each overlapping with the first electrode. In the seventh step, a fourth film is formed over the first layer and the second electrode; in the eighth step, a fifth film is formed over the fourth film; in the ninth step, a sixth film is formed over the fifth film; in the tenth step, a part of the sixth film over the first layer is removed by an etching method to form a third layer overlapping with the second electrode; and in the eleventh step, a part of the fifth film and a part of the fourth film each over the first layer and the first gap are removed by an etching method using the third layer to form a fourth layer and a second unit overlapping with the second electrode and a second gap overlapping with the first gap. In the twelfth step, a fifth layer that is in contact with the insulating film in the first gap and covers the first unit and the second unit is formed; and in the thirteenth step, a sixth layer that fills the first gap and the second gap and has a first opening portion overlapping with the first electrode and a second opening portion overlapping with the second electrode is formed. In the fourteenth step, the fifth layer and the first layer each in a portion overlapping with the first opening portion and the fifth layer and the third layer each in a portion overlapping with the second opening portion are removed by an etching method using the sixth layer; and in the fifteenth step, the second layer in a portion overlapping with the first opening portion and the fourth layer in a portion overlapping with the second opening portion are removed by an etching method using the sixth layer. In the sixteenth step, a seventh layer is formed over the first unit and the second unit; and in the seventeenth step, a conductive film is formed over the seventh layer.

Thus, the throughput can be improved as compared with a case where the third film is formed by an ALD method, for example. In addition, a manufacturing apparatus can be increased in size as compared with a case where the third film is formed by an ALD method, for example. In addition, a substrate used for a workpiece can be increased in size as compared with a case where the third film is formed by an ALD method, for example. In addition, the productivity can be increased as compared with a case where the third film is formed by an ALD method, for example. A second gap can be formed between the first unit and the second unit. Occurrence of a phenomenon in which one of light-emitting devices adjacent to each other in the display device emits light with unintended luminance in accordance with light emission of the other of the light-emitting devices can be suppressed. In addition, the light-emitting devices adjacent to each other in the display device can be individually driven. Occurrence of a cross talk phenomenon between light-emitting devices can be suppressed. The resolution of the display device can be increased. The aperture ratio of a pixel of the display device can be increased. As a result, a method for manufacturing a novel display device that is highly convenient, useful, or reliable can be provided. With this method, the amount of impurities entering the light-emitting device during the manufacturing steps from a clean room or the like can be reduced. For example, the amount of oxygen, water, boron, or the like entering an interface of the deposited layers from the clean room or the like and accumulated can be reduced. Moreover, a phenomenon of lowering the reliability due to impurities can be prevented. As a result, a method for manufacturing a novel display device that is highly convenient, useful, or reliable can be provided.

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments. Note that in structures of the invention described below, the same portions or portions having similar functions are denoted by the same reference numerals in different drawings, and the description thereof is not repeated.

### Embodiment 1

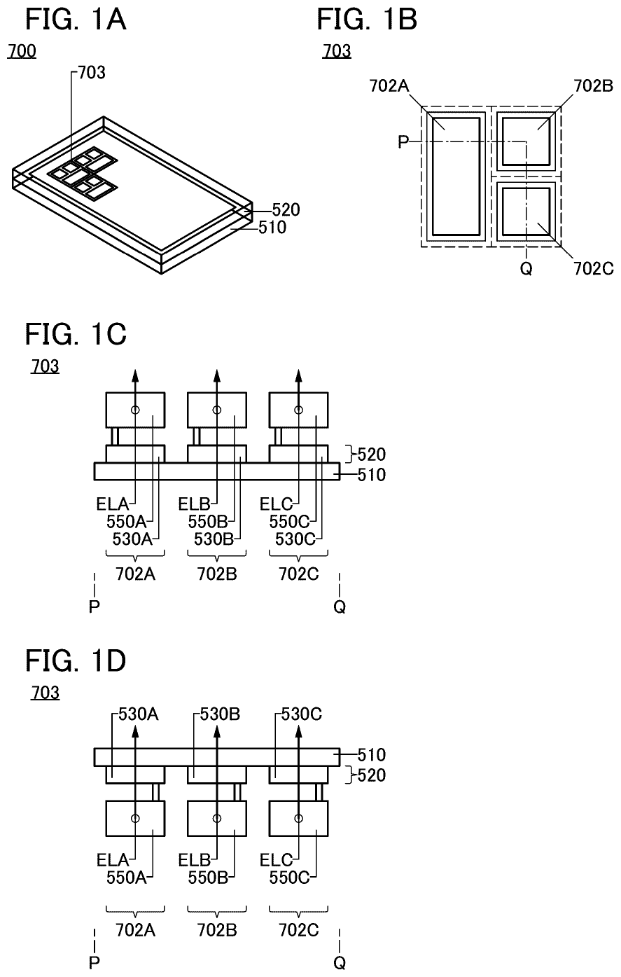

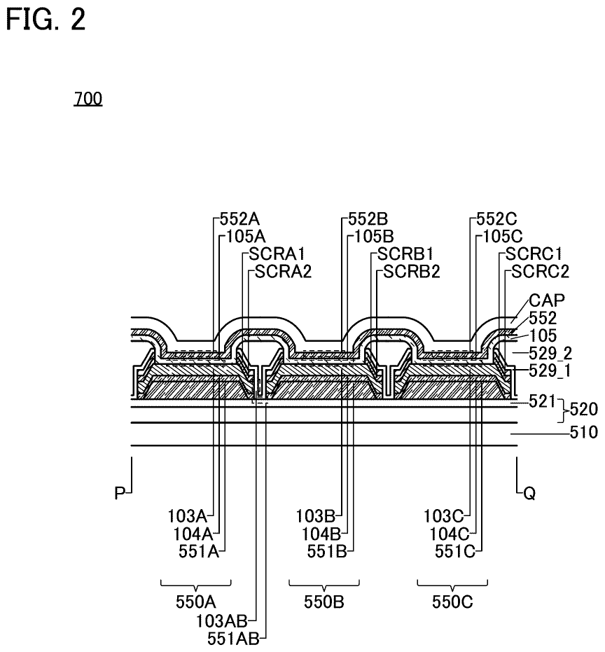

In this embodiment, a structure of a display device of one embodiment of the present invention will be described with reference to FIGS. 1A to 1D and FIG. 2.

FIG. 1A is a perspective view illustrating a structure of the display device of one embodiment of the present invention, and FIG. 1B is a top view illustrating part of FIG. 1A. FIG. 1C is a cross-sectional view taken along a cutting line P-Q in FIG. 1, and FIG. 1D is a cross-sectional view illustrating a structure different from that in FIG. 1C.

FIG. 2 is a cross-sectional view illustrating the structure of the display device of one embodiment of the present invention.

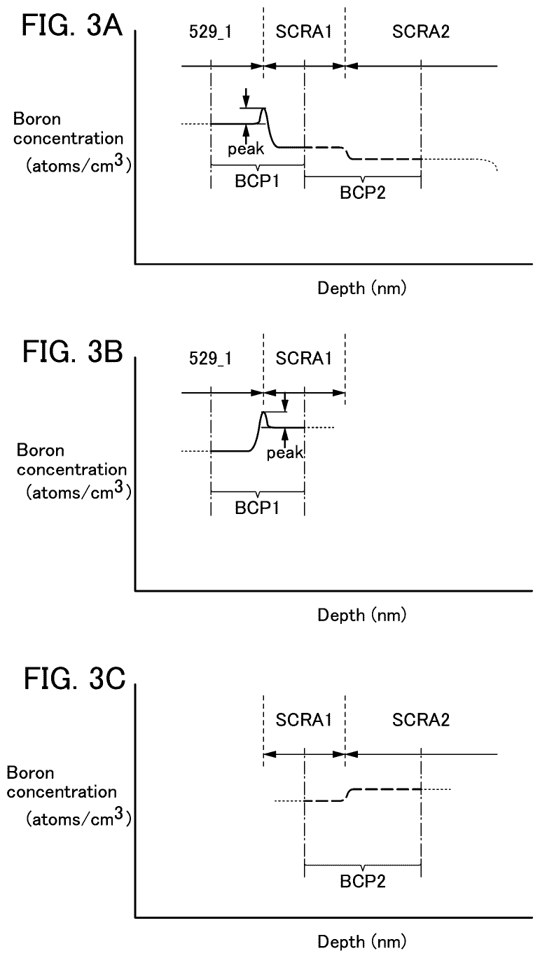

FIGS. 3A to 3C are schematic views showing the concentration of boron distributed in part of the display device of this embodiment.

### <Structure Example 1 of Display Device>

A display device 700 described in this embodiment includes a pixel set 703 (see FIG. 1A). The display device 700 includes a substrate 510 and a functional layer 520.

The pixel set 703 includes a pixel 702A, a pixel 702B, and a pixel 702C (see FIG. 1B).

The pixel 702A includes a light-emitting device 550A and a pixel circuit 530A. The light-emitting device 550A is electrically connected to the pixel circuit 530A (see FIGS. 1C and 1D).

The pixel 702B includes a light-emitting device 550B and a pixel circuit 530B. The light-emitting device 550B is electrically connected to the pixel circuit 530B.

The pixel 702C includes a light-emitting device 550C and a pixel circuit 530C. The light-emitting device 550C is electrically connected to the pixel circuit 530C.

Note that the functional layer 520 includes the pixel circuits 530A, 530B, and 530C. The pixel circuit 530A is positioned between the light-emitting device 550A and the substrate 510, the pixel circuit 530B is positioned between the light-emitting device 550B and the substrate 510, and the pixel circuit 530C is positioned between the light-emitting device 550C and the substrate 510.

In the display device 700 of one embodiment of the present invention, for example, the light-emitting device 550A emits light ELA in a direction where the pixel circuit 530A is not provided, the light-emitting device 550B emits light ELB in a direction where the pixel circuit 530B is not provided, and the light-emitting device 550C emits light ELC in a direction where the pixel circuit 530C is not provided (see FIG. 1C). In other words, the display device 700 of one embodiment of the present invention is a top-emission display device.

In the display device 700 of one embodiment of the present invention, for example, the light-emitting device 550A emits light ELA in a direction where the pixel circuit 530A is provided, the light-emitting device 550B emits light ELB in a direction where the pixel circuit 530B is provided, and the light-emitting device 550C emits light ELC in a direction where the pixel circuit 530C is provided (see FIG. 1D). In other words, the display device 700 of one embodiment of the present invention is a bottom-emission display device.

### <<Structure Example of Light-Emitting Device 550A>>

The light-emitting device 550A includes an electrode 551A, an electrode 552A, and a unit 103A (see FIG. 2). The light-emitting device 550A includes a layer 104A and a layer CAP. The layer 104A is positioned between the electrode 551A and the unit 103A.

The unit 103A is positioned between the electrode 551A and the electrode 552A and contains a light-emitting material EMA.

Note that a detailed structure that can be employed for the unit 103A will be described in detail in Embodiment 3.

A detailed structure that can be used for the electrode 551A and the layer 104A will be described in Embodiment 4.

### <<Structure Example of Light-Emitting Device 550B>>

The light-emitting device 550B includes an electrode 551i, an electrode 552B, and a unit 103B. The electrode 551B is adjacent to the electrode 551A and a gap 551AB is positioned between the electrode 551B and the electrode 551A. The light-emitting device 550B includes a layer 104B. The layer 104B is positioned between the electrode 551B and the unit 103B.

The unit 103B is positioned between the electrode 551B and the electrode 552B and contains a light-emitting material EMB. A gap 103AB is positioned between the unit 103B and the unit 103A and overlaps with the gap 551AB.

### <Structure Example 2 of Light-Emitting Device>

The display device 700 described in this embodiment includes an insulating layer 521 and a conductive film 552 (see FIG. 2). Furthermore, the display device 700 includes a layer 5291, a layer SCRA1, and a layer SCRA2. Moreover, the display device 700 includes a layer 105, a layer SCRB1, a layer SCRC1, a layer SCRB2, and a layer SCRC2.

### <<Structure Example of Insulating Layer 521>>

The insulating layer 521 overlaps with the conductive film 552 with the electrodes 551A and 551B therebetween. In addition, the insulating layer 521 overlaps with the conductive film 552 with an electrode 551C therebetween.

### <<Structure Example of Conductive Film 552>>

The conductive film 552 includes the electrodes 552A and 552B. The conductive film 552 includes the electrode 551C.

For example, a conductive material can be used for the conductive film 552. Specifically, a single layer or a stacked layer using a metal, an alloy, or a material containing a conductive compound can be used for the conductive film 552. Note that a structure example that can be employed for the conductive film 552 will be described in detail in Embodiment 5.

### <<Structure Example of Layer 105>>

Note that the layer 105 includes layers 105A, 105B, and 105C. For the layer 105, a material that facilitates carrier injection from the electrodes 552A, 552B, and 552C can be used. An electron-injection material can be used for the layer 105, for example. Note that a structure example that can be employed for the layer 105 will be described in detail in Embodiment 5.

In this specification and the like, a device formed using a metal mask or a fine metal mask (FMM) may be referred to as a device having a metal mask (MM) structure. In this specification and the like, a device formed without using a metal mask or an FMM is sometimes referred to as a device having a metal maskless (MML) structure.

### <<Structure Example of Layer 529_1>>

The layer 529_1 overlaps with the gap 551AB and has opening portions. One of the opening portions overlaps with the electrode 551A.

The layer 5291 includes a region in contact with the unit 103A and a region in contact with the unit 103B. Furthermore, the layer 529_1 includes a region in contact with the insulating layer 521.

For example, the layer 529_1 can be formed by a CVD method. Thus, a film with good coverage can be formed. Specifically, a plasma enhanced chemical vapor deposition (PECVD) method can be employed.

Specifically, an oxide, a nitride, or the like can be used for the layer 5291. An aluminum oxide film, a silicon nitride film, or the like can be used, for example.

<<Structure Example of Layer SCRA1, layer SCRB1, and layer SCRC1>>

The layer SCRA1 is positioned between the layer 529_1 and the unit 103A. The layer SCRA1 has an opening portion overlapping with the electrode 551A.

For example, a film containing a metal, a metal oxide, an organic material, or an inorganic insulating material can be used as the layer SCRA1. Specifically, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used. In particular, a light-blocking metal film can be used. This can block light emitted in the processing process to inhibit the characteristics of the light-emitting device from being degraded by the light.

The layer SCRB1 is positioned between the layer 529_1 and the unit 103B. The layer SCRB1 has an opening portion overlapping with the electrode 551B. For example, a material that can be used for the layer SCRA1 can be used for the layer SCRB1.

The layer SCRC1 is positioned between the layer 529_1 and the unit 103C. The layer SCRC1 has an opening portion overlapping with the electrode 551C. For example, a material that can be used for the layer SCRA1 can be used for the layer SCRC1.

### <<Structure Example of Layer SCRA2, Layer SCRB2, and Layer SCRC2>>

The layer SCRA2 is positioned between the layer SCRA1 and the unit 103A. The layer SCRA2 has an opening portion overlapping with the electrode 551A and the opening portion of the layer SCRA1.

For example, a film containing an organic material or an inorganic insulating material can be used for the layer SCRA2. Specifically, any of water-soluble materials can be used. In other words, a material that will be dissolved in a solvent containing water can be used for the layer SCRA2. Specifically, a material having higher water solubility than the unit 103A can be used for the layer SCRA2. For example, a material dissolved in the aqueous solution containing hydrofluoric acid (HF), a material dissolved in an aqueous solution containing phosphoric acid, or a material dissolved in an aqueous solution containing nitric acid can be used for the layer SCRA2. Furthermore, a material dissolved in an aqueous solution containing tetramethyl ammonium hydroxide (abbreviation: TMAH) can be used for the layer SCRA2.

Specifically, a metal complex such as tris(8-quinolinolato)aluminum(III) (abbreviation: Alq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used for the layer SCRA2.

Organic compounds represented below by Structural Formulae (101) to (116) and Structural Formulae (121) to (138) can be used for the layer SCRA2.

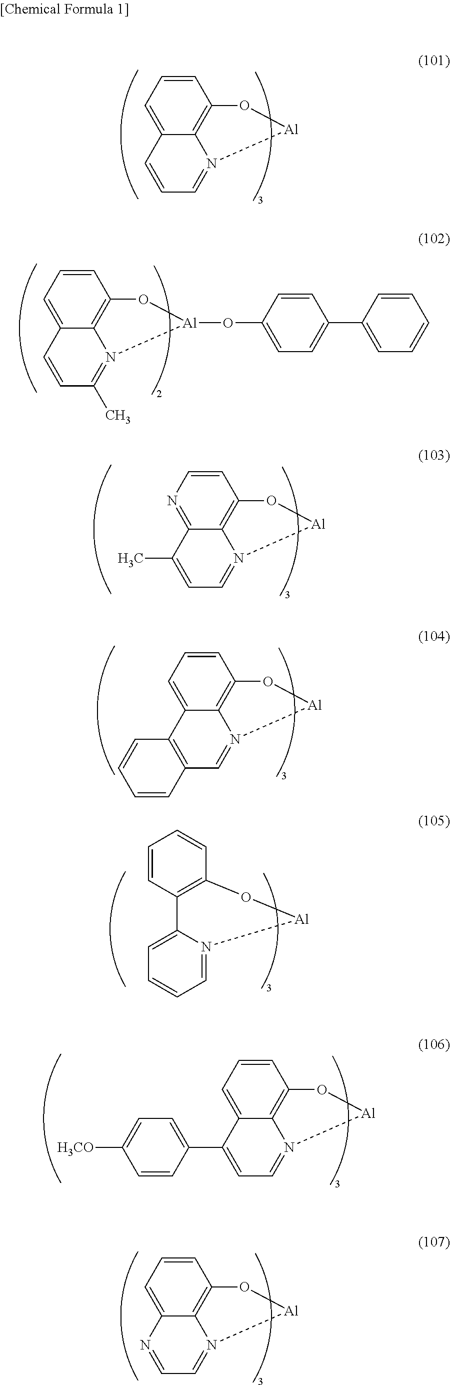

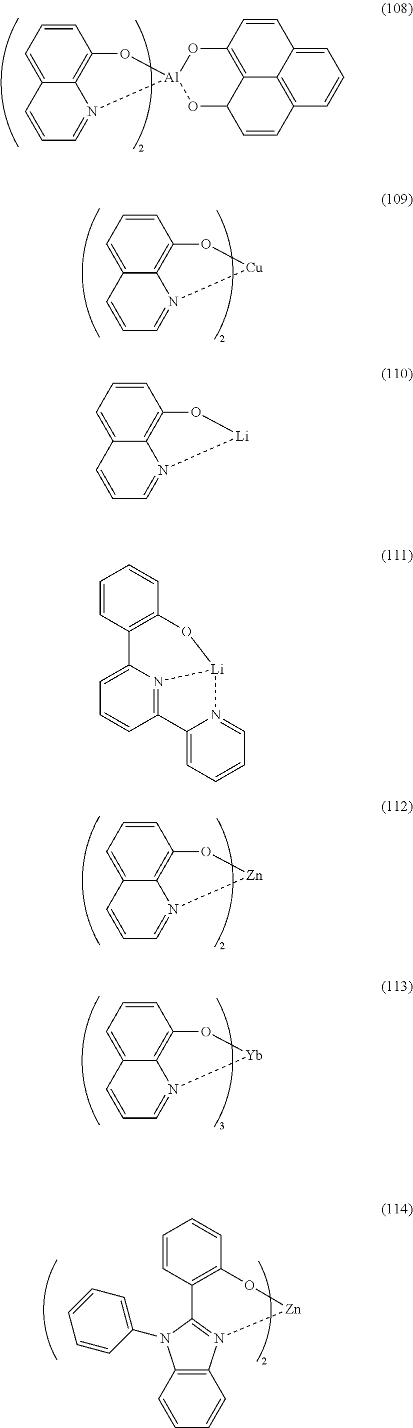

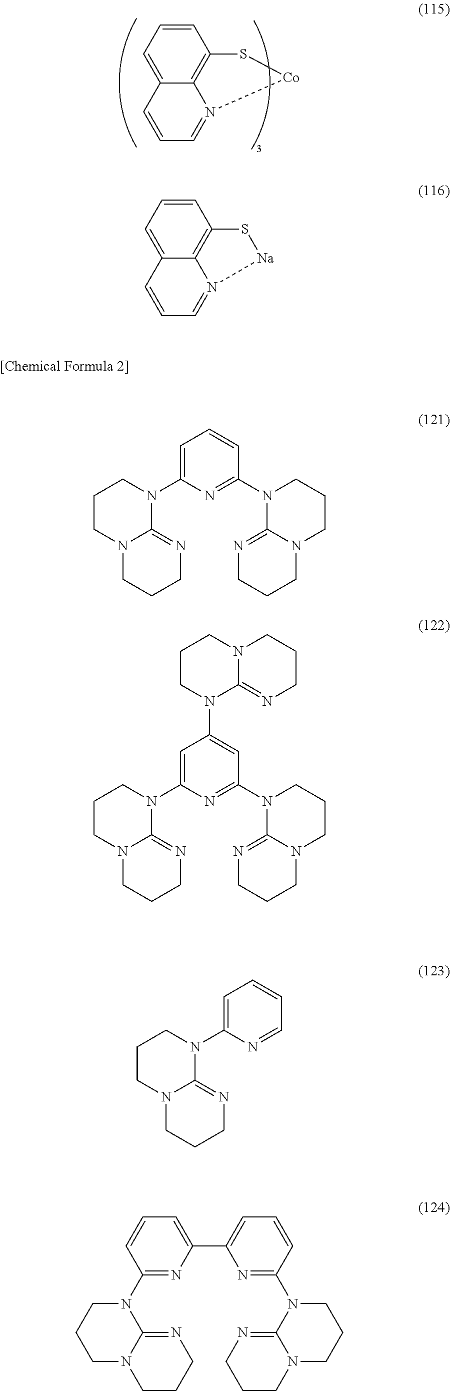

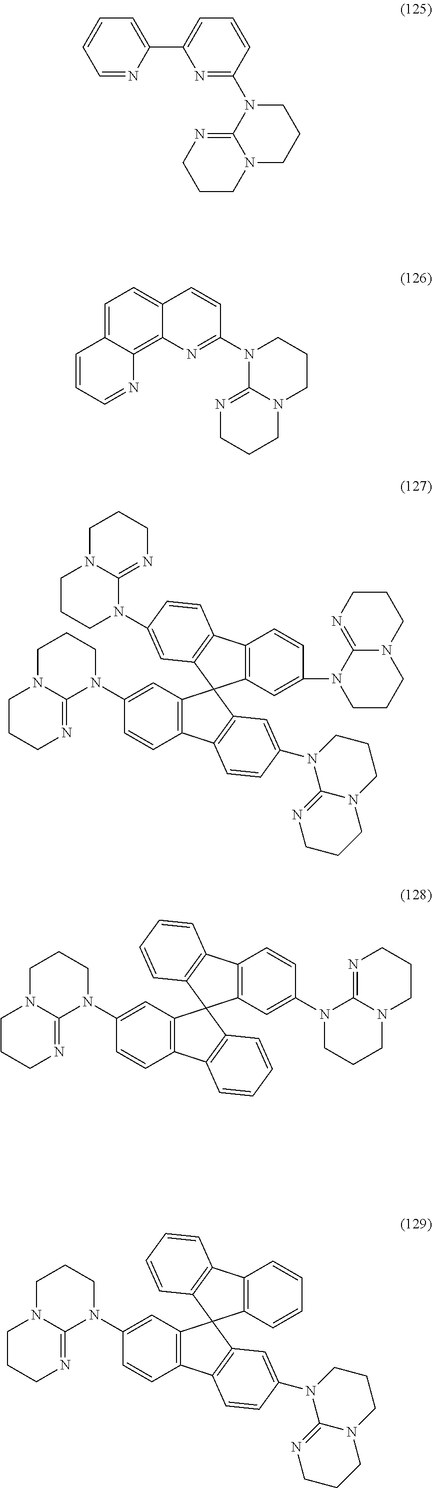 [SMILES: c1ccc(-c2cccc(N3CCCN4CCCN=C43)n2)nc1 ; c1cnc2c(c1)ccc1ccc(N3CCCN4CCCN=C43)nc12 ; c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21]

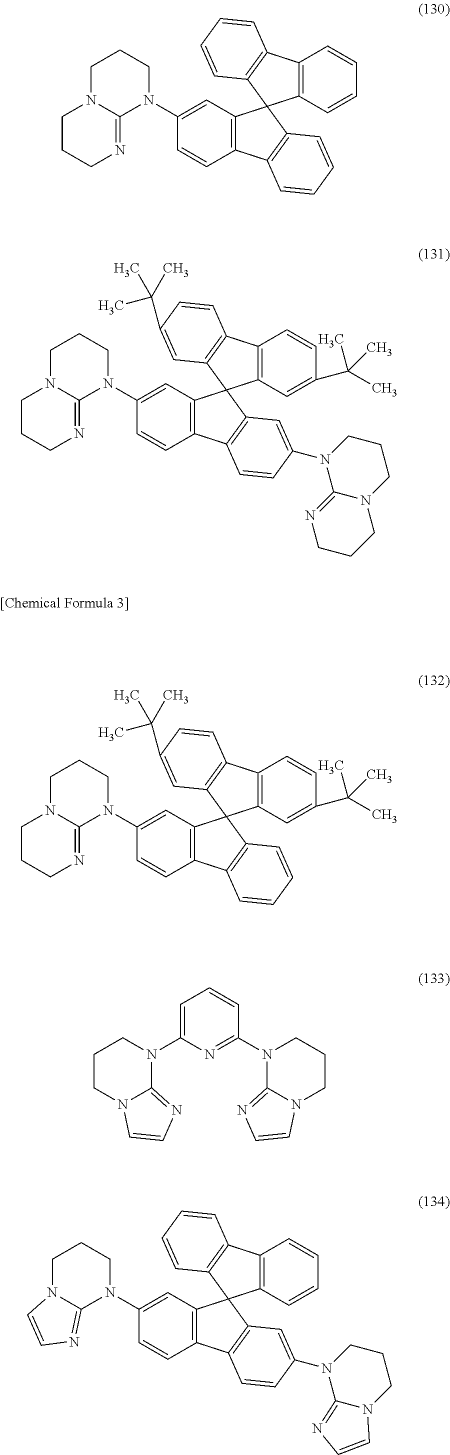 [SMILES: c1ccc2c(c1)-c1ccccc1C21c2ccccc2-c2ccc(N3CCCN4CCCN=C43)cc21 ; CC(C)(C)c1ccc2c(c1)C1(c3cc(N4CCCN5CCCN=C54)ccc3-c3ccc(N4CCCN5CCCN=C54)cc31)c1cc(C(C)(C)C)ccc1-2 ; CC(C)(C)c1ccc2c(c1)C1(c3ccccc3-c3ccc(N4CCCN5CCCN=C54)cc31)c1cc(C(C)(C)C)ccc1-2 ; c1cc(N2CCCn3ccnc32)nc(N2CCCn3ccnc32)c1 ; c1ccc2c(c1)-c1ccccc1C21c2cc(N3CCCn4ccnc43)ccc2-c2ccc(N3CCCn4ccnc43)cc21]

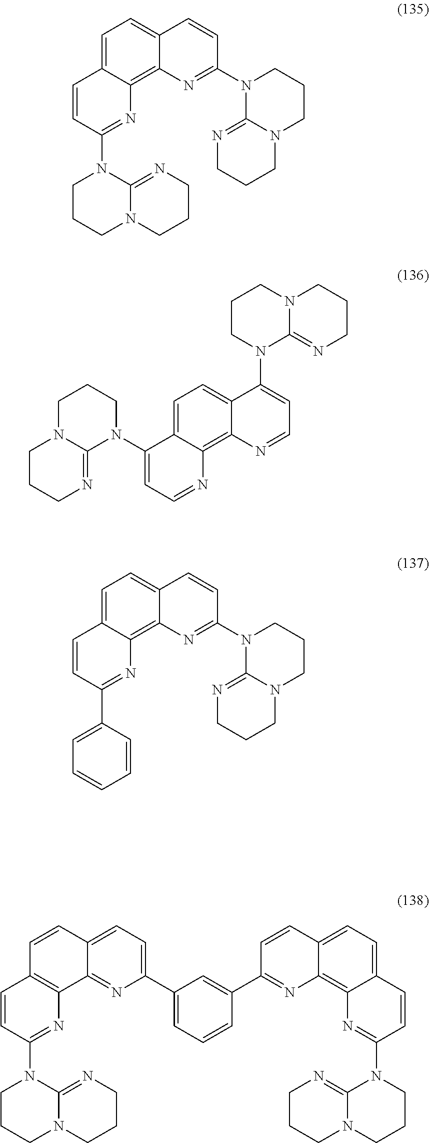 [SMILES: c1cc2ccc3ccc(N4CCCN5CCCN=C54)nc3c2nc1N1CCCN2CCCN=C21 ; c1cc(N2CCCN3CCCN=C32)c2ccc3c(N4CCCN5CCCN=C54)ccnc3c2n1 ; c1ccc(-c2ccc3ccc4ccc(N5CCCN6CCCN=C65)nc4c3n2)cc1 ; c1cc(-c2ccc3ccc4ccc(N5CCCN6CCCN=C65)nc4c3n2)cc(-c2ccc3ccc4ccc(N5CCCN6CCCN=C65)nc4c3n2)c1]

Thus, even when the properties of the layer SCRA2 change during the manufacturing process, for example, the layer SCRA2 located above the unit 103A can be removed to form the light-emitting device 550A. In addition, the layer SCRA2 exposed to plasma or the like during the manufacturing process can be removed. The layer SCRA2 can diminish the impact of plasma or the like during the manufacturing process on the components positioned closer to the substrate 510 than the layer SCRA2 is. Furthermore, the unit 103A can be protected from being damaged in the manufacturing process. As a result, a novel display device that is highly convenient, useful, or reliable can be provided.

The layer SCRB2 is positioned between the layer SCRB1 and the unit 103B. The layer SCRB2 has an opening portion overlapping with the electrode 551B and the opening portion of the layer SCRB1. For example, a material that can be used for the layer SCRA2 can be used for the layer SCRB2.

The layer SCRC2 is positioned between the layer SCRC1 and the unit 103C. The layer SCRC2 has an opening portion overlapping with the electrode 551C and the opening portion of the layer SCRC1. For example, a material that can be used for the layer SCRA2 can be used for the layer SCRC2.

### <<Example of Boron Distribution>>

The boron distribution ranging from a central plane of the layer 529_1 to a central plane of the layer SCRA1 exhibits a concentration profile BCP1 (see FIG. 3A). Note that the dashed-dotted lines in FIGS. 3A to 3C each denote a central plane of the layer. The boron distribution can be observed by secondary ion mass spectrometry (SIMS). For example, in the concentration profile BCP1 of boron shown in FIG. 3A, the boron concentration observed in the layer 5291 is higher than that observed in the layer SCRA1, and a peak of the boron concentration is observed between the layer 529_1 and the layer SCRA1. FIG. 3B shows a boron concentration profile of a display device fabricated in an environment different from that for the display device shown in FIG. 3A. In the concentration profile BCP1 of boron shown in FIG. 3B, the boron concentration observed in the layer 529_1 is lower than that observed in the vicinity of the central plane of the layer SCRA1, and a peak of the boron concentration is observed between the layer 529_1 and the layer SCRA1.

The boron distribution ranging from the central plane of the layer SCRA1 to a central plane of the layer SCRA2 exhibits a concentration profile BCP2. For example, in the concentration profile BCP2 of boron shown in FIG. 3A, the boron concentration observed in the layer SCRA1 is higher than that in the layer SCRA2, and no peak of the boron concentration is observed between the layer SCRA1 and the layer SCRA2. In the concentration profile BCP2 of boron shown in FIG. 3C, the boron concentration observed in the layer SCRA1 is lower than that in the layer SCRA2, and no peak of the boron concentration is observed between the layer SCRA1 and the layer SCRA2.

The concentration profile BCP2 exhibits a peak lower than that in the concentration profile BCP1. Alternatively, the concentration profile BCP1 has a peak whereas the concentration profile BCP2 has no peak.

With this structure, the amount of impurities entering the light-emitting device during the manufacturing steps from a clean room or the like can be reduced. For example, the amount of oxygen, water, boron, or the like entering an interface of the deposited layers from the clean room or the like and accumulated can be reduced. Moreover, a phenomenon of lowering the reliability due to impurities can be prevented. As a result, a novel display device that is highly convenient, useful, or reliable can be provided.

### <Structure Example 3 of Display Device>

The display device 700 described in this embodiment includes a layer 529_2.

### <<Structure Example of Layer 529_2>>

The layer 529_2 is positioned between the conductive film 552 and the insulating layer 521, overlaps with the gap 551AB, and fills the gap 103AB.

The layer 529_2 has a plurality of opening portions; one of the opening portions overlaps with the electrode 551A, another opening portion overlaps with the electrode 551B, and another opening portion overlaps with the electrode 551C.

The layer 529_2 can be formed using a photosensitive resin, for example. Specifically, an acrylic resin or the like can be used.

Thus, the gap 103AB can be filled with the layer 529_2. Moreover, a step caused by the gaps 551AB and 103AB can be reduced so as to be close to a flat plane. A phenomenon in which a cut or a split is generated due to the step difference in the conductive film 552 can be prevented. As a result, a novel display device that is highly convenient, useful, or reliable can be provided.

Note that this embodiment can be combined with any of the other embodiments in this specification as appropriate.

### Embodiment 2

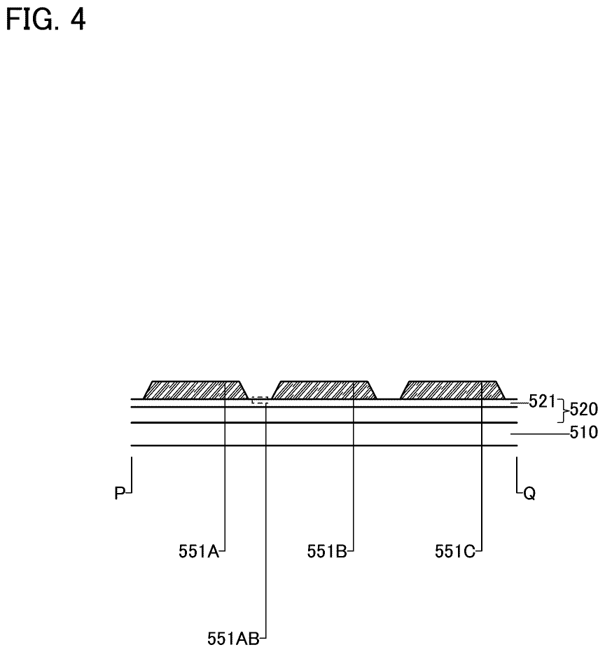

In this embodiment, a method for manufacturing a display device of one embodiment of the present invention will be described with reference to FIG. 4 to FIGS. 26A to 26D.

### <Manufacturing Method Example 1 of Display Device 700>

The method for manufacturing the display device described in this embodiment includes the following steps.

### [Step S1]

In Step S1, the electrode 551A, the electrode 551B, and the gap 551AB positioned between the electrode 551A and the electrode 551B are formed over the insulating layer 521 (see FIG. 4).

For example, a conductive film can be formed by a sputtering method and then processed into a predetermined shape by a photolithography method.

### [Step S2]

In Step S2, a film 103a is formed over the electrode 551A and the electrode 551B.

For example, a predetermined film can be formed by a resistance-heating method. Specifically, an organic compound(s) can be deposited or co-deposited. Note that a film 104a that is to be the layer 104A later can be formed before the formation of the film 103a.

### [Step S3]

In Step S3, a film SCRa2 is formed over the film 103a. This formation can inhibit a defect of altering components in the film 103a from being caused in formation of a film SCRa1 in Step S4.

For example, a predetermined film can be formed by a resistance-heating method. Note that it is preferable that a workpiece be subjected to Step S2 and Step S3 performed continuously without being exposed to the atmosphere. For example, the steps adopt treatment chambers that are connected to each other with a transfer chamber in which the pressure is reduced or a transfer chamber filled with a gas whose impurity concentration is controlled. Thus, the amount of impurities entering a light-emitting device from a clean room or the like can be reduced, for example. For example, the amount of oxygen, water, boron, or the like entering an interface of the deposited layers from the clean room or the like and accumulated can be reduced. Furthermore, a phenomenon of adsorbing and diffusing impurities contained in the atmosphere of the clean room to/in the film 103a can be prevented. Specifically, a phenomenon of adsorbing and diffusing oxygen or water to/in the film 103a can be prevented. Moreover, it is possible to eliminate a defect of altering components contained in the film 103a which is caused by activating the components or impurities contained in the film 103a by energy such as light applied to the workpiece in a later step.

A material that enables a removal of an unnecessary portion by an etching method in Step S6 and Step S15 described later can be used for the film SCRa2. Specifically, the film SCRa2 can be formed by deposition of an organic compound.

Preferably, a material that enables a concurrent removal of an unnecessary portion of the film SCRa2 and an unnecessary portion of the film 103a in Step S6 can be used for the film SCRa2. For example, a material that enables the concurrent removal by a dry etching method using an etching gas containing oxygen can be used for the film SCRa2.

Meanwhile, a material that can be used for the film SCRa2 in Step S15 is such as to enable a selective removal of an unnecessary portion of the film SCRa2 while preventing altering or dissolving the components in the film 103a. For example, a material that enables the selective removal by a wet etching using an acidic etchant can be used for the film SCRa2. Preferably, a material that enables the selective removal using an etchant containing an organic acid can be used for the film SCRa2. Specifically, an oxalic acid or a phosphoric acid can be used for the organic acid.

### [Step S4]

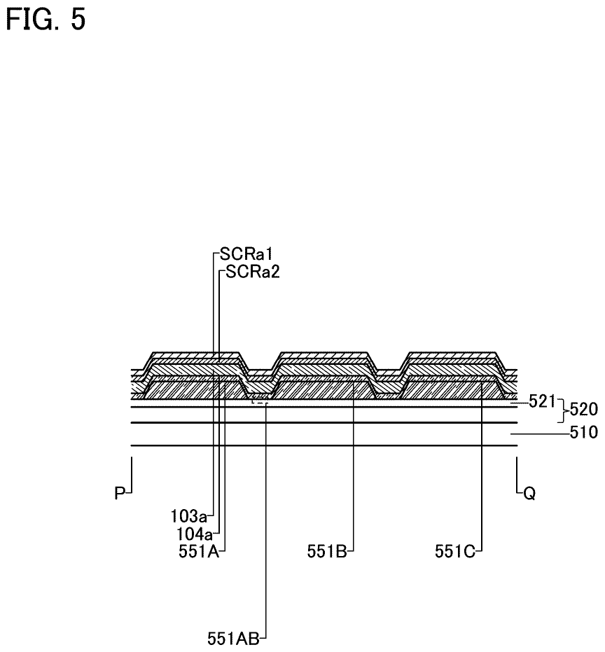

In Step S4, the film SCRa1 is formed over the film SCRa2 by a CVD method (see FIG. 5). Specifically, a plasma-enhanced chemical vapor deposition (PECVD) method can be employed.

Thus, a film with a small number of pinholes, a film with good coverage, or a dense film can be used for the film SCRa1. Furthermore, resist liquid containing a solvent and a photosensitive polymer can be used for forming of a resist RES in Step S5. It is possible to prevent a phenomenon of altering or dissolving the components in the film 103a from being caused by the solvent transmitting the pinholes and reaching the film 103a.

Moreover, the throughput can be improved as compared with a method in which the film SCRa1 is formed by an ALD method, for example. A manufacturing apparatus can be increased in size as compared with the method in which the film SCRa1 is formed by an ALD method, for example. A substrate used for a workpiece can be increased in size as compared with the method in which the film SCRa1 is formed by an ALD method, for example. The productivity can be improved as compared with the method in which the film SCRa1 is formed by an ALD method, for example. As a result, a method for manufacturing a novel display device that is highly convenient, useful, or reliable can be provided.

For example, a film containing an inorganic material can be used for the film SCRa1. Specifically, a metal, a metal oxide, an oxynitride, or a nitride can be used for the film SCRa1. Thus, a part of the film SCRa1 can serve as a hard mask in use of a dry etching method using an etching gas containing oxygen in Step S6.

It is preferable that the workpiece be subjected to Step S2 to Step S4 continuously without being exposed to the atmosphere. For example, the steps adopt treatment chambers connected to each other with a transfer chamber in which the pressure is reduced or a transfer chamber filled with a gas whose impurity concentration is controlled. Thus, the amount of impurities entering a light-emitting device from a clean room or the like can be reduced, for example. For example, the amount of oxygen, water, boron, or the like entering an interface of the deposited layers from the clean room or the like and accumulated can be reduced. Furthermore, a phenomenon of lowering the reliability due to the impurities can be prevented. As a result, a method for manufacturing a novel display device that is highly convenient, useful, or reliable can be provided.

### [Step S5]

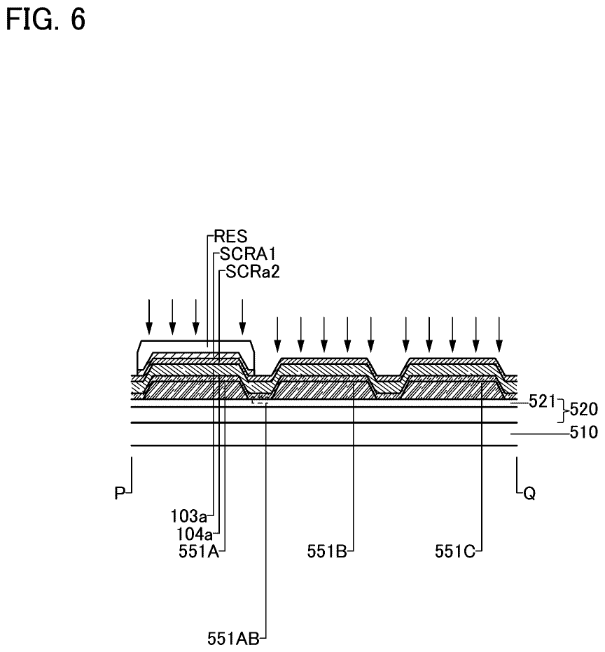

In Step S5, the film SCRa1 located above the electrode 551B is removed by an etching method, so that the layer SCRA1 overlapping with the electrode 551A is formed (see FIG. 6). For example, the resist RES is formed by a photolithography method using resist liquid containing a solvent and a photosensitive polymer, and with use of the resist RES, the layer SCRA1 is formed by an etching method.

### [Step S6]

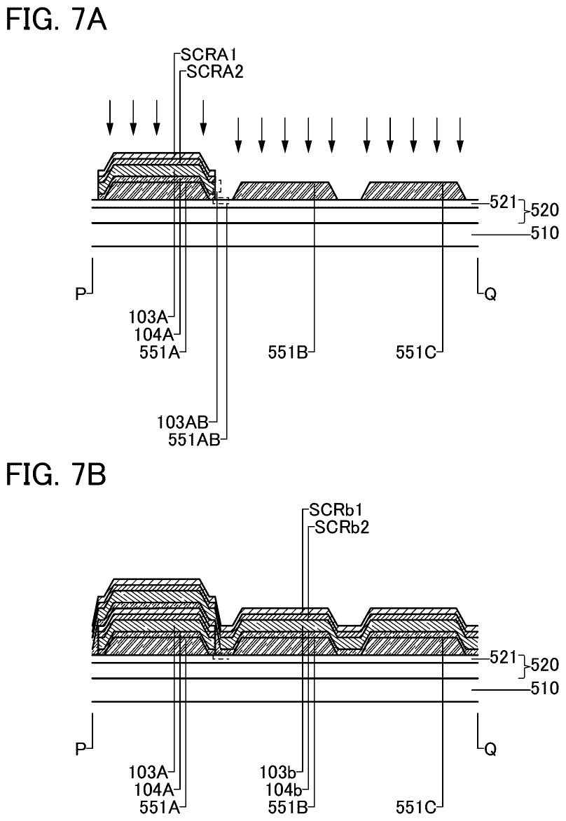

In Step S6, the film SCRa2 and the film 103a each located above the electrode 551B are removed by an etching method using the layer SCRA1, so that the layer SCRA2 and the unit 103A each overlapping with the electrode 551A are formed (see FIG. 7A). In other words, the film 104a, the film 103a, and the film SCRa2 are processed into the layer 104A, the unit 103A, and the layer SCRA2, respectively.

For example, the unit 103A can be processed into a predetermined shape by a dry etching method. Specifically, an oxygen-containing gas can be used as an etching gas. Note that the layer SCRA1 functions as a hard mask.

In Step S6, the electrodes 551B and 551C are exposed. Note that when the surfaces of the electrodes 551B and 551C are exposed to plasma containing oxygen, the properties of the electrodes 551B and 551C may be changed. Furthermore, the driving voltages of the light-emitting devices 550B and 550C may be increased. In Step S6, a change in the properties can be inhibited when nitrogen is added to the etching gas containing oxygen. Before moving on to Step S7, plasma treatment using a nitrogen-containing gas is performed on the surfaces of the electrodes 551B and 551C, whereby a change in the properties can be alleviated and the properties can be recovered. As a result, an increase in the driving voltage of the light-emitting device 550B can be suppressed. An increase in the driving voltage of the light-emitting device 550C can be also suppressed.

### [Step S7]

In Step S7, a film 103b is formed over the layer SCRA1 and the electrode 551B. Before the film 103b is formed, a film 104b that is to be the layer 104B layer can be formed.

### [Step S8]

In Step S8, a film SCRb2 is formed over the film 103b (see FIG. 7B).

### [Step S9]

In Step S9, a film SCRb1 is formed over the film SCRb2.

### [Step S10]

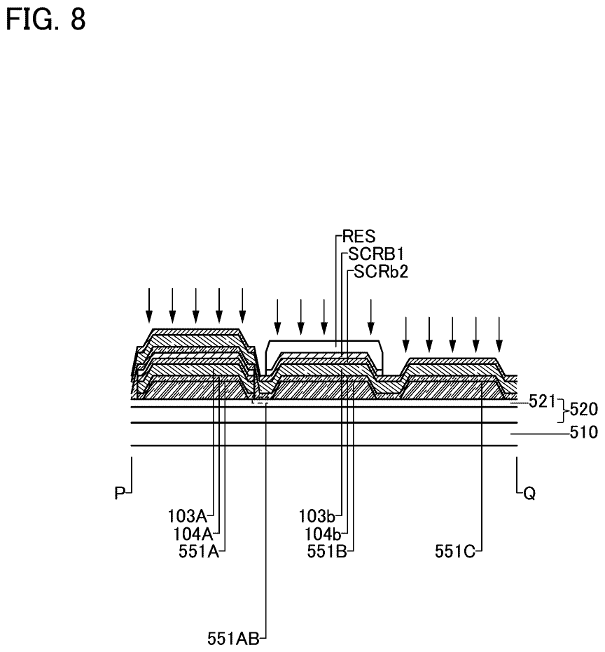

In Step S10, the film SCRb1 located above the layer SCRA1 is removed by an etching method using the resist RES, so that the layer SCRB1 overlapping with electrode 551B is formed (see FIG. 8).

### [Step S11]

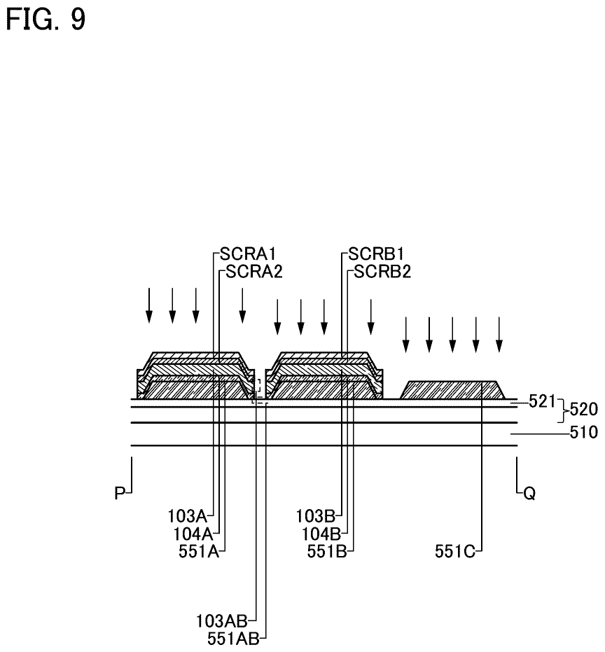

In Step S11, the film SCRb2 and the film 103b each located above the layer SCRA1 and the gap 551AB are removed by an etching method using the layer SCRB1, so that the layer SCRB2 and the unit 103B each overlapping with the electrode 551B and the gap 103AB overlapping with the gap 551AB are formed (see FIG. 9). In other words, the film 104b, the film 103b, and the film SCRb2 are processed into the layer 104B, the unit 103B, and the layer SCRB2, respectively.

For example, the unit 103B can be processed into a predetermined shape by a dry etching method. Specifically, an oxygen-containing gas can be used as an etching gas. Note that the layer SCRB1 serves as a hard mask.

In Step S11, the electrode 551C is exposed. Note that when the surface of the electrode 551C is exposed to plasma containing oxygen, a property of the electrode 551C may be changed. Furthermore, the driving voltage of the light-emitting device 550C may be increased. In Step S11, nitrogen is added to the etching gas containing oxygen, whereby a change in the properties can be inhibited. Before moving on to Step S12, plasma treatment using a nitrogen-containing gas is performed on the surface of the electrode 551C, whereby a change in the properties can be alleviated and the properties can be recovered. As a result, an increase in the driving voltage of the light-emitting device 550C can be suppressed.

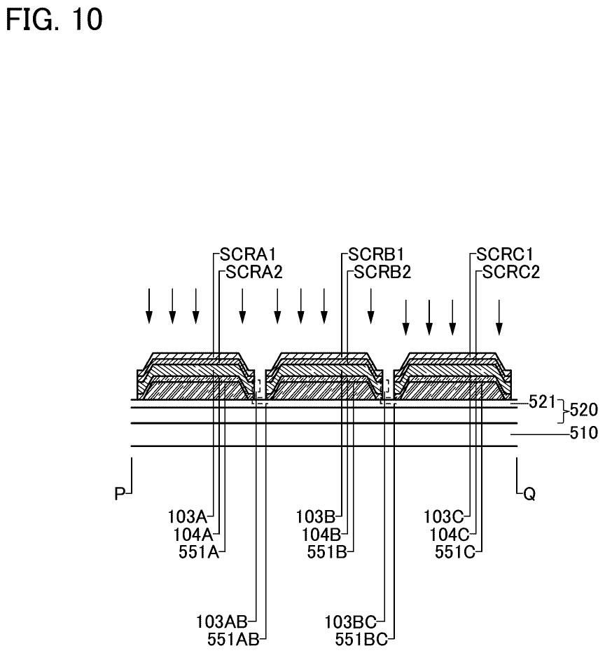

In a manner similar to the above, the layer SCRC2 and the unit 103C each overlapping with the electrode 551C and a gap 103BC overlapping with a gap 551BC are formed (see FIG. 10). Specifically, the description of Step S7 to Step S11 can be used for the description of the manufacturing method by replacing the reference numerals “b” and “B” with “c” and “C”.

### [Step S12]

In Step S12, the layer 529_1 is formed to be in contact with the insulating layer 521 in the gap 551AB and cover the units 103A and 103B.

Note that the layer 5291 is formed by a CVD method, for example. Specifically, silicon nitride can be used for the layer 529_1. Thus, a film with a small number of pinholes, a film with good coverage, or a dense film can be used for the layer 529_1. Moreover, a phenomenon of diffusing impurities such as oxygen or water into the unit 103A can be prevented. The throughput can be improved as compared with a method in which the film SCRa1 and the layer 5291 are formed by an ALD method, for example. A manufacturing apparatus can be increased in size as compared with the method in which the film SCRa1 and the layer 5291 are formed by an ALD method, for example. A substrate used for a workpiece can be increased in size as compared with the method in which the film SCRa1 and the layer 529_1 are formed by an ALD method, for example. The productivity can be improved as compared with the method in which the film SCRa1 and the layer 529_1 are formed by an ALD method, for example. As a result, a method for manufacturing a novel display device that is highly convenient, useful, or reliable can be provided.

### [Step S13]

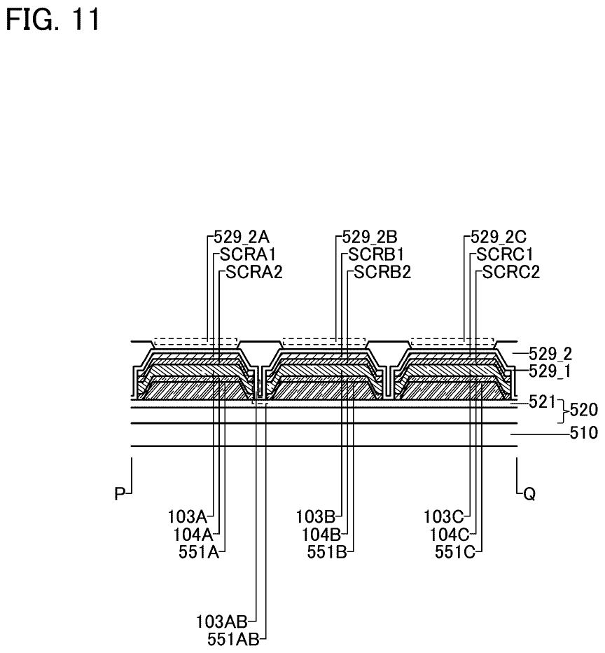

In Step S13, the layer 529_2 is formed to fill the gaps 551AB and 103AB and have an opening portion 529_2A overlapping with the electrode 551A and an opening portion 529_2B overlapping with the electrode 551B (see FIG. 11).

### [Step S14]

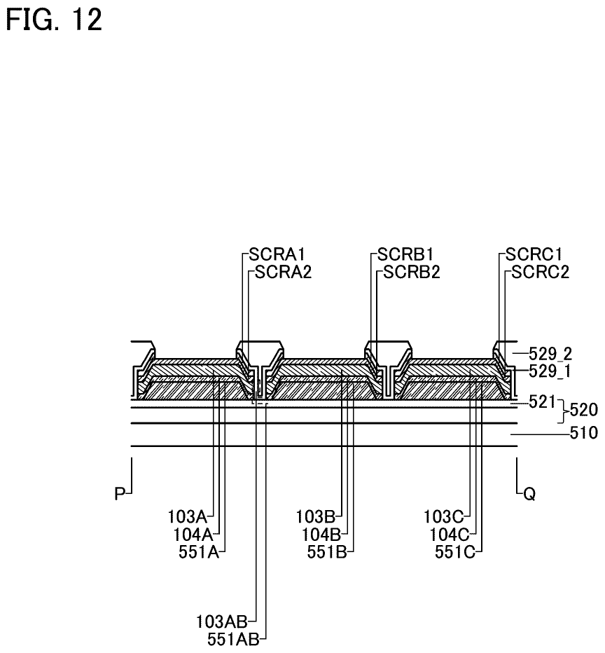

In Step S14, the layer 529_1 and the layer SCRA1 each in a portion overlapping with the opening portion 529_2A are removed, and the layer 529_1 and the layer SCRB1 each in a portion overlapping with the opening portion 529_2B, by a dry etching method using the layer 529_2 (see FIG. 12). In the case where each of the layer SCRA1 and the layer SCRB1 is formed using a stacked-layer film, unnecessary portions of the layer SCRA1 and the layer SCRB1 can be partly removed in Step S14, an parts of the remaining unnecessary portion of the layer SCRA1 and the layer SCRB1 can be removed in Step S15 following Step S14.

### [Step S15]

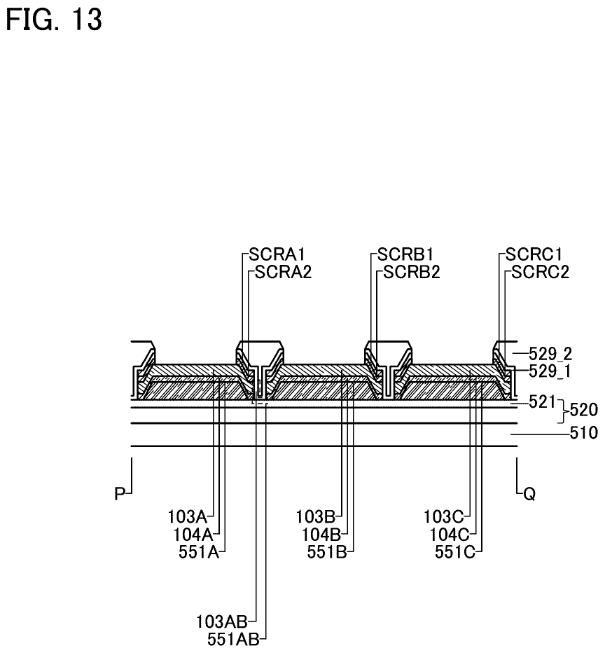

In Step S15, the layer SCRA2 in a portion overlapping with the opening portion 529_2A is removed, and the layer SCRB2 in a portion overlapping with the opening portion 529_2B are removed by an etching method using the layer 529_2 (see FIG. 13).

### [Step S16]

In Step S16, the layer 105 is formed over the units 103A and 103B.

### [Step S17]

In Step S17, the conductive film 552 is formed over the layer 105 (see FIG. 14).

Thus, the throughput can be improved as compared with a method in which the film SCRa1 is formed by an ALD method, for example. A manufacturing apparatus can be increased in size as compared with the method in which the film SCRa1 is formed by an ALD method, for example. A substrate used for a workpiece can be increased in size as compared with the method in which the film SCRa1 is formed by an ALD method, for example. The productivity can be improved as compared with the method in which the film SCRa1 is formed by an ALD method, for example. The gap 103AB can be formed between the unit 103A and the unit 103B. Occurrence of a phenomenon in which one of the light-emitting device 550A and the light-emitting device 550B emits light with unintended luminance in accordance with light emission of the other of the light-emitting device 550A and the light-emitting device 550B can be suppressed. In addition, the light-emitting device 550A and the light-emitting device 550B can be individually driven. Occurrence of a cross talk phenomenon between light-emitting devices can be suppressed. The resolution of the display device can be increased. The aperture ratio of a pixel of the display device can be increased. As a result, a method for manufacturing a novel display device that is highly convenient, useful, or reliable can be provided.

### <Manufacturing Method Example 2 of Display Device 700>

The method for manufacturing a display device of one embodiment of the present invention includes the following steps, instead of the above steps.

### [Another Example Step S14]

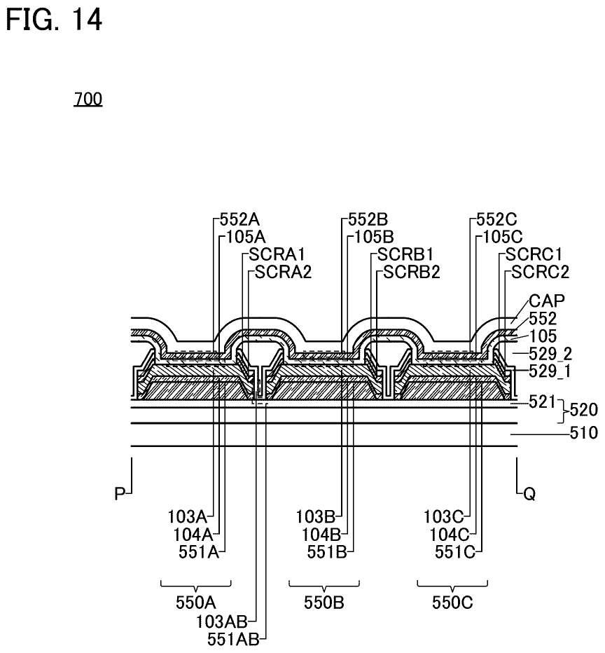

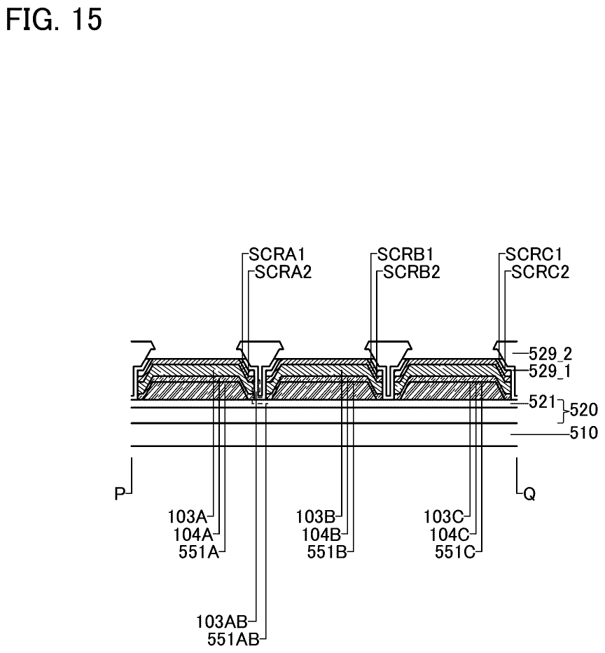

In Step S14, the layer 529_1 and the layer SCRA1 each in a portion overlapping with the opening portion 529_2A are removed, and the layer 529_1 and the layer SCRB1 each in a portion overlapping with the opening portion 529_2B are removed, by a wet etching method using the layer 529_2 (see FIG. 15). Note that in FIG. 15, part of the layer 5291, part of the layer SCRA1, and part the layer SCRB1 each overlapping with the end portion of the layer 529_2 are also removed.

### [Step S18]

Step S18 is performed between Step S14 (another example) and Step S15.

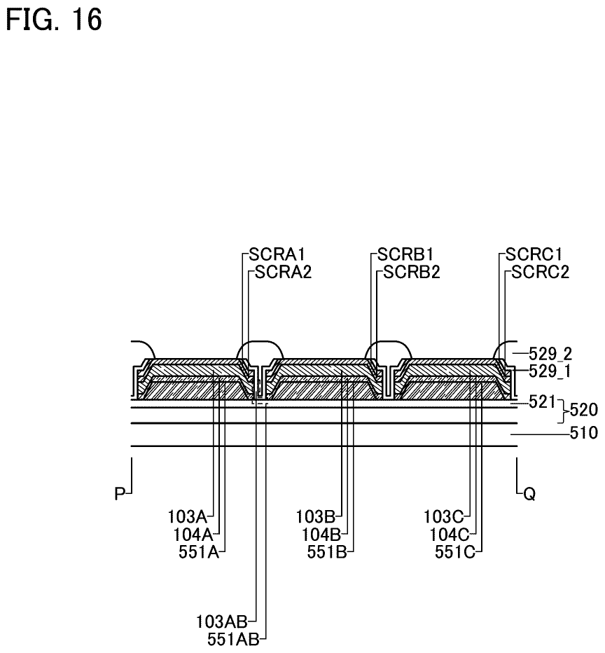

In Step S18 following Step S14 (another example) shown in FIG. 15, the layer 529_2 is made to have fluidity to be in contact with the layer SCRA2 (see FIG. 16). For example, the layer 5292 is softened by heating the workpiece, whereby the layer 529_2 can have fluidity.

### [Step S15]

In Step S15 following Step S18, the layer SCRA2 in a portion overlapping with the opening portion 529_2A is removed, and the layer SCRB2 in a portion overlapping with the opening portion 529_2B is removed, by an etching method using the layer 529_2.

### [Step S16]

In Step S16, the layer 105 is formed over the units 103A and 103B.

### [Step S17]

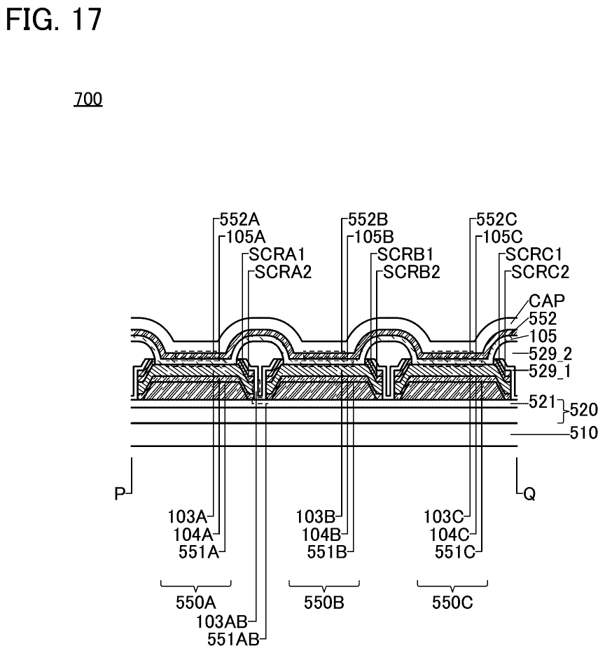

In Step S17, the conductive film 552 is formed over the layer 105 (see FIG. 17).

In the display device 700 of one embodiment of the present invention, the gaps 551AB and 103AB are filled with the layer 529_2. The layer 529_2 has the opening portion 529_2A and the opening portion 529_2B. The opening portion 529_2A overlaps with the electrode 551A, and the opening portion 529_2B overlaps with the electrode 551B. The layer 529_2 is in contact with the layer SCRA2.

Accordingly, a step difference between the layer 529_2 and the layer SCRA2 can be reduced. Moreover, a step difference between the layer 529_2 and the unit 103A can be reduced. In addition, the step can be made closer to a flat surface. A phenomenon in which a cut or a split is generated due to the step difference in the conductive film 552 can be prevented. As a result, a method for manufacturing a novel display device that is highly convenient, useful, or reliable and such a display device can be provided.

### <Manufacturing Method Example 3 of Display Device 700>

The method for manufacturing a display device of one embodiment of the present invention described in this section is different from the above method for manufacturing a display device in that the film SCRa1 has a stacked-layer film. Different portions are described in detail here, and the above description is referred to for portions formed by a method similar to the above.

For example, a stacked-layer film containing an inorganic material can be used for the film SCRa1. Specifically, a stacked-layer film including a film serving as a hard mask and a film with a small number of pinholes can be used for the film SCRa1. Alternatively, a stacked-layer film including a film serving as a hard mask and a film with good coverage can be used for the film SCRa1. Alternatively, a stacked-layer film including a film serving as a hard mask and a dense film can be used for the film SCRa1.

Furthermore, a stacked-layer film applicable to the film SCRa1 can be such that a material serving as a hard mask in Step S6 and a material serving as an etching stopper when the material serving as a hard mask is removed in Step S15 are stacked.

Furthermore, a stacked-layer film applicable to the film SCRa1 can be such that a material enabling a selective removal of an unnecessary portion by a dry etching method in Step S14 and a material enabling a selective removal of an unnecessary portion while preventing altering or dissolving the components in the film 103a in Step S15 are stacked.

Furthermore, a stacked-layer film applicable to the film SCRa1 can include a material that inhibits oxygen diffusion from the layer SCRA1 to the film 103a in Step S5. Furthermore, a stacked-layer film applicable to the film SCRa1 can include a material that inhibits oxygen diffusion from the layer SCRA1 to the unit 103A during Steps S6 to S13.

Furthermore, a stacked-layer film applicable to the film SCRa1 can include a film formed by a sputtering method and a film formed by a CVD method, for example. Specifically, a stacked-layer film applicable to the film SCRa1 can be a stack of a film containing a metal oxide overlapping with the film 103a with the film SCRa2 therebetween and a film containing a nitride overlapping with the film SCRa2 with the film containing a metal oxide therebetween. Examples of the metal oxide include indium-gallium-zinc oxide (abbreviation: IGZO), indium-tin oxide (abbreviation: ITO), and aluminum oxide (abbreviation: AlOₓ). A film containing silicon and nitrogen can be used for a nitride, for example. Instead of the nitride, a material containing silicon, oxygen, and nitrogen can be used. Specifically, a stacked-layer film including a film containing IGZO formed by a sputtering method and a film containing silicon nitride formed by a CVD method can be used for the film SCRa1.

When not the film SCRa2 but the film SCRa1 is formed on the surface of the film 103a by a sputtering method, for example, the molecular structure of an organic compound contained in the film 103a is changed in some cases. When the film 103a contains an organic compound whose molecular structure is changed, the driving voltage of a fabricated light-emitting device is increased in some cases. In some cases, power consumption of the light-emitting device is increased. The reliability of the light-emitting device is degraded in some cases.

### [Another Example of Step S4]

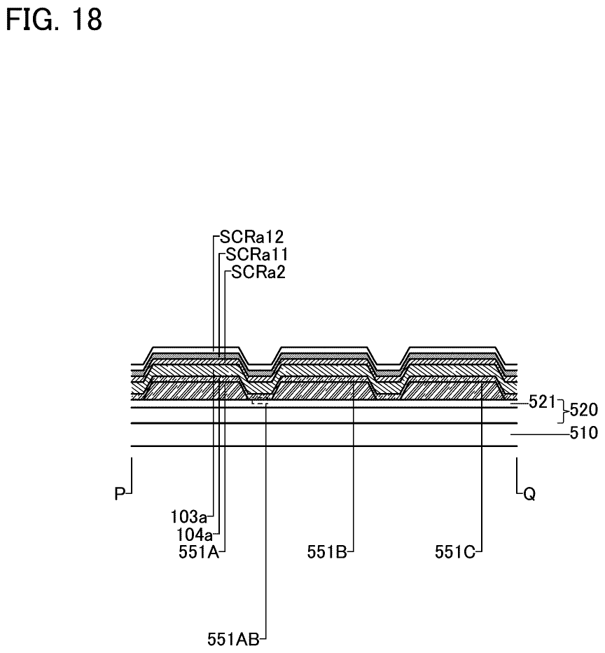

In Step S4, a stacked-layer film is formed over the film SCRa2 (see FIG. 18). For example, a film SCRa11 is formed by a sputtering method, and a film SCRa12 is formed by a plasma CVD method. Specifically, IGZO can be used for the film SCRa11. The film containing silicon nitride can be used for the film SCRa12.

### [Another Example of Step S5]

In Step S5, the film SCRa12 located above the electrode 551B is removed by an etching method, so that a layer SCRA12 and a layer SCRA11 each overlapping with the electrode 551A are formed.

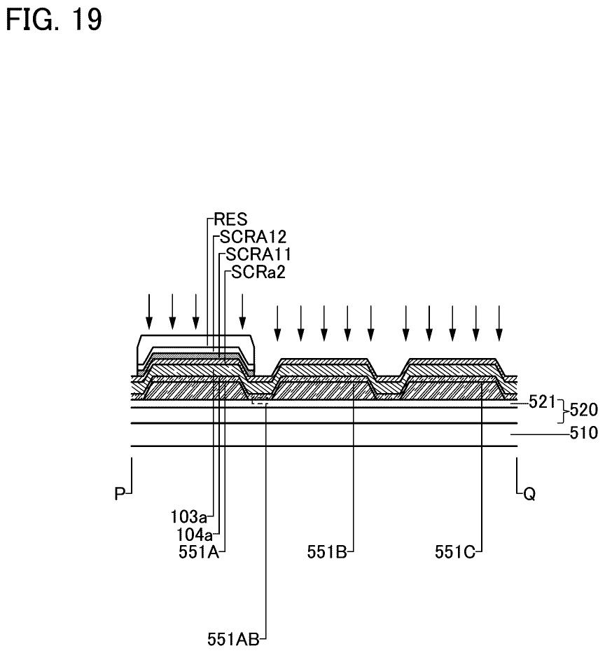

For example, the resist RES is formed by a photolithography method using resist liquid containing a solvent and a photosensitive polymer, and with use of the resist RES, the layer SCRA12 is formed by a dry etching method. In addition, the layer SCRA11 is formed by a wet etching method using the resist RES (see FIG. 19). Note that a stacked-layer body in which the layer SCRA11 and the layer SCRA12 are stacked have the same function as the layer SCRA1.

### [Another Example of Step S6]

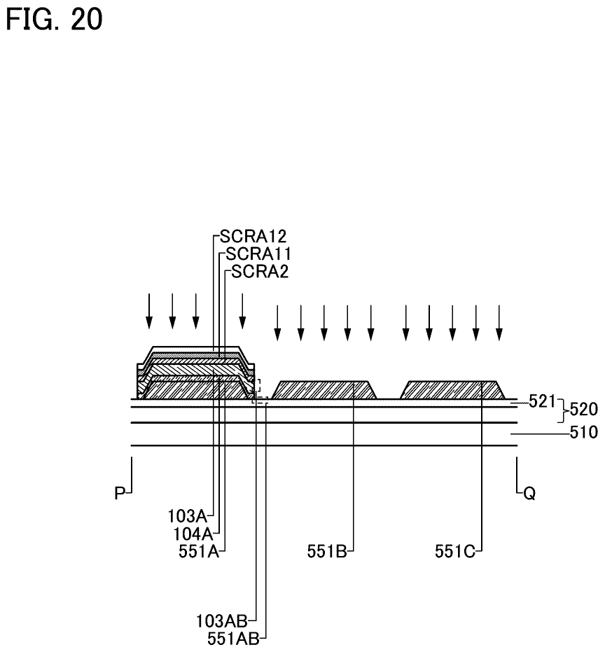

In Step S6, the layer SCRA2 and the unit 103A each overlapping with the electrode 551A are formed by an etching method using the layer SCRA12 and the layer SCRA11 (see FIG. 20).

For example, the unit 103A can be processed into a predetermined shape by a dry etching method. Specifically, an oxygen-containing gas can be used as an etching gas. Note that the layer SCRA12 serves as a hard mask.

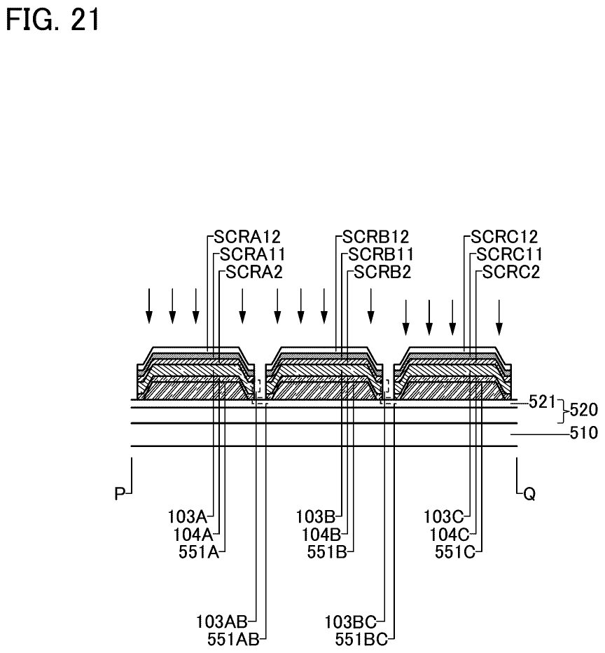

In a manner similar to the above, a layer SCRB12 and a layer SCRB11 each overlapping with the electrode 551B are formed, and a layer SCRC12 and a layer SCRC11 each overlapping with the electrode 551C are formed (see FIG. 21). Furthermore, the layer SCRB2 and the unit 103B each overlapping with the electrode 551B are formed, and the gap 103AB overlapping with the gap 551AB is formed. The layer SCRC2 and the unit 103C each overlapping with the electrode 551C are formed, and the gap 103BC overlapping with the gap 551BC is formed. Specifically, the description of another example of Step S4 to another example of Step S6 can be used for the description of the manufacturing method by replacing the reference numerals “a” and “A” with “b” or “c” and “B” or “C”.

### [Another Example of Step S12]

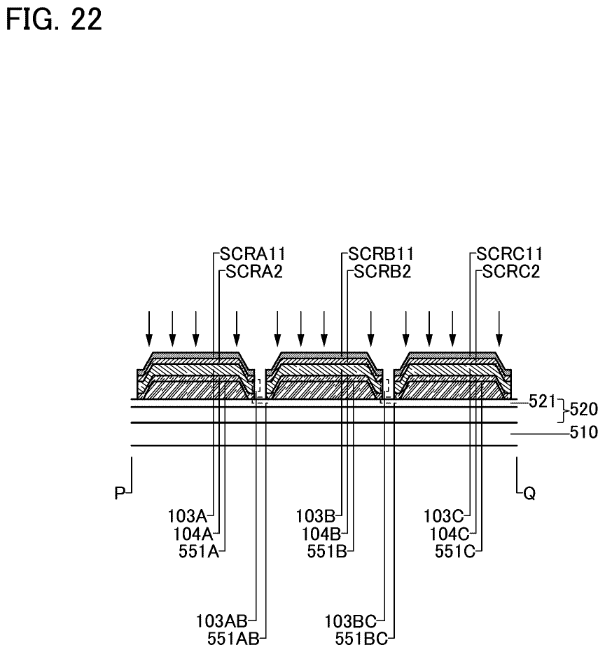

In Step S12, the layer SCRA12, the layer SCRB12, and the layer SCRC12 are removed by an etching method (see FIG. 22). Note that the layer SCRA11, the layer SCRB11, and the layer SCRC11 each serve as an etching stopper. For example, a dry etching method can be used for removal of the layer SCRA12, the layer SCRB12, and the layer SCRC12. Specifically, a fluorine-containing gas can be used as an etching gas.

For example, the layer SCRA12 suffers from a change in its property in some cases when being exposed to an etching gas repeatedly. The layer SCRA12 exposed to an etching gas containing oxygen suffers from a change in its property in some cases. Another film is stacked on the layer SCRA12 whose property has been changed, the film might be peeled off during the manufacturing process. When another film is stacked on the layer SCRA11 that is to be exposed after the removal of the layer SCRA12 whose property has been changed, the film adheres to the layer SCRA11 well.

Next, the layer 529_1 is formed to be in contact with the insulating layer 521 in the gap 551AB and cover the units 103A and 103B.

The layer 529_1 is formed by a CVD method, for example. Specifically, silicon nitride can be used for the layer 529_1. Thus, a film with a small number of pinholes, a film with good coverage, or a dense film can be used for the layer 529_1. Moreover, a phenomenon of diffusing impurities such as oxygen or water into the unit 103A can be prevented. The throughput can be improved as compared with a method in which the film SCRa1 and the layer 529_1 are formed by an ALD method, for example. A manufacturing apparatus can be increased in size as compared with the method in which the film SCRa1 and the layer 529_1 are formed by an ALD method, for example. A substrate used for a workpiece can be increased in size as compared with the method in which the film SCRa1 and the layer 529_1 are formed by an ALD method, for example. The productivity can be improved as compared with the method in which the film SCRa1 and the layer 529_1 are formed by an ALD method, for example. As a result, a method for manufacturing a novel display device that is highly convenient, useful, or reliable can be provided.

### [Step S13]

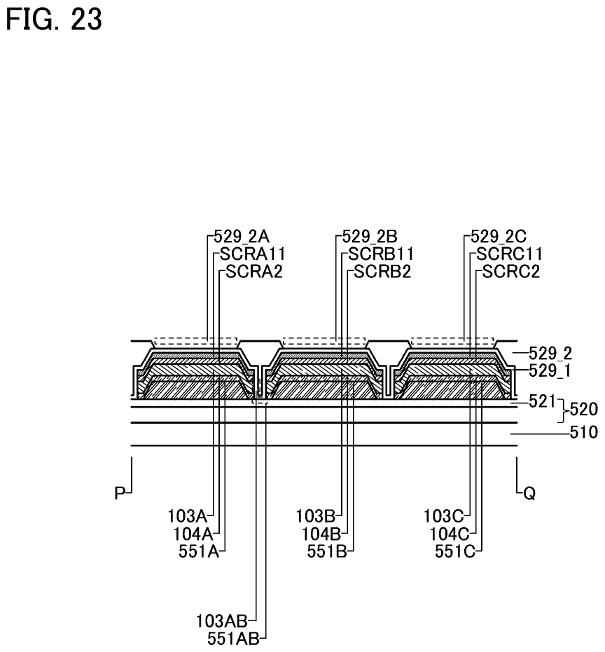

In Step S13, the layer 5292 is formed to fill the gaps 551AB and 103AB and have the opening portion 529_2A overlapping with the electrode 551A and the opening portion 529_2B overlapping with the electrode 551B (see FIG. 23).

### [Step S14]

In Step S14, the layer 529_1 in a portion overlapping with the opening portion 529_2A and the layer 529_1 in a portion overlapping with the opening portion 529_2B are removed by a dry etching method using the layer 529_2.

### [Step S15]

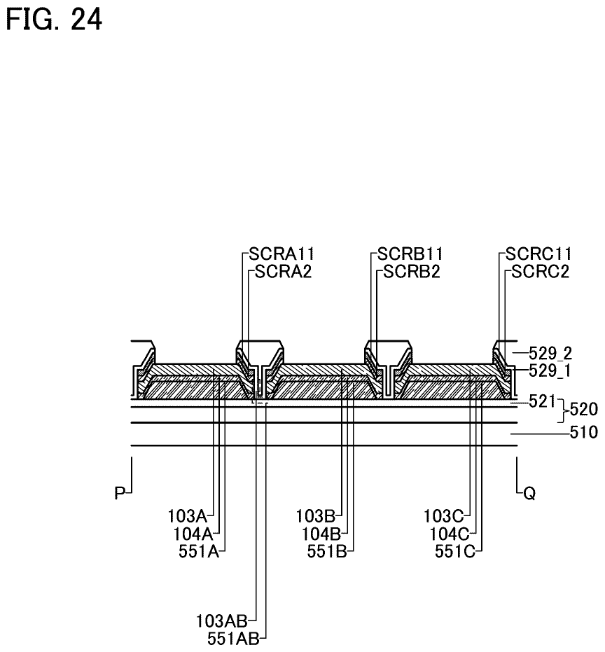

In Step S15, the layer SCRA11 and the layer SCRA2 each in a portion overlapping with the opening portion 529_2A are removed, and the layer SCRB11 and the layer SCRB2 each in a portion overlapping with the opening portion 529_2B are removed, by an etching method using the layer 529_2 (see FIG. 24).

### [Step S16]

In Step S16, the layer 105 is formed over the units 103A and 103B.

### [Step S17]

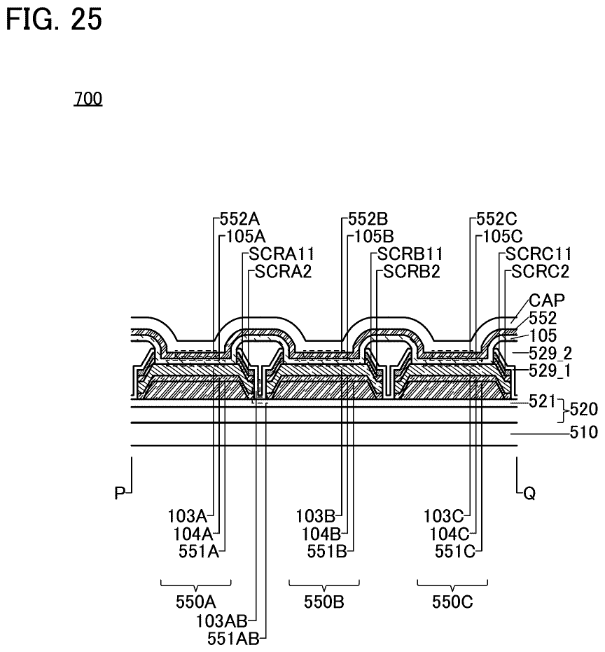

In Step S17, the conductive film 552 is formed over the layer 105 (see FIG. 25).

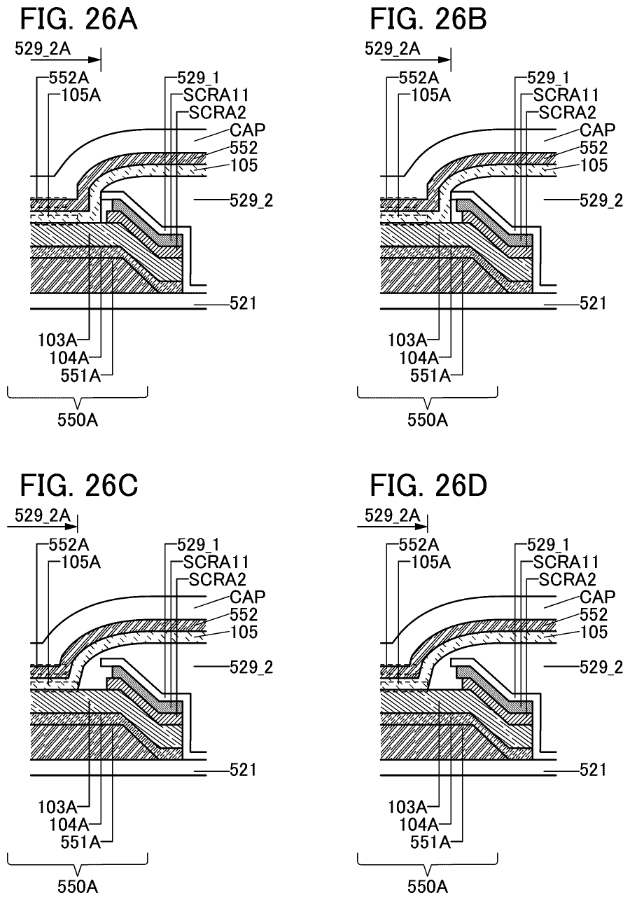

The end portion of the layer 529_2 surrounding the opening portion 529_2A is aligned with the end portion of the layer 5291 in some cases (see FIG. 26A and FIG. 26B). Opening portions larger than the opening portion formed in the layer 529_1 are formed in the layer SCRA11 and the layer SCRA2 in some cases.

In some cases, an opening portion formed in the layer SCRA2 is smaller than an opening portion formed in the layer SCRA11 (see FIG. 26A); in other cases, an opening portion formed in the layer SCRA2 is larger than an opening portion formed in the layer SCRA11 (see FIG. 26B).

Furthermore, opening portions larger than the opening portion 529_2A are formed in the layer SCRA11 and the layer SCRA2 in some cases. For example, in Step S18 following the Step S14, the layer 529_2 can be made to have fluidity so as to be in contact with the layer SCRA2. Specifically, the layer 5292 is softened by heating the workpiece, thereby being able to have fluidity (see FIG. 26C and FIG. 26D).

Note that this embodiment can be combined with any of the other embodiments in this specification as appropriate.

### Embodiment 3

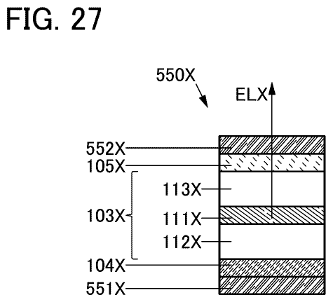

In this embodiment, a structure of a light-emitting device which can be used for a display device of one embodiment of the present invention will be described with reference to FIG. 27.

FIG. 27 is a diagram illustrating a structure of a light-emitting device which can be used for a display device of one embodiment of the present invention.

A light-emitting device 550X described in this embodiment has a structure that can be employed for a display device of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### <Structure Example of Light-Emitting Device 550X>

The light-emitting device 550X described in this embodiment includes an electrode 551X, an electrode 552X, and a unit 103X. The electrode 552X overlaps with the electrode 551X, and the unit 103X is positioned between the electrode 552X and the electrode 551X.

### <Structure Example of Unit 103X>

The unit 103X has a single-layer structure or a stacked-layer structure. The unit 103X includes a layer 111X, a layer 112X, and a layer 113X, for example (see FIG. 27). The unit 103X has a function of emitting light ELX.

The layer 111X is positioned between the layer 113X and the layer 112X, the layer 113X is positioned between the electrode 552X and the layer 111X, and the layer 112X is positioned between the layer 111X and the electrode 551X.

For example, a layer selected from functional layers such as a light-emitting layer, a hole-transport layer, an electron-transport layer, and a carrier-blocking layer can be used for the unit 103X. A layer selected from functional layers such as a hole-injection layer, an electron-injection layer, an exciton-blocking layer, and a charge-generation layer can also be used for the unit 103X.

### <<Structure Example of Layer 112X>>

A hole-transport material can be used for the layer 112X, for example. The layer 112X can be referred to as a hole-transport layer. A material having a wider bandgap than the light-emitting material contained in the layer 111X is preferably used for the layer 112X. In that case, transfer of energy from excitons generated in the layer 111X to the layer 112X can be inhibited.

### [Hole-Transport Material]

A material having a hole mobility of 1×10⁻⁶ cm²/Vs or higher can be suitably used as the hole-transport material.

As the hole-transport material, an amine compound or an organic compound having a π-electron rich heteroaromatic ring skeleton can be used, for example. Specifically, a compound having an aromatic amine skeleton, a compound having a carbazole skeleton, a compound having a thiophene skeleton, a compound having a furan skeleton, or the like can be used. The compound having an aromatic amine skeleton and the compound having a carbazole skeleton are particularly preferable because these compounds are highly reliable and have high hole-transport properties to contribute to a reduction in driving voltage.

The following are examples that can be used as a compound having an aromatic amine skeleton: 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF).

As a compound having a carbazole skeleton, for example, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP) can be used.

As a compound having a thiophene skeleton, for example, 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV) can be used.

As a compound having a furan skeleton, for example, 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II) can be used.

### <<Structure Example of Layer 113X>>

An electron-transport material, a material having an anthracene skeleton, and a mixed material can be used for the layer 113X, for example. The layer 113X can be referred to as an electron-transport layer. A material having a wider bandgap than the light-emitting material contained in the layer 111X is preferably used for the layer 113X. In that case, transfer of energy from excitons generated in the layer 111X to the layer 113X can be inhibited.

### [Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the electron-transport property in the electron-transport layer can be suppressed. The amount of electrons injected into the light-emitting layer can be controlled. The light-emitting layer can be prevented from having excess electrons.

For example, a metal complex or an organic compound having a π-electron deficient heteroaromatic ring skeleton can be used as the electron-transport material.

As a metal complex, bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ) can be used, for example.

As an organic compound having a π-electron deficient heteroaromatic ring skeleton, a heterocyclic compound having a polyazole skeleton, a heterocyclic compound having a diazine skeleton, a heterocyclic compound having a pyridine skeleton, a heterocyclic compound having a triazine skeleton, or the like can be used, for example. In particular, the heterocyclic compound having a diazine skeleton or the heterocyclic compound having a pyridine skeleton has favorable reliability and thus is preferable. In addition, the heterocyclic compound having a diazine (pyrimidine or pyrazine) skeleton has a high electron-transport property to contribute to a reduction in driving voltage.

As a heterocyclic compound having a polyazole skeleton, 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II) can be used, for example.

As a heterocyclic compound having a diazine skeleton, 2-[3-(dibenzothiophen-4-yl)phenyl]dibenzo[f,h]quinoxaline (abbreviation: 2mDBTPDBq-II), 2-[3-(3′-(dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), or 4,8-bis[3-(dibenzothiophen-4-yl)phenyl]benzo[h]quinazoline (abbreviation: 4,8mDBtP2Bqn) can be used, for example.

As a heterocyclic compound having a pyridine skeleton, 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB) can be used, for example.

As a heterocyclic compound having a triazine skeleton, 2-[3′-(9,9-dimethyl-9H-fluoren-2-yl)biphenyl-3-yl]-4,6-diphenyl-1,3,5-triazine (abbreviation: mFBPTzn), 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), or 2-{3-[3-(benzo[b]naphtho[1,2-d]furan-6-yl)phenyl]phenyl}-4,6-diphenyl-1,3,5-triazine (abbreviation: mBnfBPTzn-02) can be used, for example.

### [Material Having Anthracene Skeleton]

An organic compound having an anthracene skeleton can be used for the layer 113X. In particular, an organic compound having both an anthracene skeleton and a heterocyclic skeleton can be suitably used.

For example, an organic compound having both an anthracene skeleton and a nitrogen-containing five-membered ring skeleton can be used for the layer 113X. Alternatively, an organic compound having both an anthracene skeleton and a nitrogen-containing five-membered ring skeleton where two heteroatoms are included in a ring can be used for the layer 113X. Specifically, it is preferable to use, as the heterocyclic skeleton, a pyrazole ring, an imidazole ring, an oxazole ring, a thiazole ring, or the like.

For example, an organic compound having both an anthracene skeleton and a nitrogen-containing six-membered ring skeleton can be used for the layer 113X. Alternatively, an organic compound having both an anthracene skeleton and a nitrogen-containing six-membered ring skeleton where two heteroatoms are included in a ring can be used for the layer 113X. Specifically, it is preferable to use, as the heterocyclic skeleton, a pyrazine ring, a pyrimidine ring, a pyridazine ring, or the like.

### [Structure Example of Mixed Material]

A material in which a plurality of kinds of substances are mixed can be used for the layer 113X. Specifically, a mixed material which contains an alkali metal, an alkali metal compound, or an alkali metal complex and an electron-transport substance can be used for the layer 113X. Note that the electron-transport material preferably has a HOMO level of −6.0 eV or higher.

The mixed material can be suitably used for the layer 113X in combination with a structure using a composite material, which will be described in Embodiment 4, for a layer 104X. For example, a composite material of an electron-accepting substance and a hole-transport material can be used for the layer 104X. Specifically, a composite material of an electron-accepting substance and a substance having a relatively deep HOMO level HM1, which is higher than or equal to −5.7 eV and lower than or equal to −5.4 eV, can be used for the layer 104X. Using the mixed material for the layer 113X in combination with the structure using such a composite material for the layer 104X leads to an increase in the reliability of the light-emitting device.

Furthermore, a structure using a hole-transport material for the layer 112X is preferably combined with the structure using the mixed material for the layer 113X and the composite material for the layer 104X. For example, a substance having a HOMO level HM2, which differs by −0.2 eV to 0 eV inclusive from the relatively deep HOMO level HM1, can be used for the layer 112X. This leads to an increase in the reliability of the light-emitting device. Note that in this specification and the like, the structure of the above-described light-emitting device may be referred to as a Recombination-Site Tailoring Injection structure (ReSTI structure).

The concentration of the alkali metal, the alkali metal compound, or the alkali metal complex preferably changes in the thickness direction of the layer 113X (including the case where the concentration is 0).

For example, a metal complex having an 8-hydroxyquinolinato structure can be used. A methyl-substituted product of the metal complex having an 8-hydroxyquinolinato structure (e.g., a 2-methyl-substituted product or a 5-methyl-substituted product) or the like can also be used.

As the metal complex having an 8-hydroxyquinolinato structure, 8-hydroxyquinolinato-lithium (abbreviation: Liq), 8-hydroxyquinolinato-sodium (abbreviation: Naq), or the like can be used. In particular, a complex of a monovalent metal ion, especially a complex of lithium is preferable, and Liq is further preferable.

### <<Structure Example 1 of Layer 111X>>

Either a structure containing a light-emitting material or a structure containing a light-emitting material and a host material can be employed for the layer 111X, for example. The layer 111X can be referred to as a light-emitting layer. The layer 111X is preferably provided in a region where holes and electrons are recombined. This allows efficient conversion of energy generated by recombination of carriers into light and emission of the light.

Furthermore, the layer 111X is preferably provided apart from a metal used for the electrode or the like. In that case, a quenching phenomenon caused by the metal used for the electrode or the like can be inhibited.

It is preferable that a distance from an electrode or the like having reflectivity to the layer 111X be adjusted and the layer 111X be placed in an appropriate position in accordance with an emission wavelength. With this structure, the amplitude can be increased by utilizing an interference phenomenon between light reflected by the electrode or the like and light emitted from the layer 111X. Light with a predetermined wavelength can be intensified and the spectrum of the light can be narrowed. In addition, bright light emission colors with high intensity can be obtained. In other words, the layer 111X is placed in an appropriate position between electrodes and the like, and thus a microcavity structure can be formed.

For example, a fluorescent substance, a phosphorescent substance, or a substance exhibiting thermally activated delayed fluorescence (TADF) (also referred to as a TADF material) can be used for the light-emitting material. Thus, energy generated by recombination of carriers can be released as the light ELX from the light-emitting material (see FIG. 27).

### [Fluorescent Substance]

A fluorescent substance can be used for the layer 111X. For example, fluorescent substances exemplified below can be used for the layer 111X. Note that fluorescent substances that can be used for the layer 111X are not limited to the following, and a variety of known fluorescent substances can be used for the layer 111X.

Specifically, any of the following fluorescent substances can be used: 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra(tert-butyl)perylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N,N′-(pyrene-1,6-diyl)bis[(6,N-diphenylbenzo[b]naphtho[1,2-d]furan)-8-amine](abbreviation: 1,6BnfAPrn-03), N,N′-diphenyl-N,N′-bis(9-phenyl-9H-carbazol-2-yl)naphtho[2,3-b;6,7-b′]bisbenzofuran-3,10-diamine (abbreviation: 3,10PCA2Nbf(IV)-02), 3,10-bis[N-(dibenzofuran-3-yl)-N-phenylamino]naphtho[2,3-b;6,7-b′]bisbenzofuran (abbreviation: 3,10FrA2Nbf(IV)-02), and the like.

Condensed aromatic diamine compounds typified by pyrenediamine compounds such as 1,6FLPAPrn, 1,6mMemFLPAPrn, and 1,6BnfAPrn-03 are particularly preferable because they have high hole-trapping properties and have high emission efficiency or high reliability.

Other examples of fluorescent substances include N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, 9,10-diphenyl-[N-phenyl-N-(9-phenyl-carbazol-3-yl)-amino]-anthracene (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracene-2-amine (abbreviation: 2YGABPhA), N,N,9-triphenylanthracene-9-amine (abbreviation: DPhAPhA), coumarin 545T, N,N′-diphenylquinacridone (abbreviation: DPQd), rubrene, and 5,12-bis(biphenyl-4-yl)-6,11-diphenyltetracene (abbreviation: BPT).

Other examples of fluorescent substances include 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3, 6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), and 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM).

[Phosphorescent substance]

A phosphorescent substance can be used for the layer 111X. For example, phosphorescent substances exemplified below can be used for the layer 111X. Note that phosphorescent substances that can be used for the layer 111X are not limited to the following, and a variety of known phosphorescent substances can be used for the layer 111X.

For example, any of the following can be used for the layer 111X: an organometallic iridium complex having a 4H-triazole skeleton, an organometallic iridium complex having a 1H-triazole skeleton, an organometallic iridium complex having an imidazole skeleton, an organometallic iridium complex having a phenylpyridine derivative with an electron-withdrawing group as a ligand, an organometallic iridium complex having a pyrimidine skeleton, an organometallic iridium complex having a pyrazine skeleton, an organometallic iridium complex having a pyridine skeleton, a rare earth metal complex, a platinum complex, and the like.

### [Phosphorescent Substance (Blue)]

As an organometallic iridium complex having a 4H-triazole skeleton or the like, tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris[4-(3-biphenyl)-5-isopropyl-3-phenyl-4H-1,2,4-triazolato]iridium(III) (abbreviation: [Ir(iPrptz-3b)₃]), or the like can be used.

As an organometallic iridium complex having a 1H-triazole skeleton or the like, tris[3-methyl-1-(2-methylphenyl)-5-phenyl-1H-1,2,4-triazolato]iridium(III) (abbreviation: [Ir(Mptz1-mp)₃]), tris(1-methyl-5-phenyl-3-propyl-1H-1,2,4-triazolato)iridium(III) (abbreviation: [Ir(Prptz1-Me)₃]), or the like can be used.

As an organometallic iridium complex having an imidazole skeleton or the like, fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), or the like can be used.

As an organometallic iridium complex having a phenylpyridine derivative with an electron-withdrawing group as a ligand, or the like, bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: Ir(CF₃ppy)₂(pic)), bis[2-(4′,6′-difluorophenyl)pyridinato-N,C²′]iridium(III) acetylacetonate (abbreviation: FIracac), or the like can be used.

These substances are compounds exhibiting blue phosphorescence and having an emission wavelength peak at 440 nm to 520 nm.

### [Phosphorescent Substance (Green)]

As an organometallic iridium complex having a pyrimidine skeleton or the like, tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis(4,6-diphenylpyrimidinato)iridium(III) (abbreviation: [Ir(dppm)₂(acac)]), or the like can be used.

As an organometallic iridium complex having a pyrazine skeleton or the like, (acetylacetonato)bis(3,5-dimethyl-2-phenylpyrazinato)iridium(III) (abbreviation: [Ir(mppr-Me)₂(acac)]), (acetylacetonato)bis(5-isopropyl-3-methyl-2-phenylpyrazinato)iridium(III) (abbreviation: [Ir(mppr-iPr)₂(acac)]), or the like can be used.

As an organometallic iridium complex having a pyridine skeleton or the like, tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: [Ir(5mppy-d3)₂(mbfpypy-d₃)]), [2-d₃-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy-d₃)]), or the like can be used.

Examples of a rare earth metal complex are tris(acetylacetonato) (monophenanthroline)terbium(III) (abbreviation: [Tb(acac)₃(Phen)]), and the like.

These are compounds that mainly exhibit green phosphorescence and have an emission wavelength peak at 500 nm to 600 nm. Note that an organometallic iridium complex having a pyrimidine skeleton has distinctively high reliability or emission efficiency.

### [Phosphorescent Substance (Red)]

As an organometallic iridium complex having a pyrimidine skeleton or the like, (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(d1npm)₂(dpm)]), or the like can be used.

As an organometallic iridium complex having a pyrazine skeleton or the like, (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), (acetylacetonato)bis[2,3-bis(4-fluorophenyl)quinoxalinato]iridium(III) (abbreviation: [Ir(Fdpq)₂(acac)]), or the like can be used.

As an organometallic iridium complex having a pyridine skeleton or the like, tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), or the like can be used.

As a rare earth metal complex or the like, tris(1,3-diphenyl-1,3-propanedionato)(monophenanthroline)europium(III) (abbreviation: [Eu(DBM)₃(Phen)]), tris[1-(2-thenoyl)-3,3,3-trifluoroacetonato](monophenanthroline)europium(III) (abbreviation: [Eu(TTA)₃(Phen)]), or the like can be used.

As a platinum complex or the like, 2,3,7,8,12,13,17,18-octaethyl-21H,23H-porphyrin platinum(II) (abbreviation: PtOEP) or the like can be used.

These are compounds that exhibit red phosphorescence and have an emission peak at 600 nm to 700 nm. Furthermore, the organometallic iridium complexes having a pyrazine skeleton can provide red light emission with chromaticity favorably used for display devices.

### [Substance Exhibiting Thermally Activated Delayed Fluorescence (TADF)]

A TADF material can be used for the layer 111X. When a TADF material is used as the light-emitting substance, the S1 level of a host material is preferably higher than that of the TADF material. In addition, the T₁ level of the host material is preferably higher than that of the TADF material.

For example, any of the TADF materials exemplified below can be used as the light-emitting material. Note that without being limited thereto, a variety of known TADF materials can be used.

In the TADF material, the difference between the S1 level and the T1 level is small, and reverse intersystem crossing (upconversion) from the triplet excited state into the singlet excited state can be achieved by a small amount of thermal energy. Thus, the singlet excited state can be efficiently generated from the triplet excited state. In addition, the triplet excitation energy can be converted into luminescence.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

Examples of the TADF material include a fullerene, a derivative thereof, an acridine, a derivative thereof, and an eosin derivative. Furthermore, porphyrin containing a metal such as magnesium (Mg), zinc (Zn), cadmium (Cd), tin (Sn), platinum (Pt), indium (In), or palladium (Pd) can be also used as the TADF material.

Specifically, the following materials whose structural formulae are shown below can be used: a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), an octaethylporphyrin-platinum chloride complex (PtCl₂OEP), and the like.

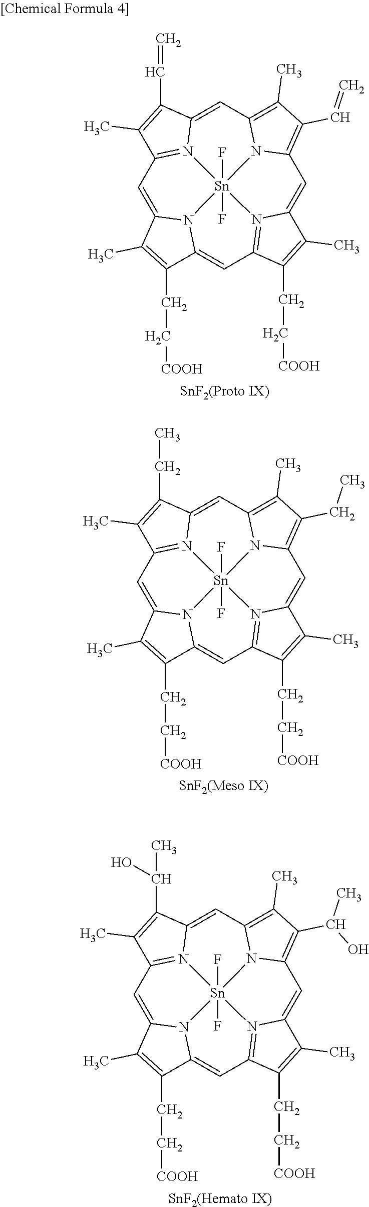

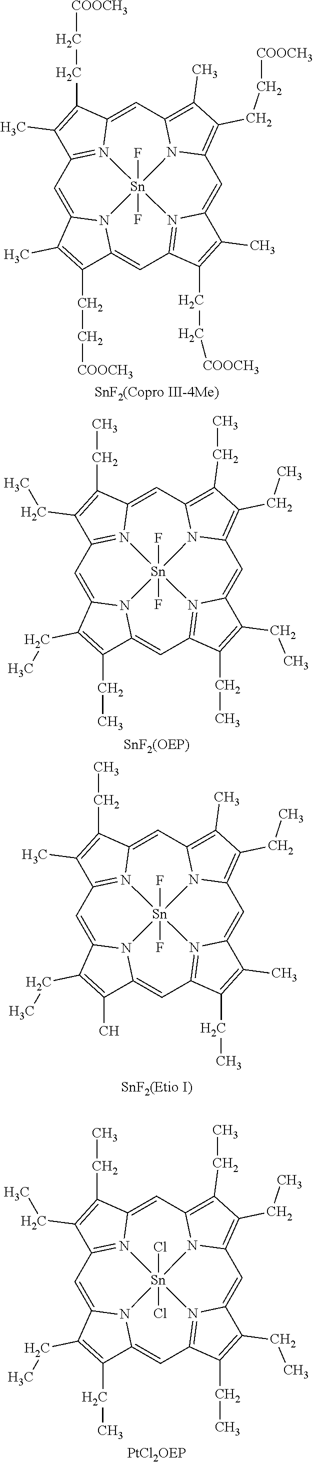

Furthermore, a heterocyclic compound including one or both of a rc-electron rich heteroaromatic ring and a π-electron deficient heteroaromatic ring can be used, for example, as the TADF material.

Specifically, the following compounds whose structural formulae are shown below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), and the like.

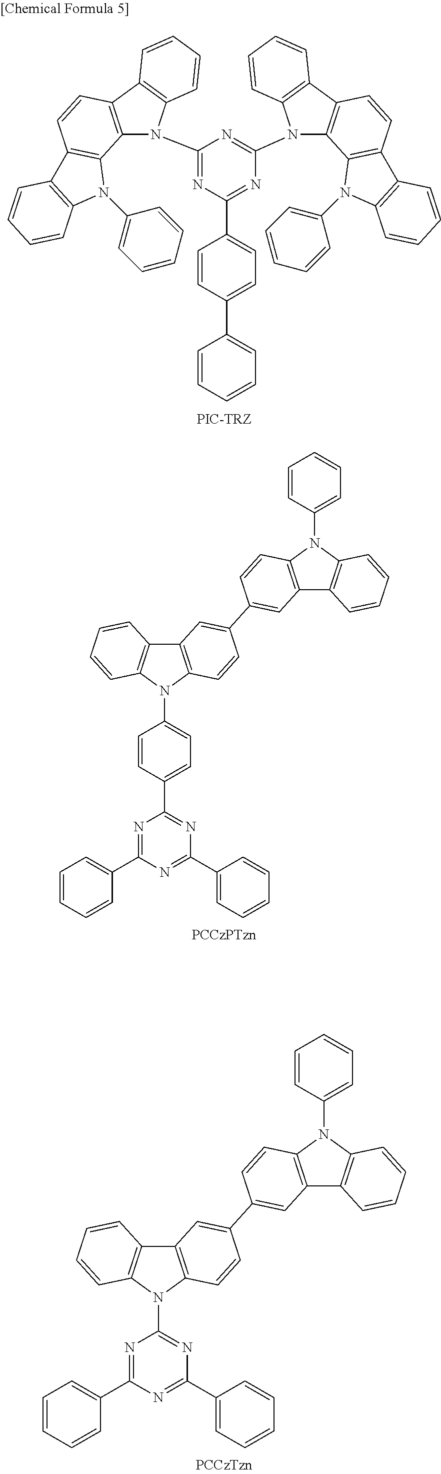 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

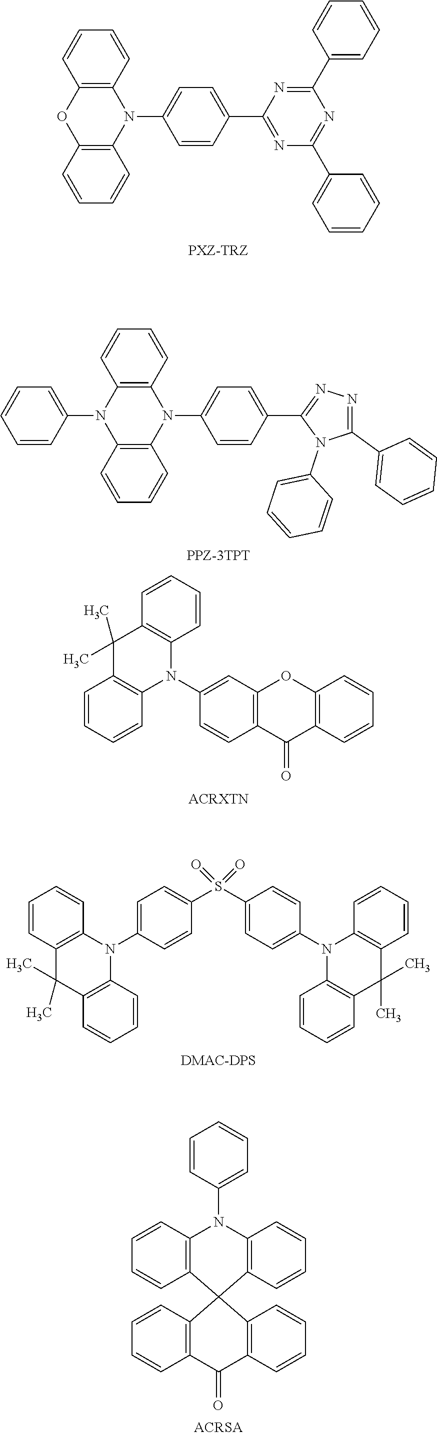

Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, in particular, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and high reliability.

Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used.

As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane and boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used.

As described above, a π-electron deficient skeleton and a if-electron rich skeleton can be used instead of at least one of the π-electron deficient heteroaromatic ring and the π-electron rich heteroaromatic ring.

### <<Structure Example 2 of Layer 111X>>

A carrier-transport material can be used as the host material. For example, a hole-transport material, an electron-transport material, a substance exhibiting thermally activated delayed fluorescence (TADF), a material having an anthracene skeleton, or a mixed material can be used as the host material. A material having a wider bandgap than the light-emitting material contained in the layer 111X is preferably used as the host material. Thus, transfer of energy from excitons generated in the layer 111X to the host material can be inhibited.

### [Hole-Transport Material]

A material having a hole mobility of 1×10⁻⁶ cm²/Vs or higher can be suitably used as the hole-transport material. For example, a hole-transport material that can be used for the layer 112X can be used for the layer 111X.

### [Electron-Transport Material]

A metal complex or an organic compound having a π-electron deficient heteroaromatic ring skeleton can be used as the electron-transport material. For example, an electron-transport material that can be used for the layer 113X can be used for the layer 111X.

### [Material Having Anthracene Skeleton]

An organic compound having an anthracene skeleton can be used as the host material. An organic compound having an anthracene skeleton is particularly preferable in the case where a fluorescent substance is used as the light-emitting substance. Thus, a light-emitting device with high emission efficiency and high durability can be obtained.

Among the organic compounds having an anthracene skeleton, an organic compound having a diphenylanthracene skeleton, in particular, a 9,10-diphenylanthracene skeleton, is chemically stable and thus is preferable. The host material preferably has a carbazole skeleton because the hole-injection and hole-transport properties are improved. In particular, the host material preferably has a dibenzocarbazole skeleton because the HOMO level thereof is shallower than that of a host material having a carbazole skeleton by approximately 0.1 eV so that holes enter the host material easily, the hole-transport property is improved, and the heat resistance is increased. Note that in terms of the hole-injection and hole-transport properties, instead of a carbazole skeleton, a benzofluorene skeleton or a dibenzofluorene skeleton may be used.

Thus, a substance having both a 9,10-diphenylanthracene skeleton and a carbazole skeleton, a substance having both a 9,10-diphenylanthracene skeleton and a benzocarbazole skeleton, or a substance having both a 9,10-diphenylanthracene skeleton and a dibenzocarbazole skeleton is preferable as the host material.

Examples of the substances that can be used include 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: α,N-βNPAnth), 9-[4-(9-phenylcalbazol-3-yl)]phenyl-10-phenylanthracene (abbreviation: PCzPA), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), and 3-[4-(1-naphthyl)-phenyl]-9-phenyl-9H-carbazole (abbreviation: PCPN).

In particular, CzPA, cgDBCzPA, 2mBnfPPA, and PCzPA have excellent characteristics.

### [Substance Exhibiting Thermally Activated Delayed Fluorescence (TADF)]

A TADF material can be used as the host material. When the TADF material is used as the host material, triplet excitation energy generated in the TADF material can be converted into singlet excitation energy by reverse intersystem crossing. Moreover, excitation energy can be transferred to the light-emitting substance. In other words, the TADF material functions as an energy donor, and the light-emitting substance functions as an energy acceptor. Thus, the emission efficiency of the light-emitting device can be increased.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on the lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination.

Here, the luminophore refers to an atomic group (skeleton) that causes light emission in a fluorescent substance. The luminophore is preferably a skeleton having a π bond, further preferably includes an aromatic ring, and still further preferably includes a fused aromatic ring or a fused heteroaromatic ring.

Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. In particular, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

For example, the TADF material that can be used as the light-emitting material can be used as the host material.

### [Structure Example 1 of Mixed Material]

A material in which a plurality of kinds of substances are mixed can be used as the host material. For example, a material which includes an electron-transport material and a hole-transport material can be used as the mixed material. The weight ratio of the hole-transport material to the electron-transport material contained in the mixed material is (the hole-transport material/the electron-transport material)=(1/19) or more and (19/1) or less. Accordingly, the carrier-transport property of the layer 111X can be easily adjusted. A recombination region can also be controlled easily.

### [Structure Example 2 of Mixed Material]

In addition, a material mixed with a phosphorescent substance can be used as the host material. When a fluorescent substance is used as the light-emitting substance, a phosphorescent substance can be used as an energy donor for supplying excitation energy to the fluorescent substance.

### [Structure Example 3 of Mixed Material]

A mixed material containing a material to form an exciplex can be used as the host material. For example, a material in which an emission spectrum of a formed exciplex overlaps with a wavelength on the lowest-energy-side absorption band of the light-emitting substance can be used as the host material. This enables smooth energy transfer and improves emission efficiency. The driving voltage can be suppressed. With such a structure, light emission can be efficiently obtained by exciplex-triplet energy transfer (ExTET), which is energy transfer from the exciplex to the light-emitting substance (phosphorescent material).

A phosphorescent substance can be used as at least one of the materials forming an exciplex. Accordingly, reverse intersystem crossing can be used. Triplet excitation energy can be efficiently converted into singlet excitation energy.

Combination of an electron-transport material and a hole-transport material whose HOMO level is higher than or equal to that of the electron-transport material is preferable for forming an exciplex. The LUMO level of the hole-transport material is preferably higher than or equal to the LUMO level of the electron-transport material. Thus, an exciplex can be efficiently formed. Note that the LUMO levels and the HOMO levels of the materials can be derived from the electrochemical characteristics (the reduction potentials and the oxidation potentials). Specifically, the reduction potentials and the oxidation potentials can be measured by cyclic voltammetry (CV).

The formation of an exciplex can be confirmed by a phenomenon in which the emission spectrum of the mixed film in which the hole-transport material and the electron-transport material are mixed is shifted to the longer wavelength side than the emission spectrum of each of the hole-transport material and the electron-transport material (or has another peak on the longer wavelength side) observed by comparison of the emission spectra of the hole- and electron-transport materials and the mixed materials, for example. Alternatively, the formation of an exciplex can be confirmed by a difference in transient response, such as a phenomenon in which the transient photoluminescence (PL) of the mixed film exhibits longer lifetime components or a larger proportion of delayed components in terms of lifetime than the transient PL of each of the hole-transport and electron-transport materials, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

Note that this embodiment can be combined with any of the other embodiments in this specification as appropriate.

### Embodiment 4

In this embodiment, a structure of a light-emitting device which can be used for a display device of one embodiment of the present invention will be described with reference to FIG. 27.

The structure of the light-emitting device 550X described in this embodiment can be employed for a display device of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### <Structure Example of Light-Emitting Device 550X>

The light-emitting device 550X described in this embodiment includes the electrode 551X, the electrode 552X, the unit 103X, and the layer 104X. The electrode 552X overlaps with the electrode 551X, and the unit 103X is positioned between the electrode 552X and the electrode 551X. The layer 104X is positioned between the electrode 551X and the unit 103X. For example, the structure described in Embodiment 3 can be used for the unit 103X.

### <Structure Example of Electrode 551X>

For example, a conductive material can be used for the electrode 551X. Specifically, a single layer or a stack using a metal, an alloy, or a film containing a conductive compound can be used for the electrode 551X.

A film that efficiently reflects light can be used for the electrode 551X, for example. Specifically, an alloy containing silver, copper, and the like, an alloy containing silver, palladium, and the like, or a metal film of aluminum or the like can be used for the electrode 551X.

For example, a metal film that transmits part of light and reflects another part of light can be used for the electrode 551X. Thus, a microcavity structure can be provided in the light-emitting device 550X. Alternatively, light with a predetermined wavelength can be extracted more efficiently than light with the other wavelengths. Alternatively, light with a narrow spectral width at half maximum can be extracted. Alternatively, light of a bright color can be extracted.

For example, a film having a property of transmitting visible light can be used for the electrode 551X. Specifically, a single layer or a stack using a metal film, an alloy film, a conductive oxide film, or the like that is thin enough to transmit light can be used for the electrode 551X.

In particular, a material having a work function higher than or equal to 4.0 eV can be suitably used for the electrode 551X.

For example, a conductive oxide containing indium can be used. Specifically, indium oxide, indium-tin oxide (abbreviation: ITO), indium-tin oxide containing silicon or silicon oxide (abbreviation: ITSO), indium-zinc oxide, indium oxide containing tungsten oxide and zinc oxide (abbreviation: IWZO), or the like can be used.

For another example, a conductive oxide containing zinc can be used. Specifically, zinc oxide, zinc oxide to which gallium is added, zinc oxide to which aluminum is added, or the like can be used.

Furthermore, for example, gold (Au), platinum (Pt), nickel (Ni), tungsten (W), chromium (Cr), molybdenum (Mo), iron (Fe), cobalt (Co), copper (Cu), palladium (Pd), or a nitride of a metal material (e.g., titanium nitride) can be used. Graphene can also be used.

### <<Structure Example 1 of Layer 104X>>

A hole-injection material can be used for the layer 104X, for example. The layer 104X can be referred to as a hole-injection layer.

For example, a material having a hole mobility lower than or equal to 1×10⁻³ cm²/Vs when the square root of the electric field strength [V/cm] is 600 can be used for the layer 104X. A film having an electrical resistivity greater than or equal to 1×10⁴ Ω·cm and less than or equal to 1×10⁷ Ω·cm can be used as the layer 104X. The electrical resistivity of the layer 104X is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### <<Structure Example 2 of Layer 104X>>

Specifically, an electron-accepting substance can be used for the layer 104X. Alternatively, a composite material containing a plurality of kinds of substances can be used for the layer 104X. This can facilitate the injection of holes from the electrode 551X, for example. Alternatively, the driving voltage of the light-emitting device 550X can be reduced.

### [Electron-Accepting Substance]

An organic compound or an inorganic compound can be used as the electron-accepting substance. The electron-accepting substance can extract electrons from an adjacent hole-transport layer or a hole-transport material by the application of an electric field.

For example, a compound having an electron-withdrawing group (a halogen group or a cyano group) can be used as the electron-accepting substance. Note that an electron-accepting organic compound is easily evaporated, which facilitates film deposition. Thus, the productivity of the light-emitting device 550X can be increased.

Specifically, 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), 2-(7-dicyanomethylene-1,3,4,5,6,8,9,10-octafluoro-7H-pyren-2-ylidene)malononitrile, or the like can be used.

A compound in which electron-withdrawing groups are bonded to a condensed aromatic ring having a plurality of heteroatoms, such as HAT-CN, is particularly preferable because it is thermally stable.

A [3]radialene derivative having an electron-withdrawing group (in particular, a cyano group or a halogen group such as a fluoro group) has a very high electron-accepting property and thus is preferred.

Specifically, α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], α,α′,α″-1,2,3-cyclopropanetriylidenetris[2,3,4,5,6-pentafluorobenzeneacetonitrile], or the like can be used.

For the electron-accepting substance, a transition metal oxide such as a molybdenum oxide, a vanadium oxide, a ruthenium oxide, a tungsten oxide, or a manganese oxide can be used.

It is possible to use any of the following materials: phthalocyanine-based compounds such as phthalocyanine (abbreviation: H₂Pc); phthalocyanine-based complex compounds such as copper(II) phthalocyanine (abbreviation: CuPc); and compounds having an aromatic amine skeleton such as 4,4′-bis[N-(4-diphenylaminophenyl)-N-phenylamino]biphenyl (abbreviation: DPAB) and N,N′-bis[4-bis(3-methylphenyl)aminophenyl]-N,N′-diphenyl-4,4′-diaminobiphenyl (abbreviation: DNTPD).

In addition, high molecular compounds such as poly(3,4-ethylenedioxythiophene)/polystyrenesulfonic acid (abbreviation: PEDOT/PSS), and the like can be used.

### [Structure Example 1 of Composite Material]

For example, a composite material containing an electron-accepting substance and a hole-transport material can be used for the layer 104X. Accordingly, not only a material having a high work function but also a material having a low work function can also be used for the electrode 551X. Alternatively, a material used for the electrode 551X can be selected from a wide range of materials regardless of its work function.

For the hole-transport material in the composite material, for example, a compound having an aromatic amine skeleton, a carbazole derivative, an aromatic hydrocarbon, an aromatic hydrocarbon having a vinyl group, or a high molecular compound (such as an oligomer, a dendrimer, or a polymer) can be used. A material having a hole mobility of 1×10⁻⁶ cm²/Vs or higher can be suitably used as the hole-transport material in the composite material. For example, the hole-transport material that can be used for the layer 112X can be used for the composite material.

A substance having a relatively deep HOMO level can be suitably used as the hole-transport material in the composite material. Specifically, the HOMO level is preferably higher than or equal to −5.7 eV and lower than or equal to −5.4 eV. Accordingly, hole injection to the unit 103X can be facilitated. Hole injection to the layer 112X can be facilitated. The reliability of the light-emitting device 550X can be increased.

As the compound having an aromatic amine skeleton, for example, N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N′-bis[4-bis(3-methylphenyl)aminophenyl]-N,N′-diphenyl-4,4′-diaminobiphenyl (abbreviation: DNTPD), or 1,3,5-tris[N-(4-diphenylaminophenyl)-N-phenylamino]benzene (abbreviation: DPA3B) can be used.

As the carbazole derivative, for example, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), or 1,4-bis[4-(N-carbazolyl)phenyl]-2,3,5,6-tetraphenylbenzene can be used.

As the aromatic hydrocarbon, for example, 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, 2,5,8,11-tetra(tert-butyl)perylene, pentacene, or coronene can be used.

As the aromatic hydrocarbon having a vinyl group, for example, 4,4′-bis(2,2-diphenylvinyl)biphenyl (abbreviation: DPVBi) or 9,10-bis[4-(2,2-diphenylvinyl)phenyl]anthracene (abbreviation: DPVPA) can be used.

As the high molecular compound, for example, poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl)methacrylamide](abbreviation: PTPDMA), or poly[N,N′-bis(4-butylphenyl)-N,N′-bis(phenyl)benzidine](abbreviation: Poly-TPD) can be used.

Furthermore, a substance having any of a carbazole skeleton, a dibenzofuran skeleton, a dibenzothiophene skeleton, and an anthracene skeleton can be suitably used as the hole-transport material in the composite material, for example. Moreover, a substance including any of the following can be used as the hole-transport material in the composite material: an aromatic amine having a substituent that includes a dibenzofuran ring or a dibenzothiophene ring, an aromatic monoamine that includes a naphthalene ring, and an aromatic monoamine in which a 9-fluorenyl group is bonded to nitrogen of amine through an arylene group. With use of a substance including an N,N-bis(4-biphenyl)amino group, the reliability of the light-emitting device 550X can be increased.

Specific examples of the material having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAβNB-03), 4,4′-diphenyl-4″-(6;2′-binaphthyl-2-yl)triphenylamine (abbreviation: BBA(β8N2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBi/INB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

### [Structure Example 2 of Composite Material]

For example, a composite material including an electron-accepting substance, a hole-transport material, and a fluoride of an alkali metal or a fluoride of an alkaline earth metal can be used as the hole-injection material. In particular, a composite material in which the proportion of fluorine atoms is higher than or equal to 20% can be suitably used. Thus, the refractive index of the layer 104X can be reduced. A layer with a low refractive index can be formed inside the light-emitting device 550X. The external quantum efficiency of the light-emitting device 550X can be improved.

Note that this embodiment can be combined with any of the other embodiments in this specification as appropriate.

### Embodiment 5

In this embodiment, a structure of a light-emitting device which can be used for a display device of one embodiment of the present invention will be described with reference to FIG. 27.

The structure of the light-emitting device 550X described in this embodiment can be employed for a display device of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### <Structure Example of Light-Emitting Device 550X>

The light-emitting device 550X described in this embodiment includes the electrode 551X, the electrode 552X, the unit 103X, and the layer 105X. The electrode 552X includes a region overlapping with the electrode 551X, and the unit 103X includes a region positioned between the electrode 551X and the electrode 552X. The layer 105X includes a region positioned between the unit 103X and the electrode 552X. For example, the structure described in Embodiment 3 can be used for the unit 103X.

### <Structure Example of Electrode 552X>

For example, a conductive material can be used for the electrode 552X. Specifically, a single layer or a stack using a metal, an alloy, or a material containing a conductive compound can be used for the electrode 552X.

The material that can be used for the electrode 551X described in Embodiment 4 can be used for the electrode 552X, for example. In particular, a material having a lower work function than the electrode 551X can be suitably used for the electrode 552X. Specifically, a material having a work function lower than or equal to 3.8 eV is preferably used.

For example, an element belonging to Group 1 of the periodic table, an element belonging to Group 2 of the periodic table, a rare earth metal, or an alloy containing any of these elements can be used for the electrode 552X.

Specifically, an element such as lithium (Li) or cesium (Cs), an element such as magnesium (Mg), calcium (Ca), or strontium (Sr), an element such as europium (Eu) or ytterbium (Yb), or an alloy containing any of these elements such as an alloy of magnesium and silver or an alloy of aluminum and lithium can be used for the electrode 552X.

### <<Structure Example of Layer 105X>>

An electron-injection material can be used for the layer 105X, for example. The layer 105X can be referred to as an electron-injection layer.

Specifically, an electron-donating substance can be used for the layer 105X. Alternatively, a material in which an electron-donating substance and an electron-transport material are combined can be used for the layer 105X. Alternatively, electride can be used for the layer 105X. This can facilitate the injection of electrons from the electrode 552X, for example. Alternatively, not only a material having a low work function but also a material having a high work function can also be used for the electrode 552X. Alternatively, a material used for the electrode 552X can be selected from a wide range of materials regardless of its work function. Specifically, aluminum (Al), silver (Ag), indium-tin oxide (abbreviation: ITO), indium-tin oxide containing silicon or silicon oxide, or the like can be used for the electrode 552X. Alternatively, the driving voltage of the light-emitting device 550X can be reduced.

[Electron-donating substance]

For example, an alkali metal, an alkaline earth metal, a rare earth metal, or a compound thereof (an oxide, a halide, a carbonate, or the like) can be used as the electron-donating substance. Alternatively, an organic compound such as tetrathianaphthacene (abbreviation: TTN), nickelocene, or decamethylnickelocene can be used as the electron-donating substance.

As an alkali metal compound (including an oxide, a halide, and a carbonate), lithium oxide, lithium fluoride (LiF), cesium fluoride (CsF), lithium carbonate, cesium carbonate, 8-hydroxyquinolinato-lithium (abbreviation: Liq), or the like can be used.

As an alkaline earth metal compound (including an oxide, a halide, and a carbonate), calcium fluoride (CaF₂) or the like can be used.

### [Structure Example 1 of Composite Material]

A material composed of two or more kinds of substances can be used as the electron-injection material. For example, an electron-donating substance and an electron-transport material can be used for the composite material.

### [Electron-Transport Material]

For example, a material having an electron mobility higher than or equal to 1×10⁻⁷ cm²/Vs and lower than or equal to 5×10⁻⁵ cm²/Vs when the square root of the electric field strength [V/cm] is 600 can be suitably used as the electron-transport material. In this case, the amount of electrons injected into the light-emitting layer can be controlled. The light-emitting layer can be prevented from having excess electrons.

A metal complex or an organic compound having a π-electron deficient heteroaromatic ring skeleton can be used as the electron-transport material. For example, an electron-transport material that can be used for the layer 113X can be used for the layer 105X.

### [Structure Example 2 of Composite Material]

A material including a fluoride of an alkali metal in a microcrystalline state and an electron-transport material can be used for the composite material. Alternatively, a material including a fluoride of an alkaline earth metal in a microcrystalline state and an electron-transport material can be used for the composite material. In particular, a composite material including a fluoride of an alkali metal or a fluoride of an alkaline earth metal at 50 wt % or higher can be suitably used. Alternatively, a composite material including an organic compound having a bipyridine skeleton can be suitably used. Thus, the refractive index of the layer 105X can be reduced. The external quantum efficiency of the light-emitting device 550X can be improved.

### [Structure Example 3 of Composite Material]

For example, a composite material of a first organic compound including an unshared electron pair and a first metal can be used for the layer 105X. The sum of the number of electrons of the first organic compound and the number of electrons of the first metal is preferably an odd number. The molar ratio of the first metal to 1 mol of the first organic compound is preferably greater than or equal to 0.1 and less than or equal to 10, further preferably greater than or equal to 0.2 and less than or equal to 2, still further preferably greater than or equal to 0.2 and less than or equal to 0.8.

Accordingly, the first organic compound including an unshared electron pair interacts with the first metal and thus can form a singly occupied molecular orbital (SOMO). Furthermore, in the case where electrons are injected from the electrode 552X into the layer 105X, a barrier therebetween can be reduced.

The layer 105X can adopt a composite material that allows the spin density measured by an electron spin resonance (ESR) method to be preferably greater than or equal to 1×10¹⁶ spins/cm³, further preferably greater than or equal to 5×10¹⁶ spins/cm³, still further preferably greater than or equal to 1×10¹⁷ spins/cm³.

### [Organic Compound Including Unshared Electron Pair]

For example, an electron-transport material can be used for the organic compound including an unshared electron pair. For example, a compound having an electron deficient heteroaromatic ring can be used. Specifically, a compound with at least one of a pyridine ring, a diazine ring (a pyrimidine ring, a pyrazine ring, and a pyridazine ring), and a triazine ring can be used. Accordingly, the driving voltage of the light-emitting device 550X can be reduced.

Note that the lowest unoccupied molecular orbital (LUMO) level of the organic compound including an unshared electron pair is preferably higher than or equal to −3.6 eV and lower than or equal to −2.3 eV. In general, the HOMO level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris(3′-(pyridin-3-yl)biphenyl-3-yl)-1,3,5-triazine (abbreviation: TmPPPyTz), 2,2′-(1,3-phenylene)bis(9-phenyl-1,10-phenanthroline) (abbreviation: mPPhen2P), or the like can be used as the organic compound including an unshared electron pair. Note that NBPhen has a higher glass transition temperature (Tg) than BPhen and thus has high heat resistance.

Alternatively, for example, copper phthalocyanine can be used as the organic compound including an unshared electron pair. The number of electrons of the copper phthalocyanine is an odd number.

### [First Metal]

When the number of electrons of the first organic compound including an unshared electron pair is an even number, for example, a composite material of the first organic compound and the metal that belongs to an odd-numbered group in the periodic table can be used for the layer 105X.

For example, manganese (Mn), which is a metal belonging to Group 7, cobalt (Co), which is a metal belonging to Group 9, copper (Cu), silver (Ag), and gold (Au), which are metals belonging to Group 11, aluminum (Al) and indium (In), which are metals belonging to Group 13 are odd-numbered groups in the periodic table. Note that elements belonging to Group 11 have a lower melting point than elements belonging to Group 7 or Group 9 and thus are suitable for vacuum evaporation. In particular, Ag is preferable because of its low melting point. By using a metal having a low reactivity with water or oxygen as the first metal, the moisture resistance of the light-emitting device 550X can be improved.

The use of Ag for the electrode 552X and the layer 105X can increase the adhesion between the layer 105X and the electrode 552X.

When the number of electrons of the first organic compound including an unshared electron pair is an odd number, a composite material of the first organic compound and the first metal that belongs to an even-numbered group in the periodic table can be used for the layer 105X. For example, iron (Fe), which is a metal belonging to Group 8, is an element belonging to an even-numbered group in the periodic table.

### [Electride]

For example, a substance obtained by adding electrons at high concentration to an oxide where calcium and aluminum are mixed can be used, for example, as the electron-injection material.

Note that this embodiment can be combined with any of the other embodiments in this specification as appropriate.

### Embodiment 6

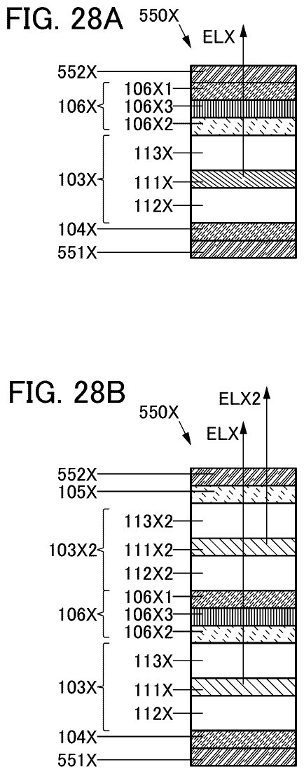

In this embodiment, a structure of a light-emitting device which can be used for a display device of one embodiment of the present invention will be described with reference to FIG. 28A.

FIG. 28A is a cross-sectional view illustrating a structure of a light-emitting device which can be used for a display device of one embodiment of the present invention.

The structure of the light-emitting device 550X described in this embodiment can be employed for a display device of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### <Structure Example of Light-Emitting Device 550X >

The light-emitting device 550X described in this embodiment includes the electrode 551X, the electrode 552X, the unit 103X, and an intermediate layer 106X (see FIG. 28A). The electrode 552X includes a region overlapping with the electrode 551X, and the unit 103X includes a region positioned between the electrode 551X and the electrode 552X. The intermediate layer 106X includes a region positioned between the electrode 552X and the unit 103X.

### <<Structure Example 1 of Intermediate Layer 106X>>

The intermediate layer 106X has a function of supplying electrons to the anode side and supplying holes to the cathode side when voltage is applied. The intermediate layer 106X can be referred to as a charge-generation layer.

For example, the hole-injection material that can be used for the layer 104X described in Embodiment 4 can be used for the intermediate layer 106X. Specifically, the composite material can be used for the intermediate layer 106X.

Alternatively, for example, a stacked-layer film in which a film containing the composite material and a film containing a hole-transport material are stacked can be used for the intermediate layer 106X. Note that the film containing a hole-transport material is positioned between the film containing the composite material and the cathode.

### <<Structure Example 2 of Intermediate Layer 106X>>

A stacked-layer film in which a layer 106X1 and a layer 106X2 are stacked can be used for the intermediate layer 106X. The layer 106X1 includes a region positioned between the unit 103X and the electrode 552X and the layer 106X2 includes a region positioned between the unit 103X and the layer 106X1.

### <<Structure Example of Layer 106X1>>

For example, the hole-injection material that can be used for the layer 104X described in Embodiment 4 can be used for the layer 106X1. Specifically, the composite material can be used for the layer 106X1. A film having an electrical resistivity greater than or equal to 1×10⁴ Ω·cm and less than or equal to 1×10⁷ Ω·cm can be used as the layer 106X1. The electrical resistivity of the layer 106X1 is preferably greater than or equal to 5×10⁴ Ω·cm and less than or equal to 1×10⁷ Ω·cm, further preferably greater than or equal to 1×10⁵ Ω·cm and less than or equal to 1×10⁷ Ω·cm.

### <<Structure Example of Layer 106X2>>

For example, the material that can be used for the layer 105X described in Embodiment 5 can be used for the layer 106X2.

### <<Structure Example 3 of Intermediate Layer 106X>>

A stacked-layer film in which the layer 106X1, the layer 106X2, and a layer 106X3 are stacked can be used for the intermediate layer 106X. The layer 106X3 includes a region positioned between the layer 106X1 and the layer 106X2.

### <<Structure Example of Layer 106X3>>

For example, an electron-transport material can be used for the layer 106X3. The layer 106X3 can be referred to as an electron-relay layer. With the layer 106X3, a layer that is on the anode side and in contact with the layer 106X3 can be distanced from a layer that is on the cathode side and in contact with the layer 106X3. Interaction between the layer that is on the anode side and in contact with the layer 106X3 and the layer that is on the cathode side and in contact with the layer 106X3 can be reduced. Electrons can be smoothly supplied to the layer that is on the anode side and in contact with the layer 106X3.

A substance whose LUMO level is positioned between the LUMO level of an electron-accepting substance contained in the layer 106X1 and the LUMO level of the substance contained in the layer 106X2 can be suitably used for the layer 106X3.

For example, a material having a LUMO level in a range higher than or equal to −5.0 eV, preferably higher than or equal to −5.0 eV and lower than or equal to −3.0 eV, can be used for the layer 106X3.

Specifically, a phthalocyanine-based material can be used for the layer 106X3. For example, copper(II) phthalocyanine (abbreviation: CuPc) or a metal complex having a metal-oxygen bond and an aromatic ligand can be used for the layer 106X3.

Note that this embodiment can be combined with any of the other embodiments in this specification as appropriate.

### Embodiment 7

In this embodiment, a structure of a light-emitting device which can be used for a display device of one embodiment of the present invention will be described with reference to FIG. 28B.

FIG. 28B is a diagram illustrating a structure of a light-emitting device which can be used for a display device of one embodiment of the present invention.

The structure of the light-emitting device 550X described in this embodiment can be employed for a display device of one embodiment of the present invention. Note that the description of the structure of the light-emitting device 550X can be referred to for the light-emitting device 550A. Specifically, the description of the light-emitting device 550X can be used for the description of the light-emitting device 550A by replacing “X” in the reference numerals of the components of the light-emitting device 550X with “A”. Similarly, the structure of the light-emitting device 550X can be employed for the light-emitting device 550B or the light-emitting device 550C by replacing “X” with “B” or “C”.

### <Structure Example of Light-Emitting Device 550X >

The light-emitting device 550X described in this embodiment includes the electrode 551X, the electrode 552X, the unit 103X, the intermediate layer 106X, and a unit 103X2 (see FIG. 28B).

The unit 103X is positioned between the electrode 552X and the electrode 551X, and the intermediate layer 106X is positioned between the electrode 552X and the unit 103X.

The unit 103X2 is positioned between the electrode 552X and the intermediate layer 106X. The unit 103X2 has a function of emitting light ELX2.

In other words, the light-emitting device 550X includes the stacked units between the electrode 551X and the electrode 552X. The number of stacked units is not limited to two and may be three or more. A structure including the stacked units positioned between the electrode 551X and the electrode 552X and the intermediate layer 106X positioned between the units is referred to as a stacked light-emitting device or a tandem light-emitting device in some cases.

This structure enables high luminance emission while the current density is kept low. Reliability can be improved. The driving voltage can be reduced in comparison with that of the light-emitting device with the same luminance. The power consumption can be reduced.

### <<Structure Example 1 of Unit 103X2>>

The unit 103X2 has a single-layer structure or a stacked-layer structure. The unit 103X2 includes a layer 111X2, a layer 112X2, and a layer 113X2, for example.

The layer 111X2 is positioned between the layer 112X2 and the layer 113X2, the layer 113X2 is positioned between the electrode 552X and the layer 111X2, and the layer 112X2 is positioned between the layer 111X2 and the intermediate layer 106X.

The structure that can be employed for the unit 103X can be employed for the unit 103X2. Specifically, the description of the unit 103X can be used for the description of the unit 103X2 by replacing “X” with “X2”. For example, the same structure as the unit 103X can be employed for the unit 103X2.

### <<Structure Example 2 of Unit 103X2>>

The structure that is different from the structure of the unit 103X can be employed for the unit 103X2. For example, the unit 103X2 can have a structure emitting light whose hue is different from that of light emitted from the unit 103X.

Specifically, a stack including the unit 103X emitting red light and green light and the unit 103X2 emitting blue light can be employed. With this structure, a light-emitting device emitting light of a desired color can be provided. A light-emitting device emitting white light can be provided, for example.

### <<Structure Example of Intermediate Layer 106X>>

The intermediate layer 106X has a function of supplying electrons to one of the unit 103X and the unit 103X2 and supplying holes to the other. For example, the intermediate layer 106X described in Embodiment 6 can be used.

### <Fabrication Method of Light-Emitting Device 550X>

For example, each of the electrode 551X, the electrode 552X, the unit 103X, the intermediate layer 106X, and the unit 103X2 can be formed by a dry process, a wet process, an evaporation method, a droplet discharging method, a coating method, a printing method, or the like. A formation method may differ between components of the device.

Specifically, the light-emitting device 550X can be fabricated with a vacuum evaporation apparatus, an inkjet apparatus, a coating apparatus such as a spin coater, a gravure printing apparatus, an offset printing apparatus, a screen printing apparatus, or the like.

For example, the electrode can be formed by a wet process or a sol-gel method using a paste of a metal material. In addition, an indium-zinc oxide film can be formed by a sputtering method using a target obtained by adding zinc oxide to indium oxide at a concentration higher than or equal to 1 wt % and lower than or equal to 20 wt %. Furthermore, an indium oxide film containing tungsten oxide and zinc oxide (IWZO) can be formed by a sputtering method using a target containing, with respect to indium oxide, tungsten oxide at a concentration higher than or equal to 0.5 wt % and lower than or equal to 5 wt % and zinc oxide at a concentration higher than or equal to 0.1 wt % and lower than or equal to 1 wt %.

Note that this embodiment can be combined with any of the other embodiments in this specification as appropriate.

### Embodiment 8

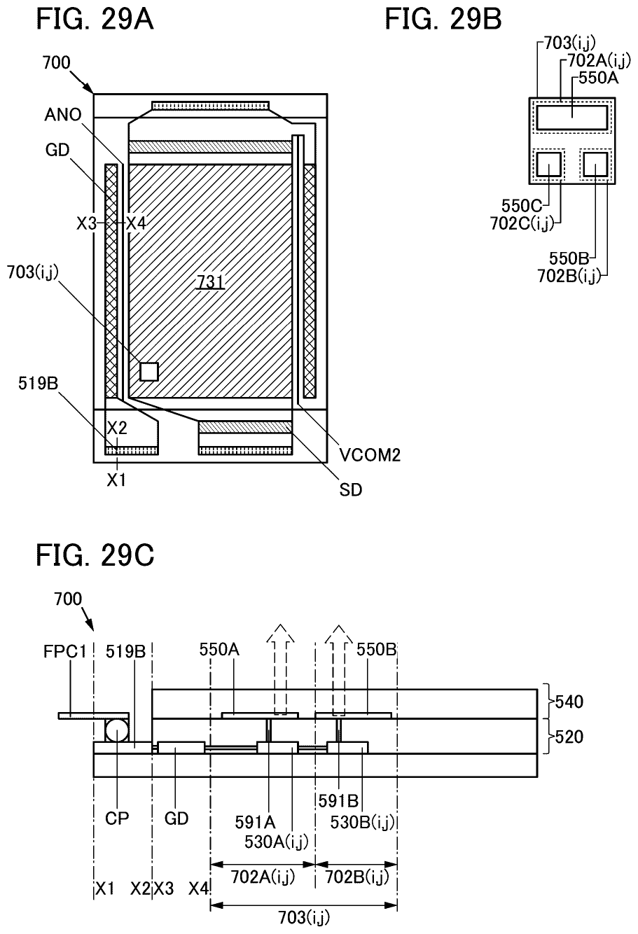

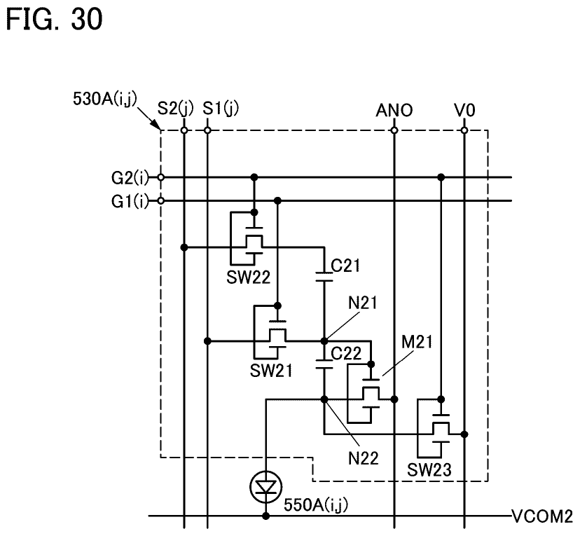

In this embodiment, a structure of a display device of one embodiment of the present invention will be described with reference to FIGS. 29A to 29C and FIG. 30.

FIGS. 29A to 29C illustrate a structure of a display device of one embodiment of the present invention. FIG. 29A is a top view of the display device of one embodiment of the present invention, and FIG. 29B is a top view illustrating part of FIG. 29A. FIG. 29C illustrates a cross section taken along cutting lines X1-X2 and X3-X4 in FIG. 29A and a cross section of a pixel set 703(i,j).

FIG. 30 is a circuit diagram illustrating the structure of the display device of one embodiment of the present invention.

In this specification, an integer variable of 1 or more may be used for reference numerals. For example, “(p)” where p is an integer variable of 1 or more may be used for part of a reference numeral that specifies any one of up top components. For another example, “(m,n)” where each of m and n is an integer variable of 1 or more may be used for part of a reference numeral that specifies any one of up to m×n components.

### <Structure Example 1 of Display Device 700>

The display device 700 of one embodiment of the present invention includes a region 731 (see FIG. 29A). The region 731 includes the pixel set 703(i,j).

<<Structure Example 1 of Pixel Set 703(i,j)>>

The pixel set 703(i,j) includes a pixel 702A(i,j), a pixel 702B(i,j), and a pixel 702C(i,j) (see FIGS. 29B and 29C).

The pixel 702A(i,j) includes a pixel circuit 530A(i,j) and the light-emitting device 550A. The light-emitting device 550A is electrically connected to the pixel circuit 530A(i,j).

For example, the light-emitting device described in any one of Embodiments 3 to 7 can be used as the light-emitting device 550A.

The pixel 702B(i,j) includes a pixel circuit 530B(i,j) and the light-emitting device 550B. The light-emitting device 550B is electrically connected to the pixel circuit 530B(i,j). Similarly, the pixel 702C(i,j) includes the light-emitting device 550C.

For example, the structures described in Embodiments 3 to 7 can be employed for the light-emitting devices 550A and 550B.

### <Structure Example 2 of Display Device 700>

The display device 700 of one embodiment of the present invention includes a functional layer 540 and the functional layer 520 (see FIG. 29C). The functional layer 540 overlaps with the functional layer 520.

The functional layer 540 includes the light-emitting device 550A.

The functional layer 520 includes the pixel circuit 530A(i,j) and a wiring (see FIG. 29C). The pixel circuit 530A(i,j) is electrically connected to the wiring. For example, a conductive film provided in an opening 591A in the functional layer 520 can be used for the wiring. The wiring electrically connects a terminal 519B to the pixel circuit 530A(i,j). Note that a conductive material CP electrically connects the terminal 519B to a flexible printed circuit board FPC1. In addition, a conductive film provided in an opening 591B in the functional layer 520 can be used for the wiring, for example.

### <Structure Example 3 of Display Device 700>

In addition, the display device 700 of one embodiment of the present invention includes a driver circuit GD and a driver circuit SD (see FIG. 29A).

### <<Structure Example of Driver Circuit GD>>

The driver circuit GD supplies a first selection signal and a second selection signal.

### <<Structure Example of Driver Circuit SD>>

The driver circuit SD supplies a first control signal and a second control signal.

### <<Structure Example of Wiring>>

As the wiring, a conductive film G1(i), a conductive film G2(i), a conductive film S1(j), a conductive film S2(j), a conductive film ANO, a conductive film VCOM2, and a conductive film V0 are included (see FIG. 30).

The conductive film G1(i) is supplied with the first selection signal, and the conductive film G2(i) is supplied with the second selection signal.

The conductive film S1(j) is supplied with the first control signal, and the conductive film S2(j) is supplied with the second control signal.

### <<Structure Example 1 of Pixel Circuit 530A(i,j)>>

The pixel circuit 530A(i,j) is electrically connected to the conductive film G1(i) and the conductive film S1(j). The conductive film G1(i) supplies the first selection signal, and the conductive film S1(j) supplies the first control signal.

The pixel circuit 530A(i,j) drives the light-emitting device 550A in response to the first selection signal and the first control signal. The light-emitting device 550A emits light.

In the light-emitting device 550A, one of the electrodes is electrically connected to the pixel circuit 530A(i,j) and the other electrode is electrically connected to the conductive film VCOM2.

### <<Structure Example 2 of Pixel Circuit 530A(i,j)>>

The pixel circuit 530A(i,j) includes a switch SW21, a switch SW22, a transistor M21, a capacitor C21, and a node N21.

The transistor M21 includes a gate electrode electrically connected to the node N21, a first electrode electrically connected to the light-emitting device 550A, and a second electrode electrically connected to the conductive film ANO.

The switch SW21 includes a first terminal electrically connected to the node N21, a second terminal electrically connected to the conductive film S1(j), and a gate electrode having a function of controlling an on/off state of the switch SW21 according to the potential of the conductive film G1(i).

The switch SW22 includes a first terminal electrically connected to the conductive film S2(j), and a gate electrode having a function of controlling an on/off state of the switch SW22 according to the potential of the conductive film G2(i).

The capacitor C21 includes a conductive film electrically connected to the node N21 and a conductive film electrically connected to a second electrode of the switch SW22.

Accordingly, an image signal can be stored in the node N21. Alternatively, the potential of the node N21 can be changed using the switch SW22. Alternatively, the intensity of light emitted from the light-emitting device 550A can be controlled with the potential of the node N21. As a result, a novel device that is highly convenient, useful, or reliable can be provided.

### <<Structure Example 3 of Pixel Circuit 530A(i,j)>>

The pixel circuit 530A(i,j) includes a switch SW23, a node N22, and a capacitor C22.

The switch SW23 includes a first terminal electrically connected to the conductive film V0, a second terminal electrically connected to the node N22, and a gate electrode having a function of controlling an on/off state of the switch SW23 according to the potential of the conductive film G2(i).

The capacitor C22 includes a conductive film electrically connected to the node N21 and a conductive film electrically connected to the node N22.

The first electrode of the transistor M21 is electrically connected to the node N22.

Note that this embodiment can be combined with any of the other embodiments in this specification as appropriate.

### Embodiment 9

In this embodiment, a display module of one embodiment of the present invention will be described.

### <Display Module>

FIG. 31 is a perspective view illustrating a structure of a display module 280.

The display module 280 includes a display portion 80, a display device 100, and an FPC 290 or a connector. The display device described in Embodiment 1 can be used as the display device 100, for example.

The FPC 290 is supplied with a signal and electric power from the outside and supplies the signal and the electric power to the display device 100. An IC may be mounted on the FPC 290. Note that a connector is a mechanical component for electrical connection through a conductor, and the conductor can electrically connect the display device 100 to a component to be connected. For example, the FPC 290 can be used as the conductor. The connector can detach the display device 100 from the connected component.

### <<Display Device 100A>>

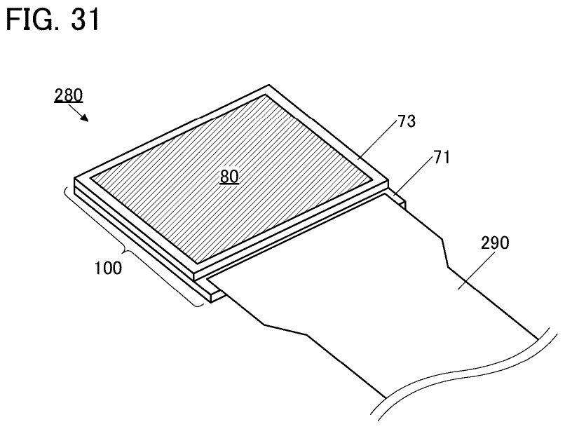

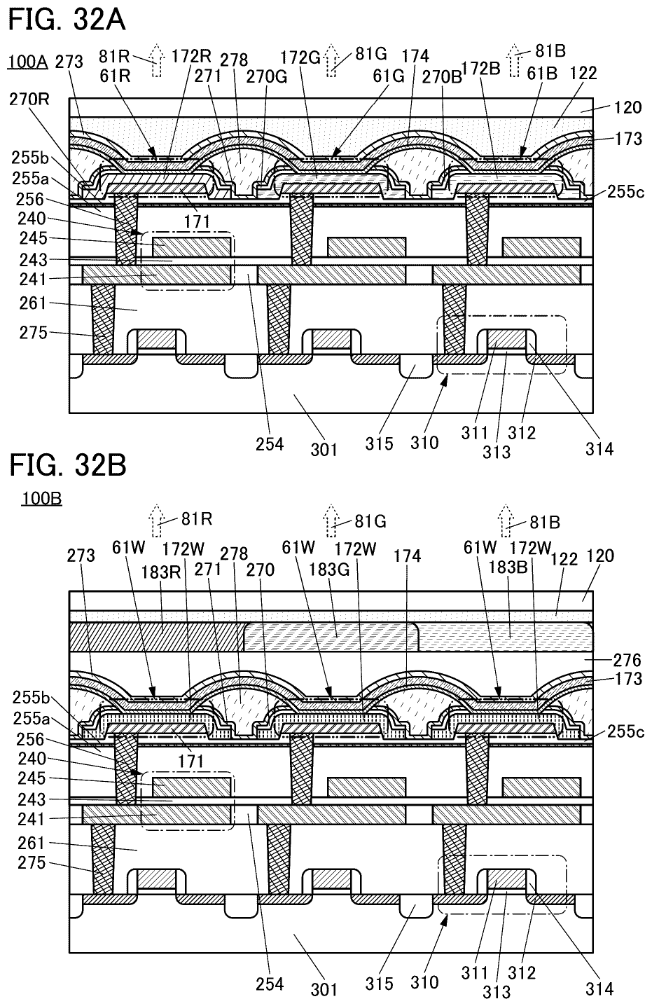

FIG. 32A is a cross-sectional view illustrating a structure of a display device 100A. The display device 100A can be used as the display device 100 of the display module 280, for example. A substrate 301 corresponds to a substrate 71 in FIG. 31.

The display device 100A includes the substrate 301, a transistor 310, an element isolation layer 315, an insulating layer 261, a capacitor 240, an insulating layer 255a, an insulating layer 255b, a light-emitting device 61R, a light-emitting device 61G, and a light-emitting device 61B. The insulating layer 261 is provided over the substrate 301, and the transistor 310 is positioned between the substrate 301 and the insulating layer 261. The insulating layer 255a is provided over the insulating layer 261, the capacitor 240 is positioned between the insulating layer 261 and the insulating layer 255a, and the insulating layer 255a is positioned between the capacitors 240 and the light-emitting devices 61R, 61G, and 61B.

### [Transistor 310]

The transistor 310 includes a conductive layer 311, a pair of low-resistance regions 312, an insulating layer 313, and an insulating layer 314, and its channel is formed in part of the substrate 301. The conductive layer 311 functions as a gate electrode. The insulating layer 313 is positioned between the substrate 301 and the conductive layer 311 and functions as a gate insulating layer. The substrate 301 includes the pair of low-resistance regions 312 doped with an impurity. Note that such regions function as a source and a drain. The side surface of the conductive layer 311 is covered with the insulating layer 314.

The element isolation layer 315 is embedded in the substrate 301, and positioned between two adjacent transistors 310.

### [Capacitor 240]

The capacitor 240 includes a conductive layer 241, a conductive layer 245, and an insulating layer 243, and the insulating layer 243 is positioned between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is positioned over the insulating layer 261 and is embedded in an insulating layer 254. The conductive layer 241 is electrically connected to one of the source and the drain of the transistor 310 through a plug 275 embedded in the insulating layer 261. The insulating layer 243 covers the conductive layer 241. The conductive layer 245 overlaps with the conductive layer 241 with the insulating layer 243 therebetween.

[Insulating Layer 255a, Insulating Layer 255b, and Insulating Layer 255c]

The display device 100A includes the insulating layer 255a, the insulating layer 255b, and an insulating layer 255c, and the insulating layer 255b is positioned between the insulating layer 255a and the insulating layer 255c.

### [Light-Emitting Device 61R, Light-Emitting Device 61G, and Light-Emitting Device 61B]

The light-emitting devices 61R, 61G, and 61B are provided over the insulating layer 255c. For example, the light-emitting device described in Embodiment 1 can be used as any of the light-emitting devices 61R, 61G, and 61B. The light-emitting devices 61R, 61G, and 61B emit light 81R, light 81G, and light 81B, respectively.

The light-emitting device 61R includes a conductive layer 171, a layer 174, a conductive layer 173, and an EL layer 172R, and the EL layer 172R covers the top and side surfaces of the conductive layer 171. The light-emitting device 61R emits the light 81R. A sacrificial layer 270R is positioned over the EL layer 172R. The light-emitting device 61G includes the conductive layer 171, the layer 174, the conductive layer 173, and an EL layer 172G, and the EL layer 172G covers the top and side surfaces of the conductive layer 171. The light-emitting device 61G emits the light 81G. A sacrificial layer 270G is positioned over the EL layer 172G. The light-emitting device 61B includes the conductive layer 171, the layer 174, the conductive layer 173, and an EL layer 172B, and the EL layer 172B covers the top and side surfaces of the conductive layer 171. The light-emitting device 61B emits the light 81B. A sacrificial layer 270B is positioned over the EL layer 172B.

The conductive layer 171 is electrically connected to one of the source and the drain of the transistor 310 through a plug 256 embedded in the insulating layers 243, 255a, 255b, and 255c, the conductive layer 241 embedded in the insulating layer 254, and the plug 275 embedded in the insulating layer 261. The top surface of the insulating layer 255c and the top surface of the plug 256 are level with or substantially level with each other. Any of a variety of conductive materials can be used for the plugs.

[Protective layer 271, insulating layer 278, protective layer 273, and bonding layer 122]

A protective layer 271 and an insulating layer 278 are positioned between adjacent light-emitting devices, e.g., between the light-emitting device 61R and the light-emitting device 61G, and the insulating layer 278 is provided over the protective layer 271. A protective layer 273 is provided over the light-emitting devices 61R, 61G, and 61B.

A bonding layer 122 attaches the protective layer 273 to a substrate 120.

### [Substrate 120]

The substrate 120 corresponds to a substrate 73 in FIG. 31. A light-blocking layer can be provided for the surface of the substrate 120 on the bonding layer 122 side, for example. A variety of optical members can be provided on the outer side of the substrate 120.

A film can be used as the substrate. In particular, a film with a low water absorption rate can be suitably used. For example, the water absorption rate is preferably 1% or lower, further preferably 0.1% or lower. Thus, a change in size of the film can be inhibited. Furthermore, generation of wrinkles or the like can be inhibited. Moreover, a change in shape of the display device can be inhibited.

For example, a polarizing plate, a retardation plate, a light diffusion layer (e.g., a diffusion film), an anti-reflection layer, a light-condensing film, or the like can be used as the optical member.

It is possible that a highly optically isotropic material, in other words, a material with a low birefringence index is used for the substrate and a circular polarizing plate is provided to overlap with the display device. For example, it is possible to use, for the substrate, a material that has an absolute value of a retardation (phase difference) of 30 nm or less, preferably 20 nm or less, further preferably 10 nm or less. For example, a triacetyl cellulose (TAC, also referred to as cellulose triacetate) film, a cycloolefin polymer (COP) film, a cycloolefin copolymer (COC) film, or an acrylic resin film can be used as a highly optically isotropic film.

Furthermore, an antistatic film inhibiting the attachment of dust, a water repellent film inhibiting the attachment of stain, a hard coat film inhibiting generation of a scratch caused by the use, an impact-absorbing layer, or the like may be provided as a surface protective layer on the outer surface of the substrate 120. For example, a glass layer, a silica layer (SiOₓ layer), DLC (diamond like carbon), aluminum oxide (AlOₓ), a polyester-based material, a polycarbonate-based material, or the like can be used for the surface protective layer. Note that a material having a high visible light transmittance can be suitably used for the surface protective layer. In addition, a material having high hardness can be suitably used for the surface protective layer.

### <<Display Device 100B>>

FIG. 32B is a cross-sectional view illustrating a structure of a display device 100B. For example, the display device 100B can be used as the display device 100 of the display module 280 (see FIG. 31).

The display device 100B includes the substrate 301, a light-emitting device 61W, the capacitor 240, and the transistor 310. The light-emitting device 61W can emit white light, for example.

The display device 100B includes a coloring layer 183R, a coloring layer 183G, and a coloring layer 183B. The coloring layer 183R has a region overlapping with one light-emitting device 61W, the coloring layer 183G has a region overlapping with another light-emitting device 61W, and the coloring layer 183B has a region overlapping with another light-emitting device 61W. The display device 100B includes a gap 276 between the light-emitting device and the coloring layer.

For example, the coloring layer 183R, the coloring layer 183G, and the coloring layer 183B can transmit red light, green light, and blue light, respectively.

### <<Display Device 100C>>

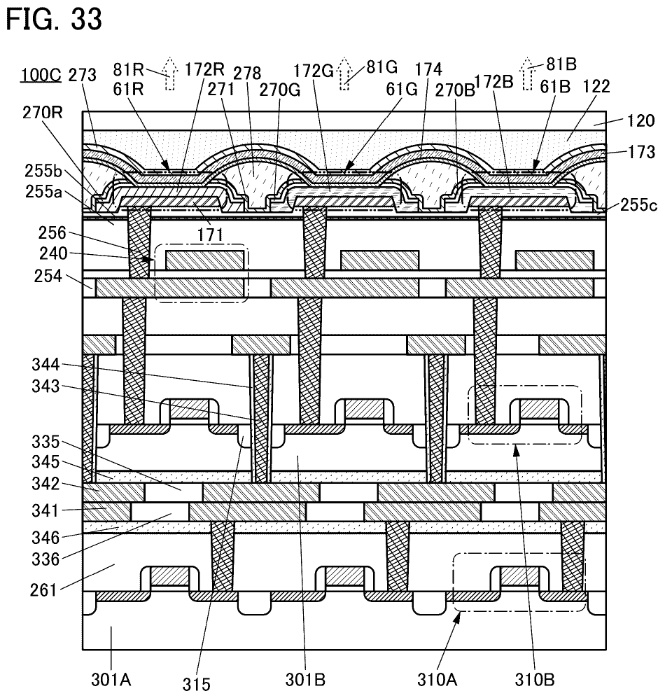

FIG. 33 is a cross-sectional view illustrating a structure of a display device 100C. The display device 100C can be used as the display device 100 of the display module 280, for example (see FIG. 31). Note that in the following description of display devices, the description of portions similar to those of the above-described display devices may be omitted.

The display device 100C includes a substrate 301B and a substrate 301A. The display device 100C includes a transistor 310B, the capacitor 240, the light-emitting devices 61R, 61G, and 61B, and a transistor 310A. A channel of the transistor 310A is formed in part of the substrate 301A and a channel of the transistor 310B is formed in part of the substrate 301B.

### [Insulating Layer 345 and Insulating Layer 346]

An insulating layer 345 is in contact with the bottom surface of the substrate 301B, and an insulating layer 346 is positioned over the insulating layer 261. For example, the inorganic insulating film that can be used as the protective layer 273 can be used as the insulating layers 345 and 346. The insulating layers 345 and 346 function as protective layers and can inhibit impurities from being diffused into the substrates 301B and 301A.

### [Plug 343]

A plug 343 penetrates the substrate 301B and the insulating layer 345. An insulating layer 344 covers the side surface of the plug 343. For example, the inorganic insulating film that can be used as the protective layer 273 can be used as the insulating layer 344. The insulating layer 344 functions as a protective layer and can inhibit impurities from being diffused into the substrate 301B.

[Conductive layer 342]

A conductive layer 342 is positioned between the insulating layer 345 and the insulating layer 346. It is preferable that the conductive layer 342 be embedded in an insulating layer 335 and a plane formed by the conductive layer 342 and the insulating layer 335 be flat. Note that the conductive layer 342 is electrically connected to the plug 343.

[Conductive layer 341]

A conductive layer 341 is positioned between the insulating layer 346 and the insulating layer 335. It is preferable that the conductive layer 341 be embedded in an insulating layer 336 and a plane formed by the conductive layer 341 and the insulating layer 336 be flat. The conductive layer 341 is bonded to the conductive layer 342. Thus, the substrate 301A is electrically connected to the substrate 301B.

The conductive layers 341 and 342 are preferably formed using the same conductive material. For example, it is possible to use a metal film containing an element selected from Al, Cr, Cu, Ta, Ti, Mo, and W, or a metal nitride film containing any of the above elements as a component (e.g., a titanium nitride film, a molybdenum nitride film, or a tungsten nitride film). Copper is particularly preferably used for the conductive layers 341 and 342. In that case, it is possible to employ copper-to-copper (Cu-to-Cu) direct bonding (a technique for achieving electrical continuity by connecting copper (Cu) pads).

### <<Display Device 100D>>

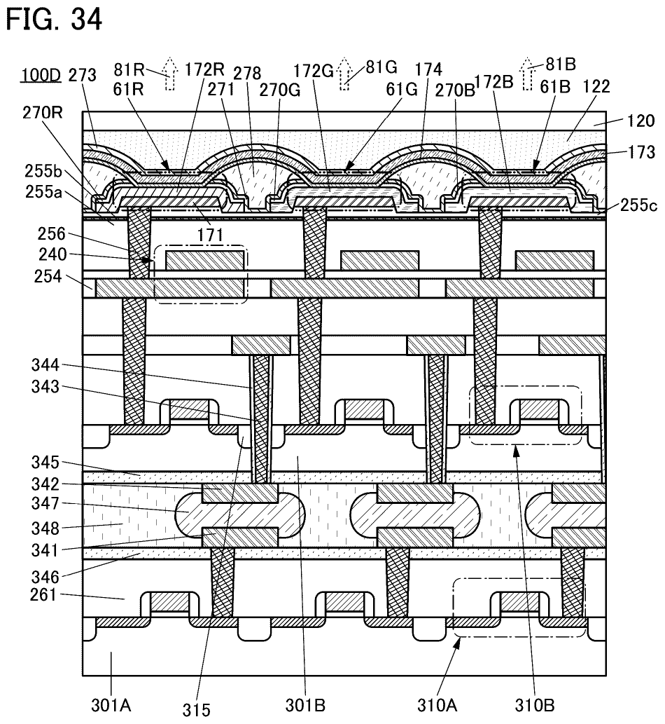

FIG. 34 is a cross-sectional view illustrating a structure of a display device 100D. The display device 100D can be used as the display device 100 of the display module 280, for example (see FIG. 31).

The display device 100D includes a bump 347, and the bump 347 bonds the conductive layer 341 to the conductive layer 342. The bump 347 electrically connects the conductive layer 341 to the conductive layer 342. The bump 347 can be formed using a conductive material containing gold (Au), nickel (Ni), indium (In), tin (Sn), or the like, for example. Solder can be used for the bump 347, for example.

The display device 100D includes a bonding layer 348. The bonding layer 348 attaches the insulating layer 345 to the insulating layer 346.

### <<Display Device 100E>>

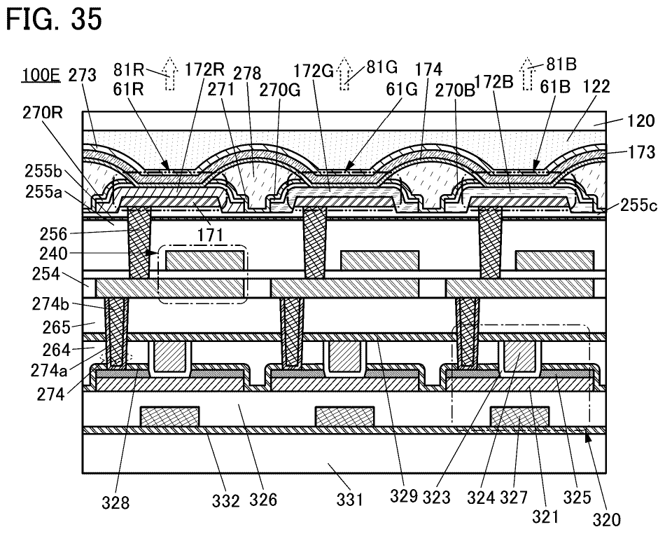

FIG. 35 is a cross-sectional view illustrating a structure of a display device 100E. The display device 100E can be used as the display device 100 of the display module 280, for example (see FIG. 31). A substrate 331 corresponds to the substrate 71 in FIG. 31. An insulating substrate or a semiconductor substrate can be used as the substrate 331. The display device 100E includes a transistor 320. Note that the display device 100E is different from the display device 100A in that the transistor is an OS transistor.

### [Insulating Layer 332]

An insulating layer 332 is provided over the substrate 331. For example, a film in which hydrogen or oxygen is less likely to be diffused than in a silicon oxide film can be used as the insulating layer 332. Specifically, an aluminum oxide film, a hafnium oxide film, a silicon nitride film, or the like can be used as the insulating layer 332. Thus, the insulating layer 332 can prevent impurities such as water and hydrogen from being diffused from the substrate 331 into the transistor 320. Furthermore, oxygen can be prevented from being released from a semiconductor layer 321 to the insulating layer 332 side.

### [Transistor 320]

The transistor 320 includes the semiconductor layer 321, an insulating layer 323, a conductive layer 324, a pair of conductive layers 325, an insulating layer 326, and a conductive layer 327.

The conductive layer 327 is provided over the insulating layer 332 and functions as a first gate electrode of the transistor 320. The insulating layer 326 covers the conductive layer 327. A part of the insulating layer 326 functions as a first gate insulating layer. The insulating layer 326 includes an oxide insulating film at least in a region in contact with the semiconductor layer 321. Specifically, a silicon oxide film or the like is preferably used. The insulating layer 326 has a flat top surface. The semiconductor layer 321 is provided over the insulating layer 326. A metal oxide film having semiconductor characteristics can be used as the semiconductor layer 321. The pair of conductive layers 325 is provided on and in contact with the semiconductor layer 321, and functions as a source electrode and a drain electrode.

### [Insulating Layer 328 and Insulating Layer 264]

An insulating layer 328 covers the top and side surfaces of the pair of conductive layers 325, the side surface of the semiconductor layer 321, and the like. An insulating layer 264 is provided over the insulating layer 328 and functions as an interlayer insulating layer. The insulating layers 328 and 264 have an opening reaching the semiconductor layer 321. For example, an insulating film similar to the insulating layer 332 can be used as the insulating layer 328. Thus, the insulating layer 328 can prevent impurities such as water or hydrogen from being diffused from the insulating layer 264 into the semiconductor layer 321. Furthermore, oxygen can be prevented from being released from the semiconductor layer 321.

### [Insulating Layer 323]

The insulating layer 323 is in contact with the side surfaces of the insulating layers 264 and 328 and the conductive layer 325 and the top surface of the semiconductor layer 321 inside the opening.

### [Conductive Layer 324]

Inside the opening, the conductive layer 324 is embedded and in contact with the insulating layer 323. The conductive layer 324 has a top surface subjected to planarization treatment, and is level with or substantially level with the top surface of the insulating layer 323 and the top surface of the insulating layer 264. The conductive layer 324 functions as a second gate electrode, and the insulating layer 323 functions as a second gate insulating layer.

### [Insulating Layer 329 and Insulating Layer 265]

An insulating layer 329 covers the conductive layer 324 and the insulating layers 323 and 264. An insulating layer 265 is provided over the insulating layer 329 and functions as an interlayer insulating layer. For example, an insulating film similar to the insulating layers 328 and 332 can be used as the insulating layer 329. Thus, impurities such as water or hydrogen can be prevented from being diffused from the insulating layer 265 into the transistor 320, for example.

### [Plug 274]

A plug 274 is embedded in the insulating layers 265, 329, 264, and 328 and is electrically connected to one of the pair of conductive layers 325. The plug 274 includes a conductive layer 274a and a conductive layer 274b. The conductive layer 274a is in contact with each of the side surfaces of openings in the insulating layers 265, 329, 264, and 328. In addition, the conductive layer 274a covers a part of the top surface of the conductive layer 325. The conductive layer 274b is in contact with the top surface of the conductive layer 274a. For example, a conductive material in which hydrogen and oxygen are less likely to be diffused can be suitably used for the conductive layer 274a.

### <<Display Device 100F>>

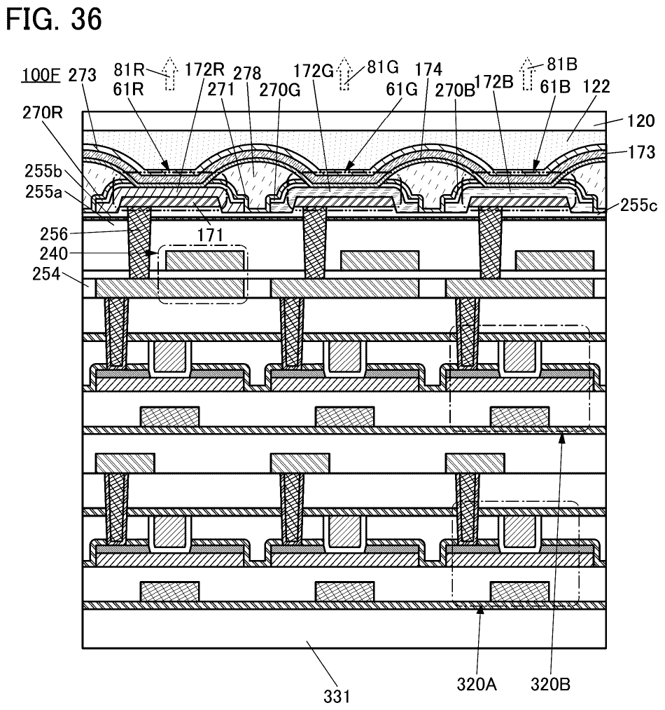

FIG. 36 is a cross-sectional view illustrating a structure of a display device 100F. The display device 100F has a structure in which a transistor 320A and a transistor 320B are stacked. Each of the transistors 320A and 320B includes an oxide semiconductor and a channel formed in the oxide semiconductor. Note that the structure of the display device 100F is not limited to the stacked-layer structure of two transistors, and may be a structure in which three or more transistors are stacked, for example.

The structures of the transistor 320A and the peripheral components are the same as those of the transistor 320 and the peripheral components of the display device 100E. The structures of the transistor 320B and the peripheral components are the same as those of the transistor 320 and the peripheral components of the display device 100E.

### <<Display Device 100G>>

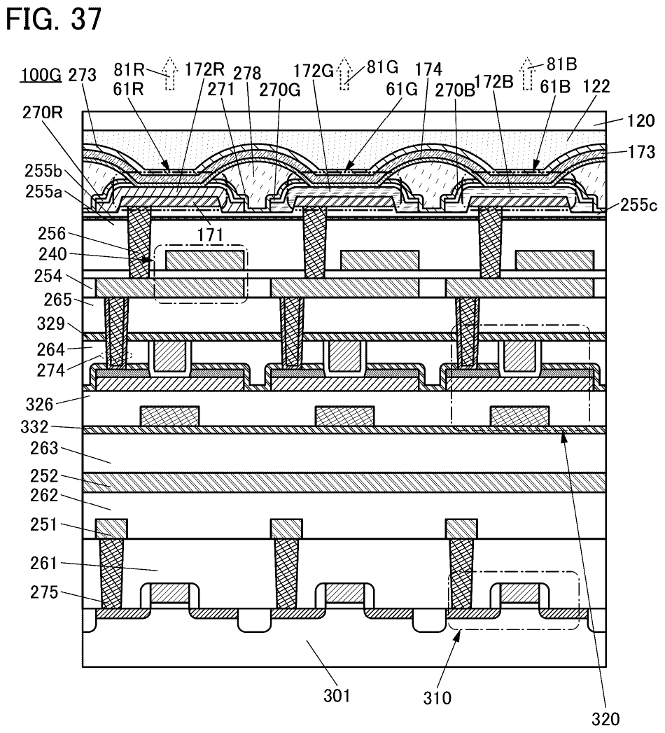

FIG. 37 is a cross-sectional view illustrating a structure of a display device 100G. The display device 100G has a structure in which the transistor 310 and the transistor 320 are stacked. The channel of the transistor 310 is formed in the substrate 301. The transistor 320 includes an oxide semiconductor and the channel formed in the oxide semiconductor.

The insulating layer 261 covers the transistor 310 and a conductive layer 251 is provided over the insulating layer 261. An insulating layer 262 covers the conductive layer 251 and a conductive layer 252 is provided over the insulating layer 262. An insulating layer 263 and the insulating layer 332 covers the conductive layer 252. The conductive layer 251 and the conductive layer 252 each function as a wiring.

The transistor 320 is provided over the insulating layer 332 and the insulating layer 265 covers the transistor 320. The capacitor 240 is provided over the insulating layer 265 and is electrically connected to the transistor 320 through the plug 274.

For example, the transistor 320 can be used as a transistor included in a pixel circuit. For another example, the transistor 310 can be used as a transistor included in a pixel circuit or for a driver circuit (e.g., a gate driver circuit or a source driver circuit) for driving the pixel circuit. The transistor 310 and the transistor 320 can be used for a variety of circuits such as an arithmetic circuit and a memory circuit. Thus, not only a pixel circuit but also a driver circuit can be provided directly under the light-emitting device, for example. The display device can be downsized as compared to the case where a driver circuit is provided around a display region.

At least part of this embodiment can be implemented in combination with any of the other embodiments described in this specification, as appropriate.

### Embodiment 10

In this embodiment, a display module of one embodiment of the present invention will be described.

### <Display Module>

FIG. 38 is a perspective view illustrating a structure of a display module.

The display module includes the display device 100, an IC (integrated circuit), and one of an FPC 177 and a connector. The display device described in Embodiment 1 can be used as the display device 100, for example.

The display device 100 is electrically connected to the IC 176 and the FPC 177. The FPC 177 is supplied with a signal and electric power from the outside and supplies the signal and the electric power to the display device 100. Note that a connector is a mechanical component for electrical connection through a conductor, and the conductor can electrically connect the display device 100 to a component to be connected. For example, the FPC 177 can be used as the conductor. The connector can detach the display device 100 from the connected component.

The display module includes the IC 176. For example, the IC 176 can be provided for a substrate 14b by a COG (chip on glass) method. Alternatively, the IC 176 can be provided for an FPC by a COF (chip on film) method, for example. Note that a gate driver circuit, a source driver circuit, or the like can be used as the IC 176.

### <<Display Device 100H>>

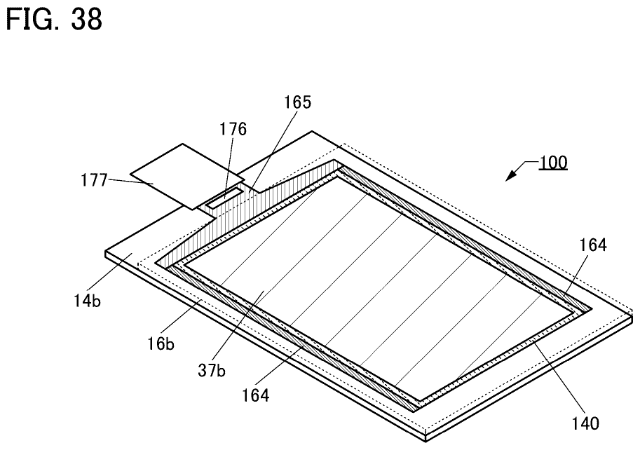

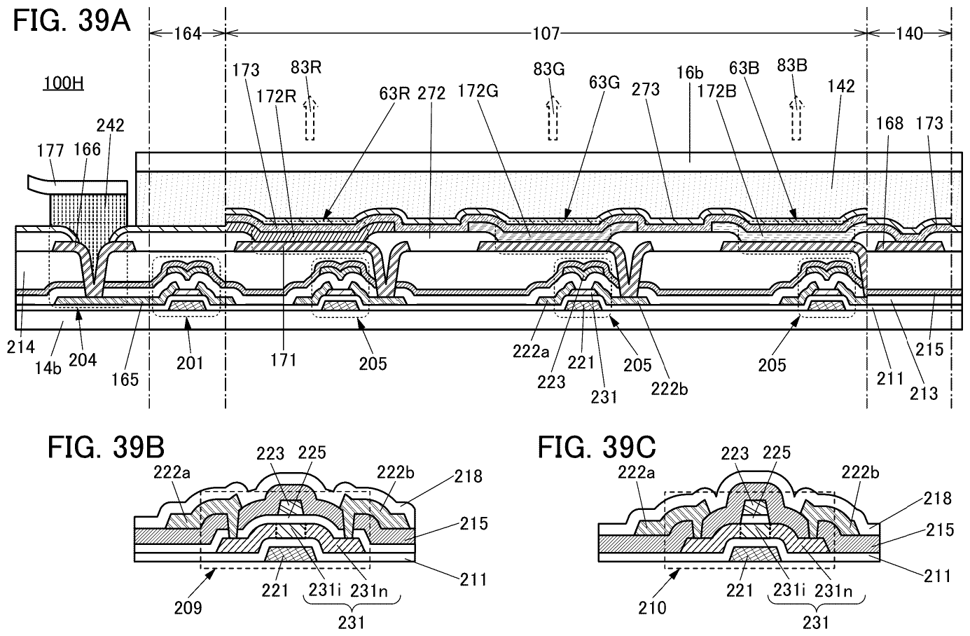

FIG. 39A is a cross-sectional view illustrating a structure of a display device 100H.

The display device 100H includes a display portion 37b, a connection portion 140, a circuit 164, a wiring 165, and the like. The display device 100H includes a substrate 16b and the substrate 14b, which are bonded to each other. The display device 100H includes one or more connection portions 140. The connection portion 140 can be provided outside the display portion 37b. For example, the connection portion 140 can be provided along one side of the display portion 37b. Alternatively, the connection portion 140 can be provided along a plurality of sides, for example, the connection portion 140 can be provided to surround four sides. In the connection portion 140, a common electrode of a light-emitting device is electrically connected to a conductive layer, which supplies a predetermined potential to the common electrode.

The wiring 165 is supplied with a signal or electric power from the FPC 177 or the IC 176. The wiring 165 supplies a signal and electric power to the display portion 37b and the circuit 164.

For example, a gate driver circuit can be used as the circuit 164.

The display device 100H includes the substrate 14b, the substrate 16b, a transistor 201, a transistor 205, a light-emitting device 63R, a light-emitting device 63G, a light-emitting device 63B, and the like (see FIG. 39A). For example, the light-emitting device 63R emits red light 83R, the light-emitting device 63G emits green light 83G, and the light-emitting device 63B emits blue light 83B. Note that a variety of optical members can be provided on the outer side of the substrate 16b. For example, a polarizing plate, a retardation plate, a light diffusion layer (e.g., a diffusion film), an anti-reflection layer, a light-condensing film, or the like can be provided.

For example, the light-emitting device described in Embodiment 1 can be used for each of the light-emitting devices 63R, 63G, and 63B.

The light-emitting device includes the conductive layer 171, which functions as a pixel electrode. The conductive layer 171 includes a recessed portion, which overlaps with an opening portion provided in an insulating layer 214, an insulating layer 215, and an insulating layer 213. The transistor 205 includes a conductive layer 222b, which is electrically connected to the conductive layer 171.

The display device 100H includes an insulating layer 272. The insulating layer 272 covers an end portion of the conductive layer 171 to fill the recessed portion of the conductive layer 171 (see FIG. 39A).

The display device 100H includes the protective layer 273 and a bonding layer 142. The protective layer 273 covers the light-emitting devices 63R, 63G, and 63B. The protective layer 273 and the substrate 16b are bonded to each other with the bonding layer 142. The bonding layer 142 fills a gap between the substrate 16b and the protective layer 273. Note that the bonding layer 142 may be formed in a frame shape so as not to overlap with the light-emitting devices and a region surrounded by the bonding layer 142, the substrate 16b, and the protective layer 273 may be filled with a resin different from the material of the bonding layer 142. Alternatively, a hollow sealing structure may be employed, in which the region is filled with an inert gas (e.g., nitrogen or argon). For example, the material that can be used for the bonding layer 122 can be used for the bonding layer 142.

The display device 100H includes the connection portion 140, which includes a conductive layer 168. Note that a power supply potential is supplied to the conductive layer 168. The light-emitting device includes a conductive layer 173. The conductive layer 168 is electrically connected to the conductive layer 173, to which a power supply potential is supplied. Note that the conductive layer 173 functions as a common electrode. For example, the conductive layer 171 and the conductive layer 168 can be formed by processing one conductive film.

The display device 100H has a top-emission structure. The light-emitting device emits light to the substrate 16b side. The conductive layer 171 contains a material reflecting visible light, and the conductive layer 173 transmits visible light.

### [Insulating Layer 211, Insulating Layer 213, Insulating Layer 215, and Insulating Layer 214]

An insulating layer 211, the insulating layer 213, the insulating layer 215, and the insulating layer 214 are provided in this order over the substrate 14b. Note that the number of insulating layers is not limited and each insulating layer may be a single layer or a stacked layer of two or more layers.

For example, an inorganic insulating film can be used as each of the insulating layers 211, 213, and 215. A silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

The insulating layers 215 and 214 cover the transistors. The insulating layer 214 functions as a planarization layer. For example, a material in which impurities such as water and hydrogen are less likely to be diffused is preferably used for the insulating layer 215 or the insulating layer 214. This can effectively inhibit impurities from being diffused to the transistors from the outside. Furthermore, the reliability of the display device can be improved.

For example, an organic insulating layer can be favorably used as the insulating layer 214. Specifically, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used for the organic insulating layer. Alternatively, the insulating layer 214 can have a stacked-layer structure of an organic insulating layer and an inorganic insulating layer. Thus, the outermost layer of the insulating layer 214 can be used as an etching protective layer. For example, in the case where a phenomenon of forming a recessed portion in the insulating layer 214 should be avoided in processing the conductive layer 171 into a predetermined shape, the phenomenon can be inhibited.

### [Transistor 201 and Transistor 205]

The transistor 201 and the transistor 205 are formed over the substrate 14b. These transistors can be fabricated using the same materials in the same steps.

Each of the transistors 201 and 205 includes a conductive layer 221, the insulating layer 211, a conductive layer 222a, the conductive layer 222b, a semiconductor layer 231, the insulating layer 213, and a conductive layer 223. The insulating layer 211 is positioned between the conductive layer 221 and the semiconductor layer 231. The conductive layer 221 functions as a gate and the insulating layer 211 functions as a first gate insulating layer. The conductive layer 222a and the conductive layer 222b function as a source and a drain. The insulating layer 213 is positioned between the conductive layer 223 and the semiconductor layer 231. The conductive layer 223 functions as a gate and the insulating layer 213 functions as a second gate insulating layer. Here, a plurality of layers obtained by processing the same conductive film are shown with the same hatching pattern.

There is no particular limitation on the structure of the transistors included in the display device of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistors 201 and 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor layer of the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferable to use a semiconductor having crystallinity, in which case deterioration of the transistor characteristics can be suppressed.

The semiconductor layer of the transistor preferably includes a metal oxide. That is, an OS transistor is preferably used as the transistor included in the display device of this embodiment.

### [Semiconductor Layer]

For example, indium oxide, gallium oxide, and zinc oxide can be used for the semiconductor layer. The metal oxide preferably contains two or three kinds selected from indium, an element M, and zinc. The element M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. Specifically, the element M is preferably one or more of aluminum, gallium, yttrium, and tin.

It is particularly preferable that an oxide containing indium (In), gallium (Ga), and zinc (Zn) (also referred to as IGZO) be used as the metal oxide used for the semiconductor layer. Alternatively, it is preferable to use an oxide containing indium, tin, and zinc (also referred to as ITZO (registered trademark)). It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the metal oxide used for the semiconductor layer is In-M-Zn oxide, the atomic ratio of In is preferably greater than or equal to the atomic ratio of Min the In-M-Zn oxide. Examples of the atomic ratio of the metal elements in such In-M-Zn oxide, In:M:Zn, are 1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the neighborhood of the atomic ratio includes ±30% of an intended atomic ratio.

For example, when the atomic ratio of In:Ga:Zn is described as 4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio of In:Ga:Zn is described as 5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio of In:Ga:Zn is described as 1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

The semiconductor layer may include two or more metal oxide layers having different compositions. For example, a stacked-layer structure of a first metal oxide layer having an atomic ratio of In:M:Zn=1:3:4 or a composition in the vicinity thereof and a second metal oxide layer having an atomic ratio of In:M:Zn=1:1:1 or a composition in the vicinity thereof and being formed over the first metal oxide layer can be favorably employed. In particular, gallium or aluminum is preferably used as the element M.

Alternatively, a stacked-layer structure of one selected from indium oxide, indium gallium oxide, and IGZO, and one selected from IAZO, IAGZO, and ITZO (registered trademark) may be employed, for example.

Examples of an oxide semiconductor having crystallinity include a CAAC-OS (c-axis-aligned crystalline oxide semiconductor) and an nc-OS (nanocrystalline oxide semiconductor).

Alternatively, a transistor including silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (also referred to as an LTPS transistor) can be used. The LTPS transistor has high field-effect mobility and excellent frequency characteristics.

With use of Si transistors such as LTPS transistors, a circuit required to be driven at a high frequency (e.g., a data driver circuit) can be formed on the same substrate as the display portion. This allows simplification of an external circuit mounted on the display device and a reduction in costs of parts and mounting costs.

An OS transistor has much higher field-effect mobility than a transistor containing amorphous silicon. In addition, the OS transistor has an extremely low leakage current between a source and a drain in an off state (hereinafter also referred to as off-state current), and charge accumulated in a capacitor that is connected in series to the transistor can be held for a long period. Furthermore, the power consumption of the display device can be reduced with the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher breakdown voltage between a source and a drain than a Si transistor; hence, a high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

When transistors are driven in a saturation region, a change in source-drain current relative to a change in gate-source voltage can be smaller in an OS transistor than in a Si transistor. Accordingly, when an OS transistor is used as the driving transistor included in the pixel circuit, a current flowing between the source and the drain can be minutely determined by controlling the gate-source voltage. Thus, the amount of current flowing through the light-emitting device can be controlled. Consequently, the number of gray levels expressed by the pixel circuit can be increased.

Regarding saturation characteristics of current flowing when transistors are driven in the saturation region, even when the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor is driven in the saturation region, the source-drain current hardly changes with an increase in the source-drain voltage. Hence, the luminance of the light-emitting device can be stable.

As described above, by using OS transistors as the driving transistors included in the pixel circuits, it is possible to inhibit black-level degradation, increase the luminance, increase the number of gray levels, and suppress variations in characteristics of light-emitting devices, for example.

The transistors included in the circuit 164 and the transistors included in the display portion 107 may have the same structure or different structures. One structure or two or more kinds of structures may be employed for a plurality of transistors included in the circuit 164. Similarly, one structure or two or more kinds of structures may be employed for a plurality of transistors included in the display portion 107.

All transistors included in the display portion 107 may be OS transistors, or all transistors included in the display portion 107 may be Si transistors. Alternatively, some of the transistors included in the display portion 107 may be OS transistors and the others may be Si transistors.

For example, when both an LTPS transistor and an OS transistor are used in the display portion 107, the display device can have low power consumption and high driving capability. Note that a structure in which an LTPS transistor and an OS transistor are used in combination is referred to as LTPO in some cases. For example, it is preferable that an OS transistor be used as a transistor functioning as a switch for controlling electrical continuity between wirings and an LTPS transistor be used as a transistor for controlling a current.

For example, one transistor included in the display portion 107 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased.

Another transistor included in the display portion 107 functions as a switch for controlling selection or non-selection of a pixel and can be referred to as a selection transistor. A gate of the selection transistor is electrically connected to a gate line, and one of a source and a drain thereof is electrically connected to a signal line. An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML structure. This structure can significantly reduce a leakage current that would flow through a transistor and a leakage current that would flow between adjacent light-emitting devices. Displaying images on the display device having this structure can bring one or more of image crispness, image sharpness, high color saturation, and a high contrast ratio to the viewer. When a leakage current that would flow through the transistor and a lateral leakage current that would flow between light-emitting devices are extremely low, display with little leakage of light at the time of black display (black-level degradation), for example, can be achieved.

In particular, current flowing between adjacent light-emitting devices having the MML structure can be extremely reduced.

### [Transistor 209 and Transistor 210]

FIGS. 39B and 39C are cross-sectional views each illustrating another example of a cross-sectional structure of a transistor that can be used for the display device 100H.

A transistor 209 and a transistor 210 each include the conductive layer 221, the insulating layer 211, the semiconductor layer 231, the conductive layer 222a, the conductive layer 222b, an insulating layer 225, the conductive layer 223, and the insulating layer 215. The semiconductor layer 231 includes a channel formation region 231i and a pair of low-resistance regions 231n. The insulating layer 211 is positioned between the conductive layer 221 and the channel formation region 231i. The conductive layer 221 functions as a gate and the insulating layer 211 functions as a first gate insulating layer. The insulating layer 225 is positioned at least between the conductive layer 223 and the channel formation region 231i. The conductive layer 223 functions as a gate, and the insulating layer 225 functions as a second gate insulating layer. The conductive layer 222a is electrically connected to one of the pair of low-resistance regions 231n and the conductive layer 222b is electrically connected to the other of the pair of low-resistance regions 231n. The insulating layer 215 covers the conductive layer 223. An insulating layer 218 covers the transistor.

### [Structure Example 1 of Insulating Layer 225]

In the transistor 209, the insulating layer 225 covers the top and side surfaces of the semiconductor layer 231 (see FIG. 39B). The insulating layer 225 and the insulating layer 215 have openings, through which the conductive layers 222a and 222b are electrically connected to the low-resistance regions 231n. One of the conductive layers 222a and 222b functions as a source, and the other functions as a drain.

### [Structure Example 2 of Insulating Layer 225]

In the transistor 210, the insulating layer 225 overlaps with the channel formation region 231i of the semiconductor layer 231 and does not overlap with the low-resistance regions 231n (see FIG. 39C). For example, the insulating layer 225 can be processed into a predetermined shape using the conductive layer 223 as a mask. The insulating layer 215 covers the insulating layer 225 and the conductive layer 223. The insulating layer 215 has opening portions, and the conductive layers 222a and 222b are electrically connected to the low-resistance regions 231n.

### [Connection Portion 204]

A connection portion 204 is provided for the substrate 14b. The connection portion 204 includes a conductive layer 166, which is electrically connected to the wiring 165. Note that the connection portion 204 does not overlap with the substrate 16b, and the conductive layer 166 is exposed. Note that the conductive layer 166 and the conductive layer 171 can be formed by processing one conductive film. The conductive layer 166 is electrically connected to the FPC 177 through a connection layer 242. As the connection layer 242, for example, an anisotropic conductive film (ACF) or an anisotropic conductive paste (ACP) can be used.

### <<Display Device 100I>>

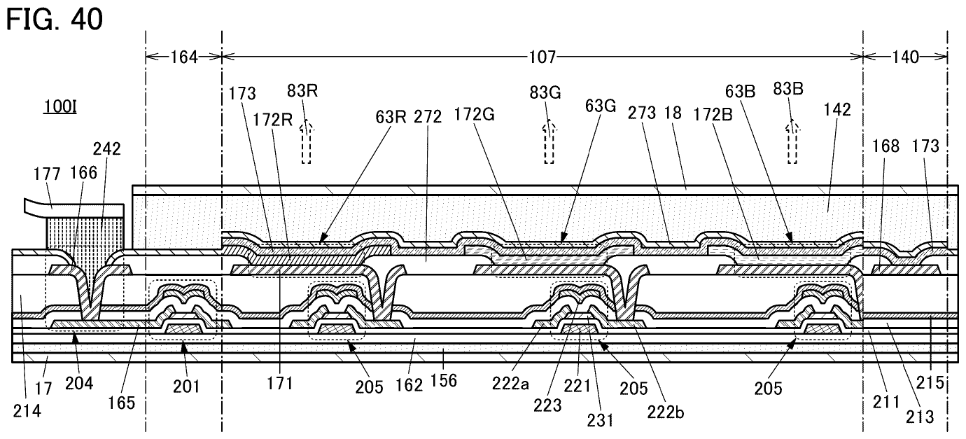

FIG. 40 is a cross-sectional view illustrating a structure of a display device 100I. The display device 100I is different from the display device 100H in having flexibility. In other words, the display device 100I is a flexible display. The display device 100I includes a substrate 17 and a substrate 18 instead of the substrate 14b and the substrate 16b, respectively. The substrates 17 and 18 both have flexibility.

The display device 100I includes a bonding layer 156 and an insulating layer 162. The insulating layer 162 and the substrate 17 are bonded to each other with the bonding layer 156. For example, the material that can be used for the bonding layer 122 can be used for the bonding layer 156. For example, the material that can be used for the insulating layer 211, the insulating layer 213, or the insulating layer 215 can be used for the insulating layer 162. Note that the transistors 201 and 205 are provided over the insulating layer 162.

For example, the insulating layer 162 is formed over a formation substrate, and the transistors, the light-emitting devices, and the like are formed over the insulating layer 162. Then, the bonding layer 142 is formed over the light-emitting devices, and the formation substrate and the substrate 18 are bonded to each other with the bonding layer 142. After that, the formation substrate is separated from the insulating layer 162 and the surface of the insulating layer 162 is exposed. Then, the bonding layer 156 is formed on the exposed surface of the insulating layer 162, and the insulating layer 162 and the substrate 17 are bonded to each other with the bonding layer 156. In this manner, the components formed over the formation substrate can be transferred onto the substrate 17, whereby the display device 100I can be manufactured.

### <<Display Device 100J>>

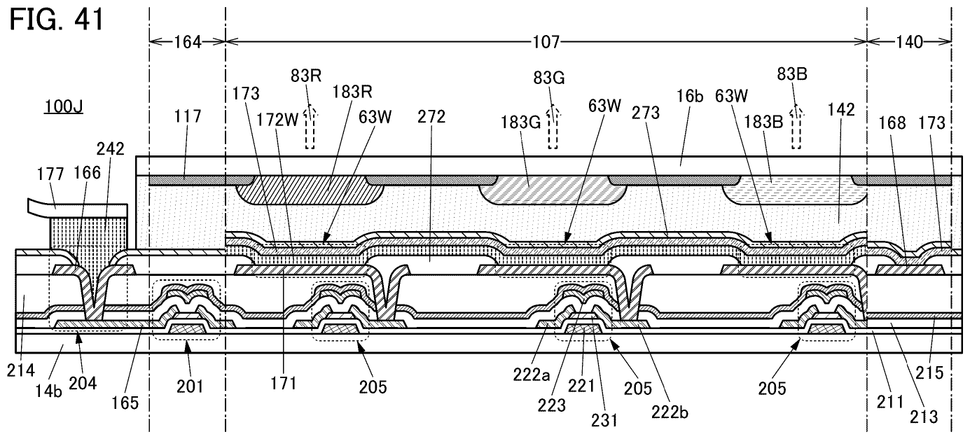

FIG. 41 is a cross-sectional view illustrating a structure of a display device 100J. The display device 100J is different from the display device 100H in including light-emitting devices 63W, instead of the light-emitting devices 63R, 63G and 63B, and the coloring layers 183R, 183G, and 183B.

The display device 100J includes the coloring layers 183R, 183G, and 183B between the substrate 16b and the substrate 14b. The coloring layer 183R overlaps with one light-emitting device 63W, the coloring layer 183G overlaps with another light-emitting device 63W, and the coloring layer 183B overlaps with another light-emitting device 63W.

The display device 100J includes a light-blocking layer 117. For example, the light-blocking layer 117 is provided between the coloring layers 183R and 183G, between the coloring layers 183G and 183B, and between the coloring layers 183B and 183R. The light-blocking layer 117 includes a region overlapping with the connection portion 140 and a region overlapping with the circuit 164.

The light-emitting device 63W can emit white light, for example. For example, the coloring layer 183R, the coloring layer 183G, and the coloring layer 183B can transmit red light, green light, and blue light, respectively. In this manner, the display device 100J can emit the red light 83R, the green light 83G, and the blue light 83B, for example, to perform full color display.

### <<Display Device 100K>>

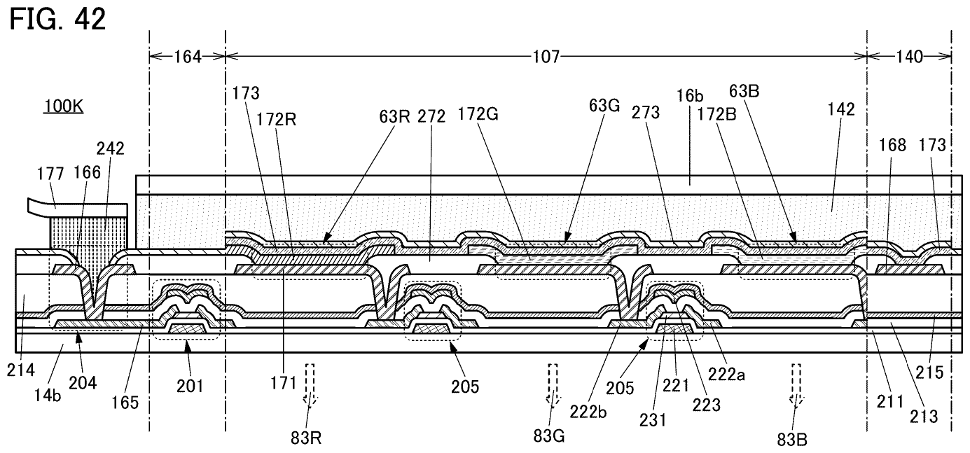

FIG. 42 is across-sectional view illustrating a structure of a display device 100K. The display device 100K is different from the display device 100H in having a bottom-emission structure. The light-emitting devices emit the light 83R, the light 83G, and the light 83B to the substrate 14b side. A visible-light-transmitting material is used for the conductive layer 171. A visible-light-reflecting material is used for the conductive layer 173.

<<Display Device 100L>>

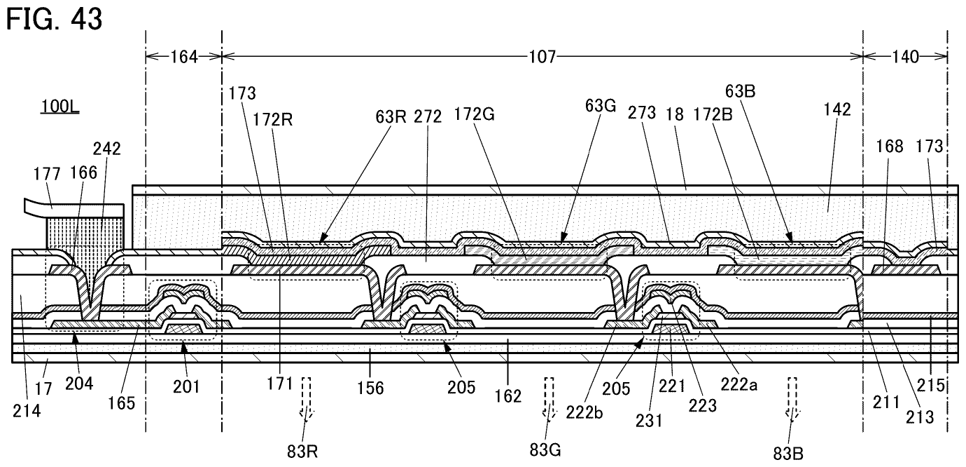

FIG. 43 is a cross-sectional view illustrating a structure of a display device 100L. The display device 100L is different from the display device 100H in having flexibility and a bottom-emission structure. The display device 100L includes the substrate 17 and the substrate 18 instead of the substrate 14b and the substrate 16b, respectively. The substrates 17 and 18 both have flexibility. The light-emitting devices emit the light 83R, the light 83G, and the light 83B to the substrate 14b side.

The conductive layer 221 and the conductive layer 223 may have a property of transmitting visible light and a property of reflecting visible light. When the conductive layers 221 and 223 have a property of transmitting visible light, the visible-light transmittance in the display portion 107 can be improved. Meanwhile, when the conductive layers 221 and 223 have a property of reflecting visible light, the amount of visible light entering the semiconductor layer 231 can be reduced. In addition, damage to the semiconductor layer 231 can be reduced. Accordingly, the reliability of the display device 100K or the display device 100L can be increased.

Even in a top-emission display device such as the display device 100H or the display device 100I, at least part of the layers included in the transistor 205 may have a property of transmitting visible light. In this case, the conductive layer 171 also has a property of transmitting visible light. Accordingly, the visible-light transmittance in the display portion 107 can be improved.

### <<Display Device 100M>>

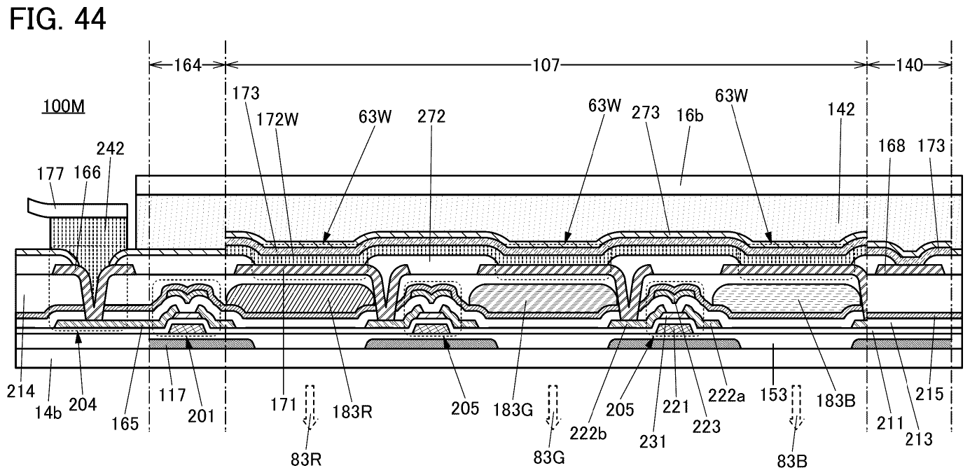

FIG. 44 is a cross-sectional view illustrating a structure of a display device 100M. The display device 100M is different from the display device 100H in having a bottom-emission structure and including the light-emitting devices 63W, instead of the light-emitting devices 63R, 63G and 63B, and the coloring layers 183R, 183G, and 183B.

The display device 100M includes the coloring layers 183R, 183G, and 183B. The display device 100M includes the light-blocking layer 117.

### [Coloring Layer 183R, Coloring Layer 183G, and Coloring Layer 183B]

The coloring layers 183R, 183G, and 183B are positioned between the substrate 14b and the respective light-emitting devices 63W. For example, the coloring layers 183R, 183G, and 183B can be provided between the insulating layer 215 and the insulating layer 214.

### [Light-Blocking Layer 117]

The light-blocking layer 117 is provided over the substrate 14b and positioned between the substrate 14b and the transistor 205. The insulating layer 153 is positioned between the light-blocking layer 117 and the transistor 205. For example, the light-blocking layer 117 does not overlap with a light-emitting region of the light-emitting device 63W. For example, the light-blocking layer 117 overlaps with the connection portion 140 and the circuit 164.

The light-blocking layer 117 can also be provided in the display device 100K or the display device 100L. In this case, light emitted from the light-emitting devices 63R, 63G, and 63B can be inhibited from being reflected by the substrate 14b and being diffused inside the display device 100K or the display device 100L, for example. Thus, the display device 100K and the display device 100L can provide high display quality. Meanwhile, when the light-blocking layer 117 is not provided, the extraction efficiency of light emitted from the light-emitting devices 63R, 63G, and 63B can be increased.

At least part of this embodiment can be implemented in combination with any of the other embodiments described in this specification, as appropriate.

### Embodiment 11

In this embodiment, electronic devices of embodiments of the present invention will be described.

Electronic devices of this embodiment are each provided with the display device of one embodiment of the present invention in a display portion. The display device of one embodiment of the present invention is highly reliable and can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With such a display device having one or both of high definition and high resolution, the electronic device can have higher realistic sensation, sense of depth, and the like in personal use such as portable use or home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

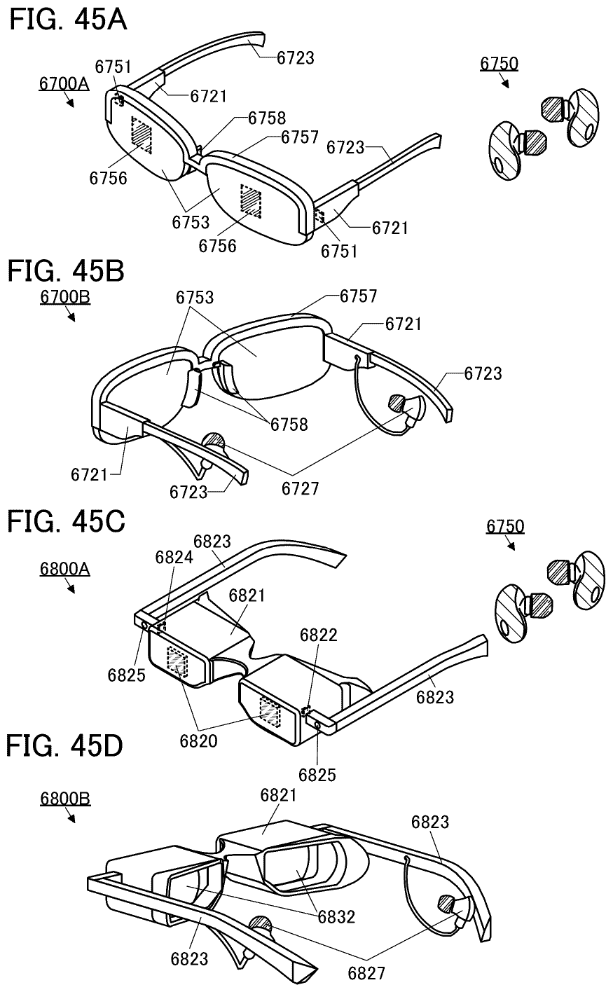

Examples of head-mounted wearable devices are described with reference to FIGS. 45A to 45D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 6700A illustrated in FIG. 45A and an electronic device 6700B illustrated in FIG. 45B each include a pair of display panels 6751, a pair of housings 6721, a communication portion (not illustrated), a pair of wearing portions 6723, a control portion (not illustrated), an image capturing portion (not illustrated), a pair of optical members 6753, a frame 6757, and a pair of nose pads 6758.

The display device of one embodiment of the present invention can be used for the display panels 6751. Thus, a highly reliable electronic device is obtained.

The electronic devices 6700A and 6700B can each project images displayed on the display panels 6751 onto display regions 6756 of the optical members 6753. Since the optical members 6753 have a light-transmitting property, the user can see images displayed on the display regions, which are superimposed on transmission images seen through the optical members 6753. Accordingly, the electronic devices 6700A and 6700B are electronic devices capable of AR display.

In the electronic devices 6700A and 6700B, a camera capable of capturing images of the front side may be provided as the image capturing portion. Furthermore, when the electronic devices 6700A and 6700B are provided with an acceleration sensor such as a gyroscope sensor, the orientation of the user's head can be sensed and an image corresponding to the orientation can be displayed on the display regions 6756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic devices 6700A and 6700B are provided with a battery so that they can be charged wirelessly and/or by wire.

A touch sensor module may be provided in the housing 6721. The touch sensor module has a function of detecting a touch on the outer surface of the housing 6721. Detecting a tap operation, a slide operation, or the like by the user with the touch sensor module enables various types of processing. For example, a moving image can be paused or restarted by a tap operation, and can be fast-forwarded or fast-reversed by a slide operation. When the touch sensor module is provided in each of the two housings 6721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion element (also referred to as a photoelectric conversion device) can be used as a light-receiving element. One or both of an inorganic semiconductor and an organic semiconductor can be used for an active layer of the photoelectric conversion element.

An electronic device 6800A illustrated in FIG. 45C and an electronic device 6800B illustrated in FIG. 45D each include a pair of display portions 6820, a housing 6821, a communication portion 6822, a pair of wearing portions 6823, a control portion 6824, a pair of image capturing portions 6825, and a pair of lenses 6832.

The display device of one embodiment of the present invention can be used in the display portions 6820. Thus, a highly reliable electronic device is obtained.

The display portions 6820 are positioned inside the housing 6821 so as to be seen through the lenses 6832. When the pair of display portions 6820 display different images, three-dimensional display using parallax can be performed.

The electronic devices 6800A and 6800B can be regarded as electronic devices for VR. The user who wears the electronic device 6800A or the electronic device 6800B can see images displayed on the display portions 6820 through the lenses 6832.

The electronic devices 6800A and 6800B preferably include a mechanism for adjusting the lateral positions of the lenses 6832 and the display portions 6820 so that the lenses 6832 and the display portions 6820 are positioned optimally in accordance with the positions of the user's eyes. Moreover, the electronic devices 6800A and 6800B preferably include a mechanism for adjusting focus by changing the distance between the lenses 6832 and the display portions 6820.

The electronic device 6800A or the electronic device 6800B can be mounted on the user's head with the wearing portions 6823. FIG. 45C, for instance, shows an example where the wearing portion 6823 has a shape like a temple (also referred to as a joint or the like) of glasses; however, one embodiment of the present invention is not limited thereto. The wearing portion 6823 can have any shape with which the user can wear the electronic device, for example, a shape of a helmet or a band.

The image capturing portion 6825 has a function of obtaining information on the external environment. Data obtained by the image capturing portion 6825 can be output to the display portion 6820. An image sensor can be used for the image capturing portion 6825. Moreover, a plurality of cameras may be provided so as to support a plurality of fields of view, such as a telescope field of view and a wide field of view.

Although an example where the image capturing portions 6825 are provided is shown here, a range sensor (also referred to as a sensing portion) capable of measuring a distance between the user and an object just needs to be provided. In other words, the image capturing portion 6825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 6800A may include a vibration mechanism that functions as bone-conduction earphones. For example, at least one of the display portion 6820, the housing 6821, and the wearing portion 6823 can include the vibration mechanism. Thus, without additionally requiring an audio device such as headphones, earphones, or a speaker, the user can enjoy video and sound only by wearing the electronic device 6800A.

The electronic devices 6800A and 6800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 6750. The earphones 6750 include a communication portion (not illustrated) and have a wireless communication function. The earphones 6750 can receive information (e.g., audio data) from the electronic device with the wireless communication function. For example, the electronic device 6700A in FIG. 45A has a function of transmitting information to the earphones 6750 with the wireless communication function. As another example, the electronic device 6800A in FIG. 45C has a function of transmitting information to the earphones 6750 with the wireless communication function.

The electronic device may include an earphone portion. The electronic device 6700B in FIG. 45B includes earphone portions 6727. For example, the earphone portion 6727 can be connected to the control portion by wire. A part of a wiring that connects the earphone portion 6727 and the control portion may be positioned inside the housing 6721 or the wearing portion 6723.

Similarly, the electronic device 6800B in FIG. 45D includes earphone portions 6827. For example, the earphone portion 6827 can be connected to the control portion 6824 by wire. Apart of a wiring that connects the earphone portion 6827 and the control portion 6824 may be positioned inside the housing 6821 or the wearing portion 6823. Alternatively, the earphone portions 6827 and the wearing portions 6823 may include magnets. This is preferred because the earphone portions 6827 can be fixed to the wearing portions 6823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic devices 6700A and 6700B) and the goggles-type device (e.g., the electronic devices 6800A and 6800B) are preferable as the electronic device of one embodiment of the present invention.

The electronic device of one embodiment of the present invention can transmit information to earphones by wire or wirelessly.

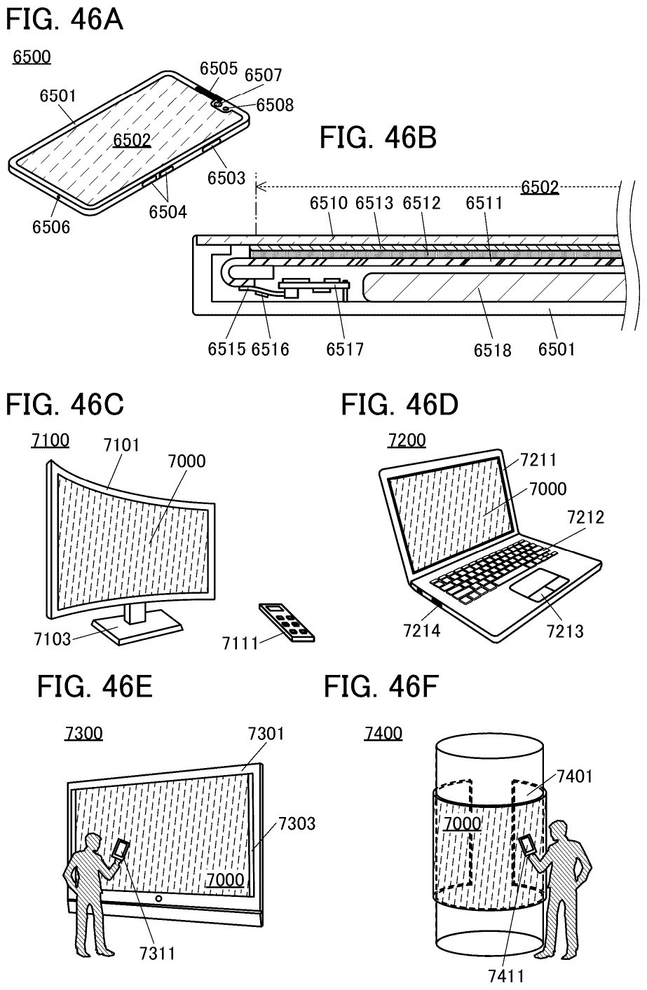

An electronic device 6500 in FIG. 46A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic device is obtained.

FIG. 46B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

A part of the display panel 6511 is folded back in a region outside the display portion 6502, and an FPC 6515 is connected to the region that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, a part of the display panel 6511 is folded back so that a connection portion with the FPC 6515 is provided on the back side of the pixel portion, whereby an electronic device with a narrow bezel can be achieved.

FIG. 46C illustrates an example of a television device. In a television device 7100, a display portion 7000 is incorporated in a housing 7101. Here, the housing 7101 is supported by a stand 7103.

The display device of one embodiment of the present invention can be used in the display portion 7000. Thus, a highly reliable electronic device is obtained.

Operation of the television device 7100 illustrated in FIG. 46C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel of the remote controller 7111, channels and volume can be controlled and images displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 46D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic device is obtained.

FIGS. 46E and 46F illustrate examples of digital signage.

Digital signage 7300 illustrated in FIG. 46E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 46F illustrates digital signage 7400 attached to a cylindrical pillar 7401. The digital signage 7400 includes the display portion 7000 provided along a curved surface of the pillar 7401.

In FIGS. 46E and 46F, the display device of one embodiment of the present invention can be used in the display portion 7000. Thus, a highly reliable electronic device is obtained.

A larger area of the display portion 7000 can increase the amount of information that can be provided at a time. The larger display portion 7000 attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, for an application for providing information such as route information or traffic information, usability can be enhanced by intuitive operation.

As illustrated in FIGS. 46E and 46F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

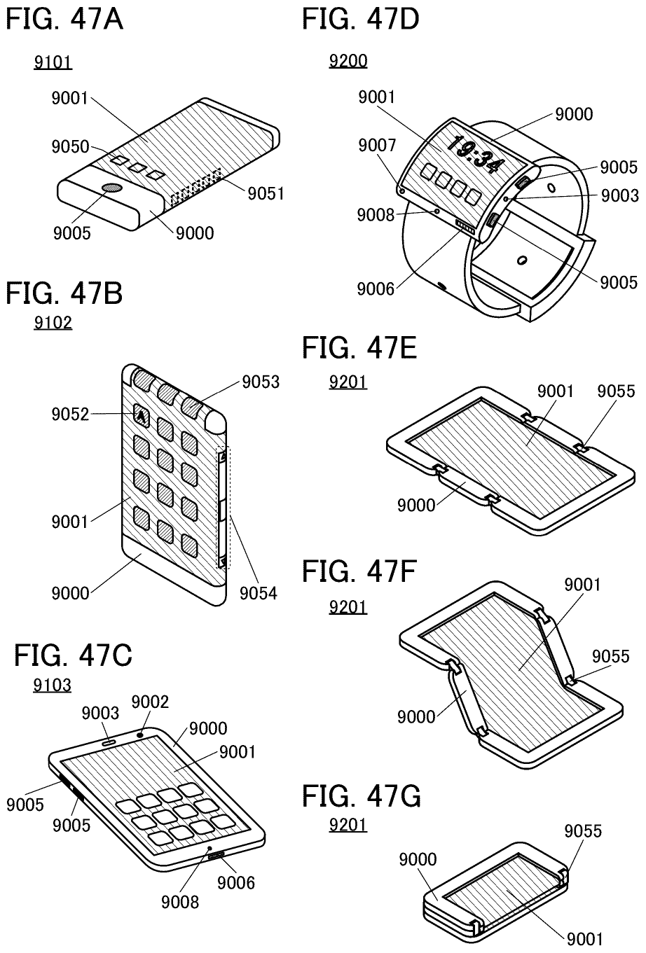

Electronic devices illustrated in FIGS. 47A to 47G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 9008, and the like.

The electronic devices illustrated in FIGS. 47A to 47G have a variety of functions. For example, the electronic devices can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of taking a still image or a moving image, a function of storing the taken image in a storage medium (an external storage medium or a storage medium incorporated in the camera), a function of displaying the taken image on the display portion, and the like.

The electronic devices in FIGS. 47A to 47G are described in detail below.

FIG. 47A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 47A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050, for example, may be displayed at the position where the information 9051 is displayed.

FIG. 47B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of user's clothes. Thus, the user can see the display without taking out the portable information terminal 9102 from the pocket and decide whether to answer the call, for example.

FIG. 47C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 47D is a perspective view of a watch-type portable information appliance 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 47E to 47G are perspective views of a foldable portable information terminal 9201. FIG. 47E is a perspective view showing the portable information terminal 9201 that is opened. FIG. 47G is a perspective view showing the portable information terminal 9201 that is folded. FIG. 47F is a perspective view showing the portable information terminal 9201 that is shifted from one of the states in FIGS. 47E and 47G to the other. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with any of the other embodiments as appropriate. In this specification, in the case where a plurality of structure examples are shown in one embodiment, the structure examples can be combined as appropriate.

### Example 1

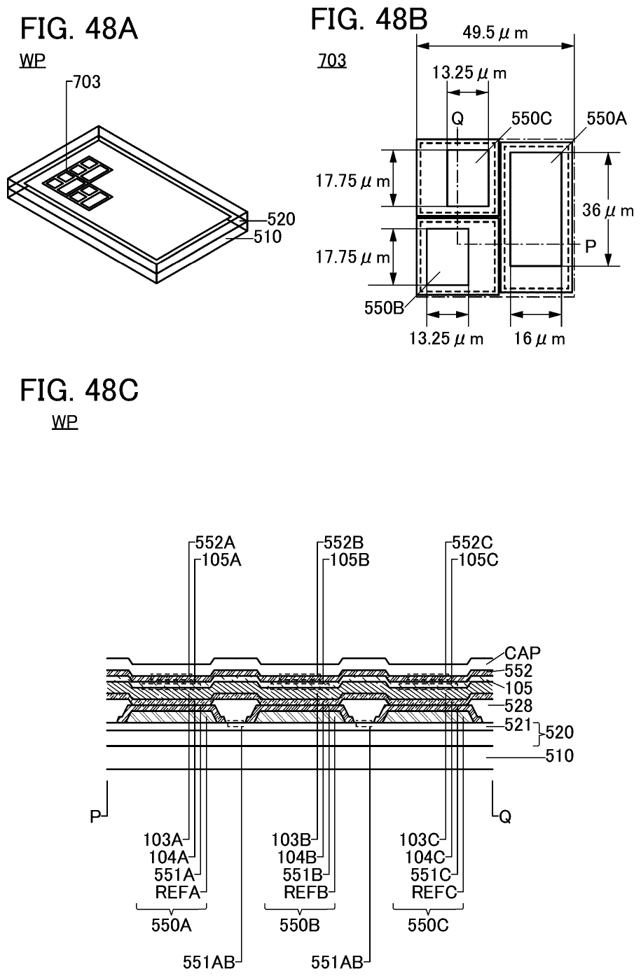

In this example, a workpiece fabricated with use of the method for manufacturing a display device of one embodiment of the present invention will be described with reference to FIGS. 48A to 48C, FIGS. 49A to 49D, FIG. 50, FIG. 51, FIG. 52, FIG. 53, FIG. 54, and FIG. 55.

FIG. 48A is a perspective view illustrating a structure of a workpiece fabricated in this example, and FIG. 48B is a top view illustrating part of FIG. 48A. FIG. 48C is a cross-sectional view taken along a cutting line P-Q in FIG. 48B.

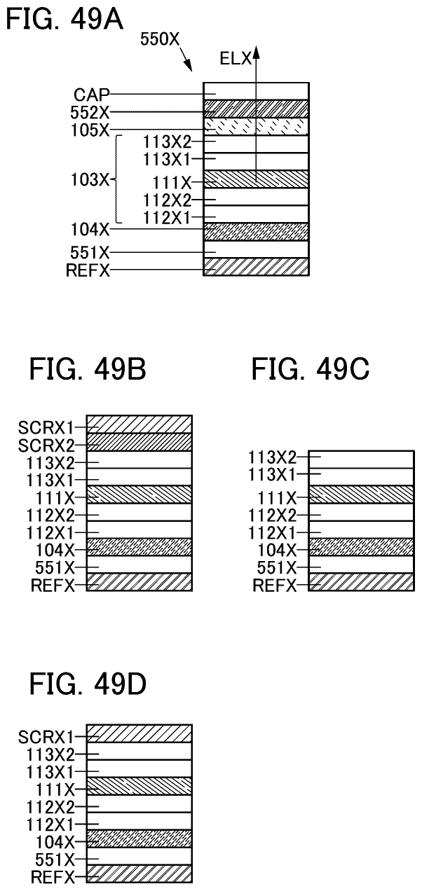

FIG. 49A illustrates a structure of a light-emitting device, and FIGS. 49B to 49D illustrate a method for manufacturing the light-emitting device.

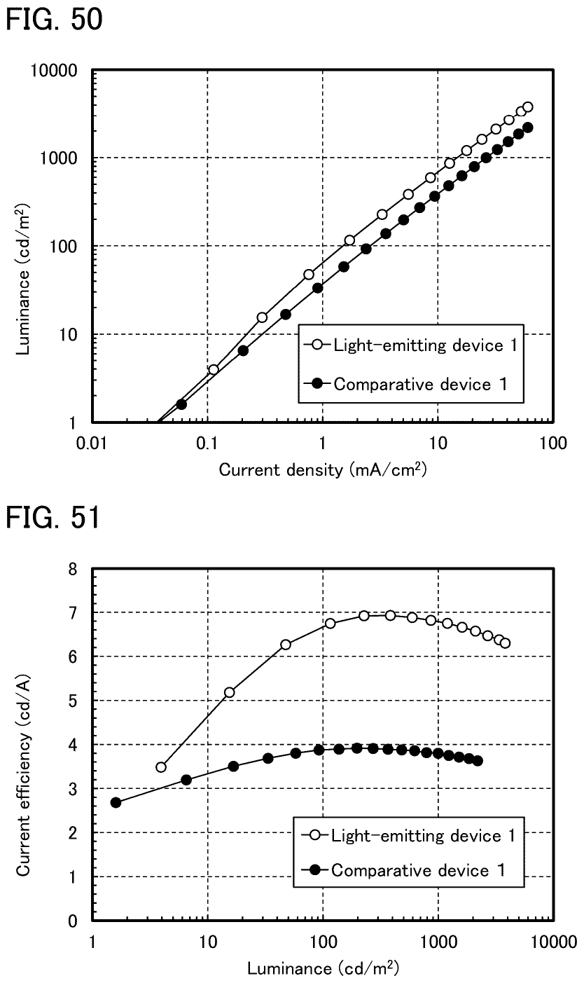

FIG. 50 shows current density-luminance characteristics of light-emitting devices.

FIG. 51 shows luminance-current efficiency characteristics of the light-emitting devices.

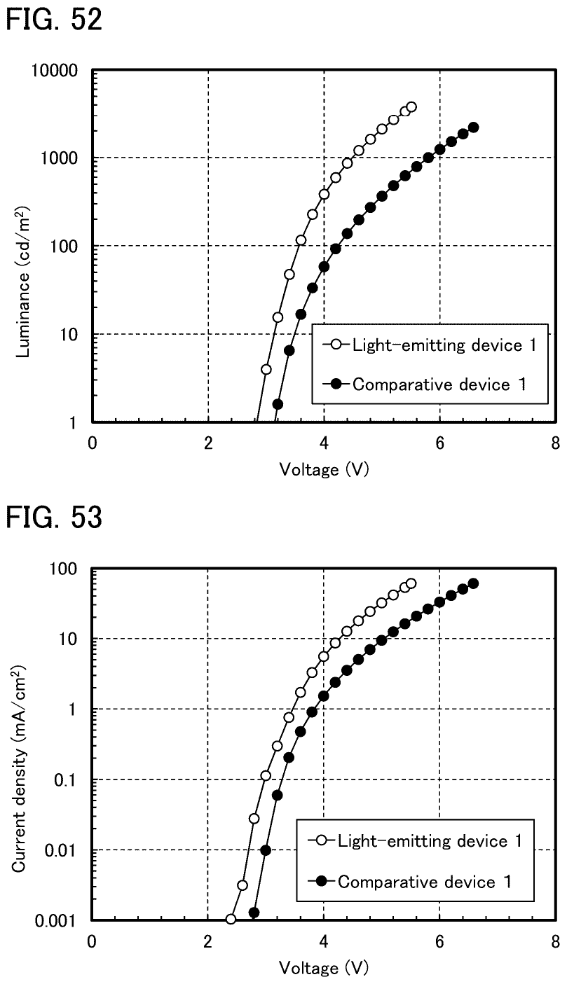

FIG. 52 shows voltage-luminance characteristics of the light-emitting devices.

FIG. 53 shows voltage-current characteristics of the light-emitting devices.

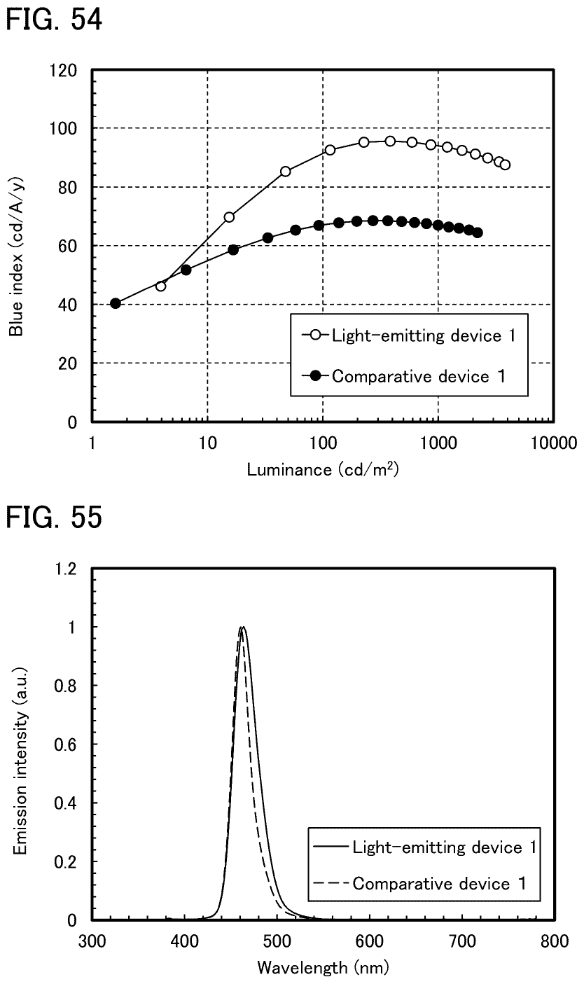

FIG. 54 shows luminance-blue index characteristics of the light-emitting devices. Note that the blue index (BI) is one of the indicators of characteristics of a blue light-emitting device, and is a value obtained by dividing current efficiency (cd/A) by chromaticity y. In general, blue light with high color purity is useful in expressing a wide color gamut. In addition, blue light with higher color purity tends to have lower chromaticity y. Thus, a value obtained by dividing current efficiency (cd/A) by chromaticity y is the indicator of usefulness of a blue light-emitting device. In other words, a blue light-emitting device with a large BI is suitable for providing a highly efficient display device capable of displaying an image with a wide color gamut.

FIG. 55 shows emission spectra of the light-emitting devices emitting light at a luminance of 1000 cd/m².

### <Workpiece>

A fabricated workpiece WP that is described in this example includes the pixel set 703 (see FIG. 48A). The pixel set 703 includes the light-emitting device 550A, the light-emitting device 550B, and the light-emitting device 550C (see FIG. 48B). The workpiece WP includes the substrate 510, the functional layer 520, and an insulating layer 528, and the functional layer 520 includes the insulating layer 521 (see FIG. 48C).

The light-emitting device 550A has a rectangular front surface with a size of approximately 36 μm long and 16 μm width (see FIG. 48B). The light-emitting device 550A includes a reflective film REFA, the electrode 551A, the layer 104A, the unit 103A, the layer 105A, the electrode 552A, and a layer CAP (see FIG. 48C).

The light-emitting device 550B has a rectangular front surface with a size of approximately 17.75 μm length and 13.25 μm width (see FIG. 48B). The light-emitting device 550B includes a reflective film REFB, the electrode 551B, the layer 104B, the unit 103B, the layer 105B, the electrode 552B, and the layer CAP (see FIG. 48C). Note that the gap 551AB is located between the electrode 551B and the electrode 551A.

The light-emitting device 550C has a rectangular front surface with a size of approximately 17.75 μm length and 13.25 μm width (see FIG. 48B). The light-emitting device 550C includes a reflective film REFC, the electrode 551C, the layer 104C, the unit 103C, the layer 105C, the electrode 552C, and the layer CAP (see FIG. 48C). Note that the gap 551BC is located between the electrode 551C and the electrode 551B.

### <Light-Emitting Device 1>

A fabricated light-emitting device 1 that is described in this example includes a plurality of pixel sets 703 in a square region (2 mm length×2 mm width) to have a resolution of 500 ppi. In other words, resolutions of the light-emitting device 550A, the light-emitting device 550B, and the light-emitting device 550C in the light-emitting device 1 are each 500 ppi.

Each of the light-emitting devices A, B, and C has a structure similar to that of the light-emitting device 550X. Thus, the description of the structure of the light-emitting device 550X can be used for the light-emitting devices 550A, 550B, and 550C. Specifically, the description of the light-emitting device 550X can be referred to for the description of the light-emitting device 550A by replacing “X” in the reference numerals of the components of the light-emitting device 550X with “A”. Similarly, the structure of the light-emitting device 550X can be referred to for the light-emitting device 550B or the light-emitting device 550C by replacing “X” with “B” or “C”.

### <<Structure of Light-Emitting Device 1>>

Table 1 shows the structure of the light-emitting device 1. Structural formulae of materials used in the light-emitting devices described in this example are shown below. Note that in the tables in this example, subscript and superscript characters are written in ordinary size for convenience. For example, a subscript character in an abbreviation and a superscript character in a unit are written in ordinary size in the tables. The corresponding description in the specification gives an accurate reading of such notations in the tables.

TABLE 1

| | Reference | | Composition | |
|---|---|---|---|---|
| Component | numeral | Material | ratio | Thickness/nm |
| Layer | CAP | IGZO | | 70 |
| Electrode | 552X | Ag:Mg | 1:0.1 | 15 |
| Layer | 105X | LiF:Yb | 1:1 | 1 |
| Layer | 113X2 | mPPhen2P | | 10 |
| Layer | 113X1 | 2mPCCzPDBq | | 10 |
| Layer | 111X | αN-βNPAnth:3,10PCA2Nbf(IV)-02 | 1:0.02 | 25 |
| Layer | 112X2 | DBfBB1TP | | 10 |
| Layer | 112X1 | PCBBiF | | 59.4 |
| Layer | 104X | PCBBiF:OCHD-003 | 1:0.03 | 11.4 |
| Electrode | 551X | ITSO | | 50 |
| Reflective film | REFX | APC | | 100 |

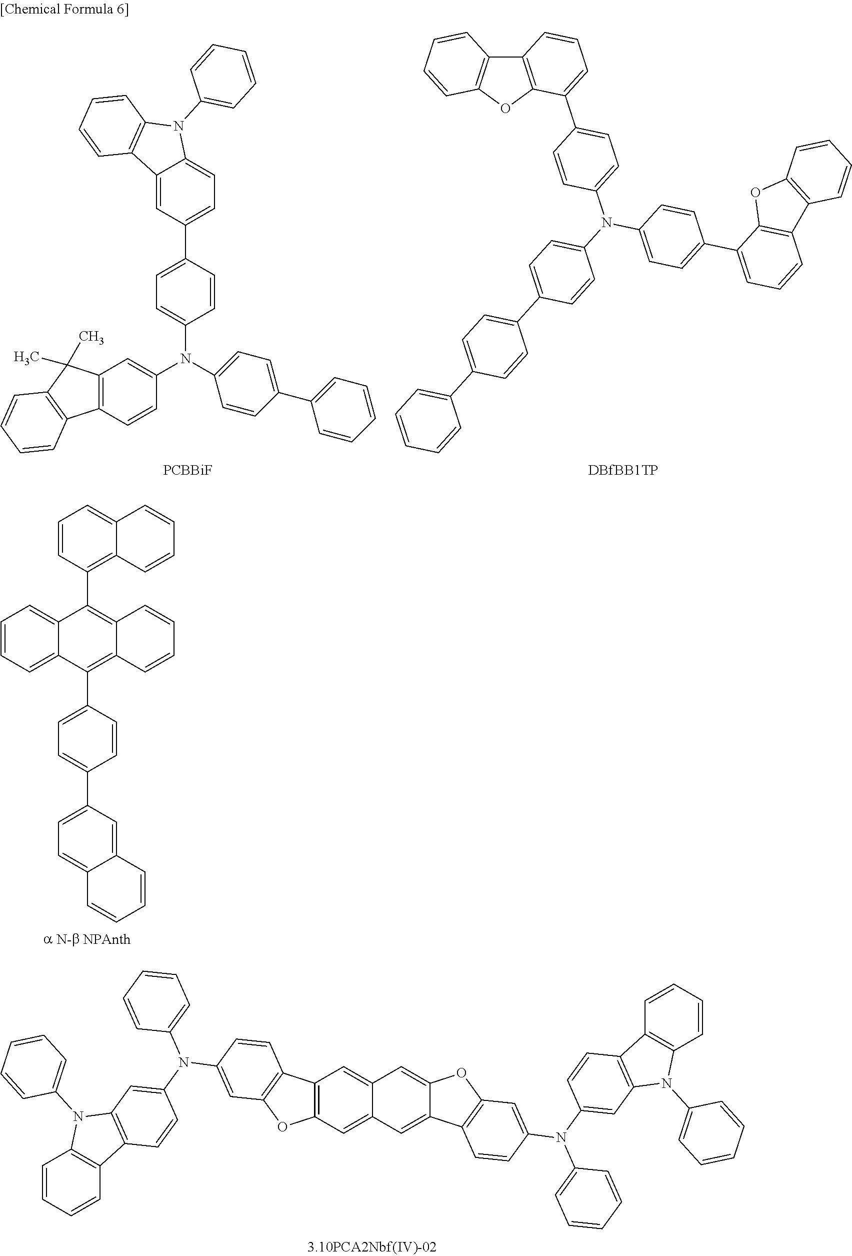

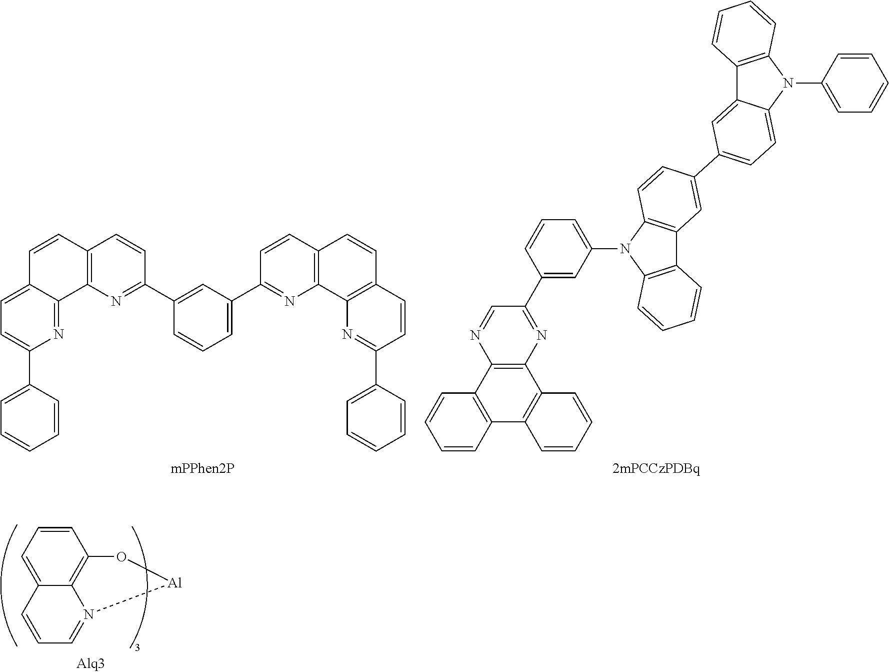

### <Fabrication Method of Workpiece>

A method for fabricating the workpiece described in this example includes steps similar to those in the method for manufacturing a display device of one embodiment of the present invention.

### <<Fabrication Method of Light-Emitting Device 1>>

The light-emitting device 1 described in this example was fabricated using a method including the following steps.

### [First Step]

A reflective film REF was formed in a first step. Specifically, the reflective film was formed by a sputtering method using an alloy containing silver (Ag), palladium (Pd), and copper (Cu) (abbreviation: APC) as a target. The reflective film REF contains APC and has a thickness of 100 nm.

### [Second Step]

In a second step, the electrode 551X was formed over the reflective film REF. Specifically, the electrode 551X was formed by a sputtering method using indium-tin oxide containing silicon or silicon oxide (abbreviation: ITSO) as a target. Note that the electrode 551X includes ITSO and has a thickness of 50 nm.

Next, a workpiece provided with the electrode was washed with water and then transferred into a vacuum evaporation apparatus. After that, the pressure in the vacuum evaporation apparatus was reduced to approximately 10⁻⁴ Pa, and vacuum baking was performed at 170° C. for 60 minutes in a heating chamber of the vacuum evaporation apparatus. Then, the workpiece was cooled down for approximately 30 minutes.

### [Third Step]

In a third step, the layer 104X was formed over the electrode 551X. Specifically, materials of the layer 104X were co-deposited by a resistance-heating method. The layer 104X contains N-(biphenyl-4-yl)-N-[4-(9-phenyl-9H-carbazol-3-yl)phenyl]-9,9-dimethyl-9H-fluoren-2-amine (abbreviation: PCBBiF) and an electron-accepting material (abbreviation: OCHD-003) at 1:0.03 (PCBBiF:OCHD-003) in a weight ratio and has a thickness of 11.4 nm. Note that OCHD-003 contains fluorine, and has a molecular weight of 672.

### [Fourth Step]

In a fourth step, a layer 112X1 was formed over the layer 104X. Specifically, a material of the layer 112X1 was deposited by a resistance-heating method. The layer 112X1 contains PCBBiF and has a thickness of 59.4 nm.

### [Fifth Step]

In a fifth step, a layer 112X2 was formed over the layer 112X1. Specifically, a material of the layer 112X2 was deposited by a resistance-heating method. The layer 112X2 contains NN-bis[4-(dibenzofuran-4-yl)phenyl]-4-amino-p-terphenyl (abbreviation: DBfBB1TP) and has a thickness of 10 nm.

### [Sixth Step]

In a sixth step, the layer 111X was formed over the layer 112X2. Specifically, materials of the layer 111X were co-deposited by a resistance-heating method. The layer 111X contains 9-(1-naphthyl)-10-[4-(2-naphthyl)phenyl]anthracene (abbreviation: αN-βNPAnth) and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) at 1:0.02 (αN-βNPAnth:3,10PCA2Nbf(IV)-02) in a weight ratio and has a thickness of 25 nm.

### [Seventh Step]

In a seventh step, a layer 113X1 was formed over the layer 111X. Specifically, a material of the layer 113X1 was deposited by a resistance-heating method. The layer 113X1 contains 2-{3-[3-(N-phenyl-9H-carbazol-3-yl)-9H-carbazol-9-yl]phenyl}dibenzo[f,h]quinoxaline (abbreviation: 2mPCCzPDBq) and has a thickness of 10 nm.

### [Eighth Step]

In an eighth step, the layer 113X2 was formed over the layer 113X1. Specifically, a material of the layer 113X2 was deposited by a resistance-heating method. The layer 113X2 contains 2,2′-(1,3-phenylene)bis(9-phenyl-1,10-phenanthroline) (abbreviation: mPPhen2P) and has a thickness of 10 nm.

### [Ninth Step]

In a ninth step, a layer SCRX2 was formed over the layer 113X2. Specifically, a material of the layer SCRX2 was deposited by a resistance-heating method. The layer SCRX2 contains tris(8-quinolinolato)aluminum(III) (abbreviation: Alq₃) and has a thickness of 30 nm.

### [Tenth Step]

In a tenth step, a layer SCRX1 was formed over the layer SCRX2. Specifically, the layer SCRX1 was formed by a sputtering method using indium-gallium-zin oxide (abbreviation: IGZO) as a target. Note that the layer SCRX1 contains IGZO and has a thickness of 10 nm (see FIG. 49B).

The layer SCRX1 was formed over the layer SCRX2 by a sputtering method, in which case the layer SCRX2 is exposed to plasma, resulting in a reduction in thickness of the layer SCRX2. The layer SCRX2 protects the layer 113X2 from a change in its property due to plasma.

### [Eleventh Step]

In an eleventh step, the layers SCRX1 and SCRX2 were removed by an etching method using an aqueous solution containing phosphoric acid at 4.25 weight %, so that the layer 113X2 was exposed (see FIG. 49C).

### [Twelfth Step]

In a twelfth step, the layer 105X was formed over the layer 113X2. Specifically, materials of the layer 113X2 were co-deposited by a resistance-heating method. The layer 105X contains lithium fluoride (LiF) and ytterbium (Yb) at 1:1 (LiF:Yb) in a weight ratio and has a thickness of 1 nm.

### [Thirteenth Step]

In a thirteenth step, the electrode 552X was formed over the layer 105X. Specifically, materials of the electrode 552X were co-deposited by a resistance-heating method. The electrode 552X contains silver (Ag) and magnesium (Mg) at 1:0.1 (Ag:Mg) in a weight ratio and has a thickness of 15 nm.

### [Fourteenth Step]

In a fourteenth step, the layer CAP was formed over the electrode 552X. Specifically, the layer CAP was formed by a sputtering method using IGZO as a target. The layer CAP contains IGZO and has a thickness of 70 nm.

### <<Operating Characteristics of Light-Emitting Device 1>>

When supplied with electric power, the light-emitting device 1 emitted the light ELX (see FIG. 49A). Specifically, the light-emitting device 1 was driven with a method where the light-emitting devices 550A, 550B, and 550C are supplied with voltages at the same level. Operating characteristics of the light-emitting device 1 were measured at room temperature (see FIG. 50 to FIG. 55). Note that luminance, CIE chromaticity, and emission spectra were measured with a spectroradiometer (SR-UL1R produced by TOPCON TECHNOHOUSE CORPORATION). The area of the light-emitting device 1 occupies 42.24% of the area of the measured region. The measured value was corrected with use of the area ratio.

Table 2 shows main initial characteristics of the fabricated light-emitting device emitting light at a luminance of approximately 1000 cd/m². Table 2 also shows characteristics of another light-emitting devices having a structure described later.

TABLE 2

| | | | Current | | | Current | |
|---|---|---|---|---|---|---|---|
| | Voltage | Current | density | Chromaticity | Chromaticity | efficiency | B.I. |
| | (V) | (mA) | (mA/cm2) | x | y | (cd/A) | (cd/A/y) |
| Light-emitting device 1 | 5.0 | 0.53 | 13.5 | 0.13 | 0.07 | 6.6 | 91.2 |
| Comparative device 1 | 6.4 | 0.83 | 21.2 | 0.14 | 0.06 | 3.7 | 65.3 |

The light-emitting device 1 was found to exhibit favorable characteristics. For example, the light-emitting device 1 exhibited high current efficiency and high blue index and operated with a low current value. As compared with a comparative device 1, the light-emitting device 1 exhibited high current efficiency and operated with a low current value at a low voltage. As a fabrication method of the light-emitting device 1, the layer SCRX2 is formed over the layer 113X2 in the ninth step, and the layer SCRX1 is formed over the layer SCRX2 by a sputtering method in the tenth step. Meanwhile, as a fabrication method of the comparative device 1, the ninth step is skipped, and the layer SCRX1 is formed over the layer 113X2 by a sputtering method in the tenth step. When the layer SCRX1 is formed by a sputtering method, a layer to be abase is damaged. The layer 113X2 in the light-emitting device 1 was protected by the layer SCRX2 from damage caused by sputtering, and the layer 113X2 in the comparative device 1 was damaged by sputtering. As a result, the light-emitting device 1 exhibited better characteristics than the comparative device 1.

### Reference Example

The fabricated comparative device 1, which is described in this reference example, has a structure similar to that of the light-emitting device 550X (see FIGS. 49A to 49D).

### <<Structure of Comparative Device 1>>

The comparative device 1 has the same structure as the light-emitting device 1 but is fabricated with a method different from that of the light-emitting device 1.

### <<Fabrication Method of Comparative Device 1>>

The comparative device 1 described in this reference example was fabricated by a method including the following steps. Note that the fabrication method of the comparative device 1 is different from that of the light-emitting device 1 in that the ninth step is skipped and the tenth step follows the eighth step. Different portions are described in detail here, and the above description is referred to for portions where a method similar to the above was employed.

### [Eighth Step]

In the eighth step, the layer 113X2 was formed over the layer 113X1. Specifically, a material of the layer 113X2 was deposited by a resistance-heating method. The layer 113X2 contains 2,2′-(1,3-phenylene)bis(9-phenyl-1,10-phenanthroline) (abbreviation: mPPhen2P) and has a thickness of 10 nm.

### [Tenth Step]

The ninth step was skipped, and in the tenth step, the layer SCRX1 was formed over the layer 113X2. Specifically, the layer SCRX1 was formed by a sputtering method using indium-gallium-zinc oxide (abbreviation: IGZO) as a target. The layer SCRX1 contains IGZO and has a thickness of 10 nm (see FIG. 49D).

The layer SCRX1 is formed over the layer 113X2 by a sputtering method, in which case the layer 113X2 is exposed to plasma, resulting in a reduction in thickness of the layer 113X2.

### [Eleventh Step]

In the eleventh step, specifically, the layer SCRX1 was removed by an etching method using an aqueous solution containing phosphoric acid at 4.25 weight %, so that the layer 113X2 was exposed (see FIG. 49C).

### <<Operating Characteristics of Comparative Device 1>>

When supplied with electric power, the comparative device 1 emitted the light ELX (see FIG. 49A). Operating characteristics of the comparative device 1 were measured at room temperature (see FIG. 50 to FIG. 55). Table 2 shows main initial characteristics of the comparative device 1 emitting light at a luminance of approximately 1000 cd/m².

### Example 2

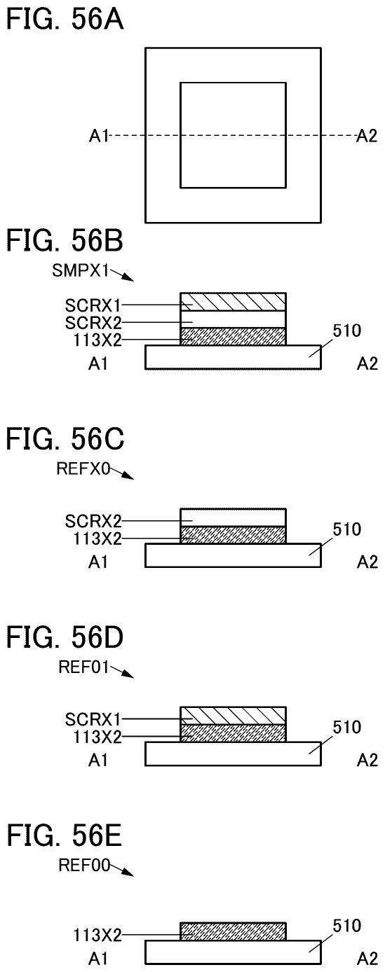

In this example, the effect of the layer SCRX2 on protecting the layer 113X2, which was observed from samples fabricated with the method for manufacturing a display device of one embodiment of the present invention, will be described with reference to FIGS. 56A to 56E, FIG. 57, FIG. 58, and FIG. 59.

FIGS. 56A to 56E illustrate structures of the samples. FIG. 56A is a front view of the sample, and FIG. 56B is a cross-sectional view taken along a cutting line A1-A2 in FIG. 56A. FIGS. 56C to 56E each illustrate a structure of a sample different from that in FIG. 56B.

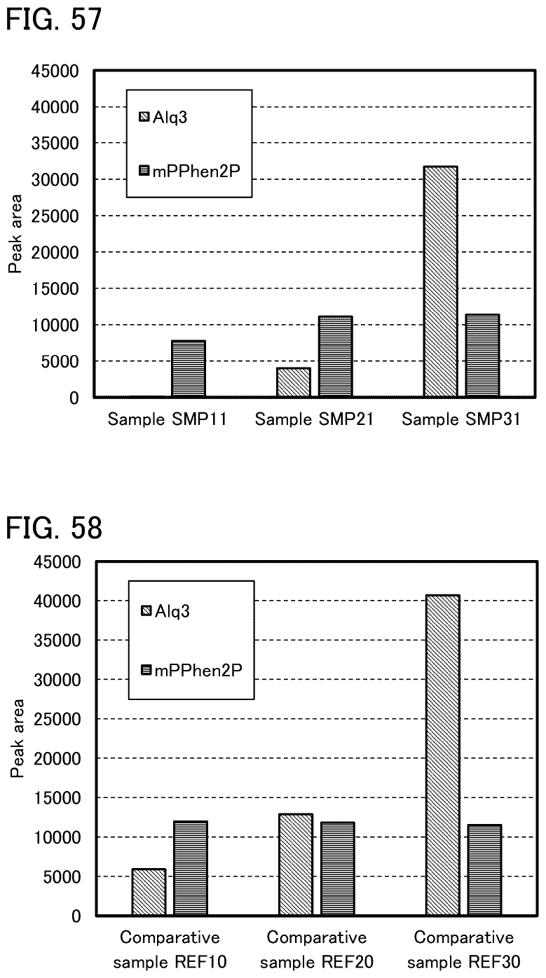

FIG. 57 shows liquid chromatography-mass spectrometry results of the samples.

FIG. 58 shows liquid chromatography-mass spectrometry results of comparative samples.

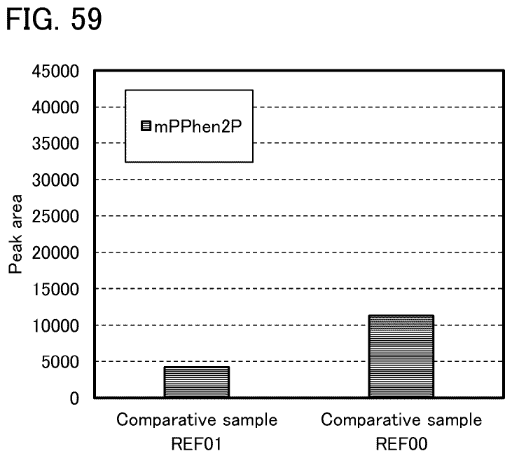

FIG. 59 shows liquid chromatography-mass spectrometry results of comparative samples.

### <Sample>

The fabricated samples that are described in this example each have a structure similar to that of a sample SMPX1 (see FIGS. 56A and 56B). Note that “SMPX1” used as a reference numeral in the drawings are replaced with “SMP11”, “SMP21”, or “SMP31” as appropriate and used for the description in this example.

The fabricated comparative samples that are described in this example each have a structure similar to that of a comparative sample REFX0 (see FIGS. 56A and 56C). Note that “REFX0” used as a reference numeral in the drawings are replaced with “REF10”, “REF20”, or “REF30” as appropriate and used for the description in this example.

### <<Structures of Sample SMP11, Sample SMP21, and Sample SMP31>>

Table 3 shows structures of samples SMP11, SMP21, and SMP31. Note that in the tables in this example, subscript and superscript characters are written in ordinary size for convenience. For example, a subscript character in an abbreviation and a superscript character in a unit are written in ordinary size in the tables. The corresponding description in the specification gives an accurate reading of such notations in the tables.

TABLE 3

| | | | Sample | Sample | Sample |
|---|---|---|---|---|---|
| | | | SMP11 | SMP21 | SMP31 |
| Layer | SCRX1 | IGZO | 50 nm | 50 nm | 50 nm |
| Layer | SCRX2 | Alq3 | 5 nm | 10 nm | 30 nm |
| Layer | 113X2 | mPPhen2P | 10 nm | 10 nm | 10 nm |

To evaluate the samples SMP11, SMP21, and SMP31, comparative samples REF10, REF20, and REF30 were fabricated. Table 4 shows structures of the comparative samples REF10, REF20, and REF30.

The comparative reference REF10 is for evaluating the sample SMP11 and different from the sample SMP11 in that the layer SCRX1 is not formed. The comparative sample REF20 is for evaluating the sample SMP21 and different from the sample SMP21 in that the layer SCRX1 is not formed. The comparative sample REF30 is for evaluating the sample SMP31 and different from the sample SMP31 in that the layer SCRX1 is not formed over the layer SCRX2.

TABLE 4

| | | | Comparative | Comparative | Comparative |
|---|---|---|---|---|---|
| | | | sample | sample | sample |
| | | | REF10 | REF20 | REF30 |
| Layer | SCRX2 | Alq3 | 5 nm | 10 nm | 30 nm |
| Layer | 113X2 | mPPhen2P | 10 nm | 10 nm | 10 nm |

### <<Fabrication Method of Sample SMP21>>

The sample SMP21 described in this example was fabricated using a method including the following steps.

### [First Step]

In a first step, the layer 113X2 was formed over the substrate 510. Specifically, a material of the layer 113X2 was deposited by a resistance-heating method. The layer 113X2 contains mPPhen2P and has a thickness of 10 nm.

### [Second Step]

In a second step, the layer SCRX2 was formed over the layer 113X2. Specifically, a material of the layer SCRX2 was deposited by a resistance-heating method. The layer SCRX2 contains Alq₃ and has a thickness of 10 nm.

### [Third Step]

In a third step, the layer SCRX1 was formed over the layer SCRX2. Specifically, the layer SCRX1 was formed by a sputtering method using IGZO as a target. The layer SCRX1 contains IGZO and has a thickness of 50 nm.

### <<Evaluation Method of Sample SMP21>>

The liquid chromatography-mass spectrometry (LC-MS) was performed. First, a piece with a size of 2.0 mm×2.0 mm cut out from the sample SMP21 was housed in a vial, a solvent in which acetonitrile and chloroform were mixed at a volume ratio of 8:2 (acetonitrile:chloroform) was added to the vial, and the vial was irradiated with an ultrasonic wave for 10 minutes with use of an ultrasonic cleaning machine. The solution was extracted from the vial and filtrated with use of a porous polytetrafluoroethylene (abbreviation: PTFE) filter with a pore diameter of 0.2 μm, so that a filtrate was obtained. The filtrate was used for measuring the sample. Note that liquid chromatography (LC) separation was carried out with ACQUITY UPLC (registered trademark) (produced by Waters Corporation) and mass spectrometry (MS) was carried out with Xevo G2 Tof MS (produced by Waters Corporation). A photodiode array and a mass analyzer were used as detectors. In the LC-MS, a peak area was calculated as a value of a product of signal intensity of a peak and a detection period during which the signal was detected.

### <<Evaluation Results of Sample SMP21>>

In the sample SMP21, a sufficient amount of mPPhen2P used in the layer 113X2 was observed (see FIG. 57). The amount of mPPhen2P observed in the sample SMP21 was approximately equal to that observed in the comparative sample REF20 (see FIG. 57 and FIG. 58). In the sample SMP21, Alq₃ used in the layer SCRX2 was observed. The amount of Alq₃ observed in the sample SMP21 was smaller than that observed in the comparative sample REF20.

When the layer SCRX1 is formed over the layer SCRX2 by a sputtering method, the layer SCRX2 is damaged. For example, in the sample SMP21, the observed amount of Alq₃ used in the layer SCRX2 was small due to a reverse sputtering phenomenon. It was confirmed that the layer SCRX2 formed over the layer 113X2 protects the layer 113X2 from the damage caused by sputtering.

### <<Fabrication Method of Sample SMP31>>

The sample SMP31 was fabricated by a method similar to the fabrication method of the sample SMP21. The fabrication method of the SMP31 is different from the fabrication method of the sample SMP21 in that the layer SCRX2 was formed to have a thickness of 30 nm in the second step. The sample SMP31 was evaluated by a method similar to that for the sample SMP21.

### <<Evaluation Results of Sample SMP31>>

In the sample SMP31, a sufficient amount of mPPhen2P used in the layer 113X2 was observed (see FIG. 57). The amount of mPPhen2P observed in the sample SMP31 was approximately equal to that observed in the comparative sample REF30 (see FIG. 57 and FIG. 58). In the sample SMP31, Alq₃ used in the layer SCRX2 was observed. The amount of Alq₃ observed in the sample SMP31 was smaller than that observed in the comparative sample REF30.

When the layer SCRX1 is formed over the layer SCRX2 by a sputtering method, the layer SCRX2 is damaged. For example, in the sample SMP31, the observed amount of Alq₃ used in the layer SCRX2 was small due to a reverse sputtering phenomenon. It was confirmed that the layer SCRX2 formed over the layer 113X2 protects the layer 113X2 from the damage caused by sputtering.

### <<Fabrication Method of Sample SMIP 1>>

The sample SMP11 was fabricated by a method similar to the fabrication method of the sample SMP21. The fabrication method of the SMP11 is different from the fabrication method of the sample SMP21 in that the layer SCRX2 was formed to have a thickness of 5 nm in the second step. The sample SMP11 was evaluated by a method similar to that for the sample SMP21.

### <<Evaluation Results of Sample SMP111>>

In the sample SMP11, mPPhen2P used in the layer 113X2 was observed (see FIG. 57). The amount of mPPhen2P observed in the sample SMP11 was smaller than that observed in the comparative sample REF10 (see FIG. 57 and FIG. 58). In the sample SMP11, Alq₃ used in the layer SCRX2 was slightly observed. The amount of Alq₃ observed in the sample SMP11 was clearly smaller than that observed in the comparative sample REF10.

When the layer SCRX1 is formed over the layer SCRX2 by a sputtering method, the layer SCRX2 is damaged. For example, in the sample SMP11, the observed amount of Alq₃ used in the layer SCRX2 was small due to a reverse sputtering phenomenon. Although the layer SCRX2 formed over the layer 113X2 has a function of protecting the layer 113X2 from the damage caused by sputtering, the thickness of 5 nm is presumably insufficient for the layer SCRX2 to have the above function.

### Reference Example

A structure of a fabricated comparative sample REF01 that is described in this reference example is shown in FIG. 56D and Table 5. To evaluate the comparative sample REF01, a comparative sample REF00 was fabricated. A structure of the comparative sample REF00 is shown in FIG. 56E and Table 5. The comparative sample REF00 is different from the comparative sample REF01 in that the layer SCRX1 is not formed.

TABLE 5

| | | | Comparative | Comparative |
|---|---|---|---|---|
| | | | sample | sample |
| | | | REF01 | REF00 |
| Layer | SCRX1 | IGZO | 50 nm | — |
| Layer | SCRX2 | Alq3 | — | — |
| Layer | 113X2 | mPPhen2P | 10 nm | 10 nm |

### <<Fabrication Method of Comparative Sample REF01>>

The comparative sample REF01 was fabricated by a method similar to the fabrication method of the sample SMP21. The fabrication method of the comparative sample REF01 is different from that of the sample SMP21 in that the layer SCRX2 is formed in the second step. The comparative sample REF01 was evaluated by a method similar to that for the sample SMP21.

### <<Evaluation Results of Comparative Sample REF01>>

In the comparative sample REF01, mPPhen2P used in the layer 113X2 was observed (see FIG. 59). The amount of mPPhen2P observed in the comparative sample REF01 was smaller than that observed in the comparative sample REF00. When the layer SCRX1 is formed over the layer SCRX2 by a sputtering method, the layer 113X2 is damaged. For example, in the comparative sample REF01, the observed amount of mPPhen2P used in the layer 113X2 was small due to a reverse sputtering phenomenon.

### Example 3

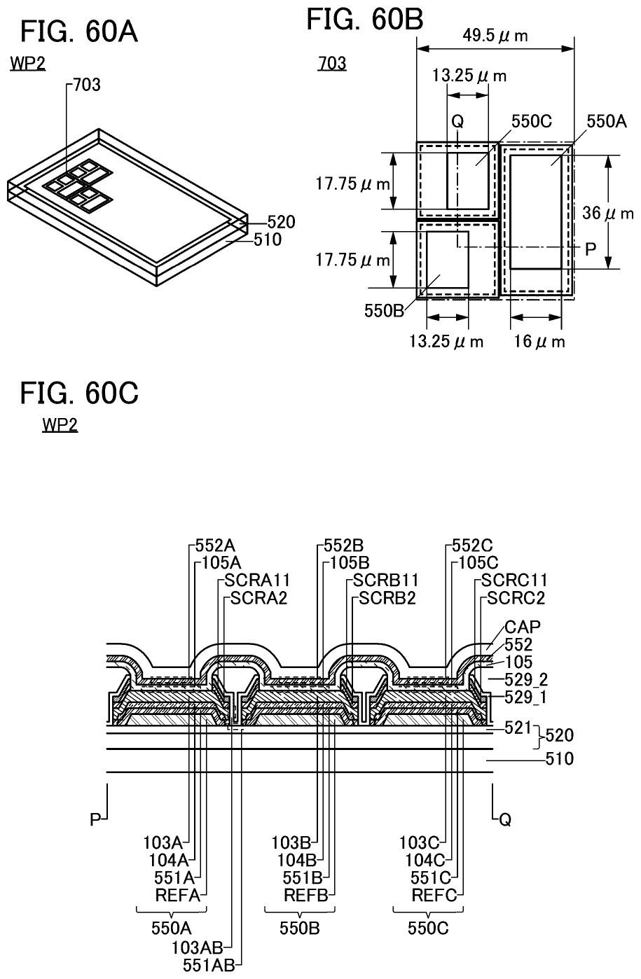

In this example, a workpiece WP2 fabricated by a manufacturing method of a display device of one embodiment of the present invention will be described with reference to FIGS. 60A to 60C, FIG. 61, FIG. 62, FIG. 63, FIG. 64, FIG. 65, FIG. 66, FIG. 67, FIG. 68, FIG. 69, FIG. 70, FIG. 71, FIGS. 72A and 72B, FIG. 73, FIG. 74, FIG. 75, FIG. 76, FIG. 77, and FIG. 78.

FIG. 60A is a perspective view illustrating a structure of the fabricated workpiece WP2 in this example, and FIG. 60B is a top view illustrating part of FIG. 60A. FIG. 60C is a cross-sectional view taken along a cutting line P-Q in FIG. 60B.

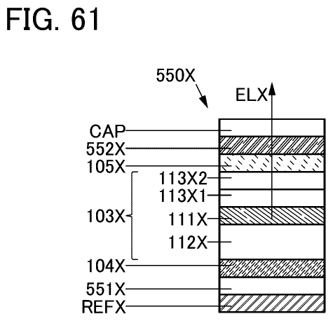

FIG. 61 is a view illustrating a structure of a light-emitting device fabricated in this example.

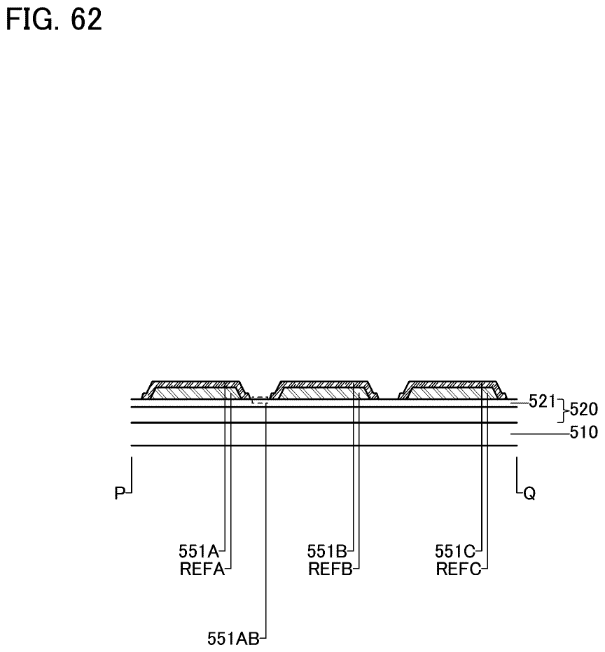

FIG. 62 illustrates a fabrication method of the workpiece WP2 fabricated in this example.

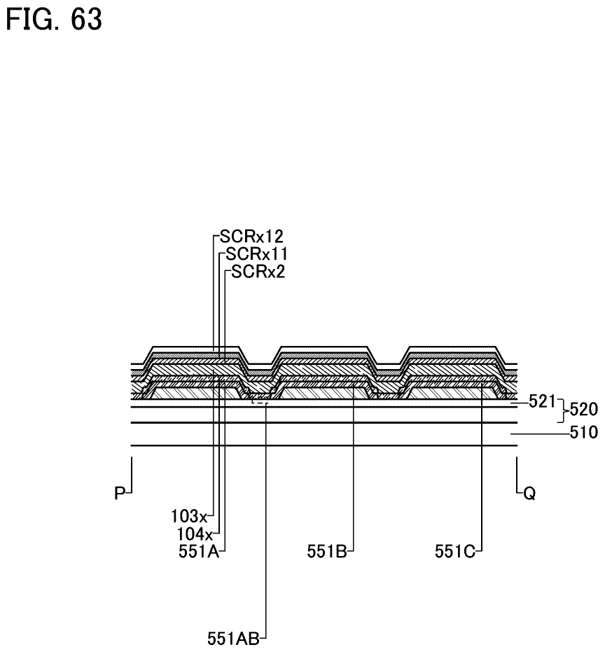

FIG. 63 illustrates a fabrication method of the workpiece WP2 fabricated in this example.

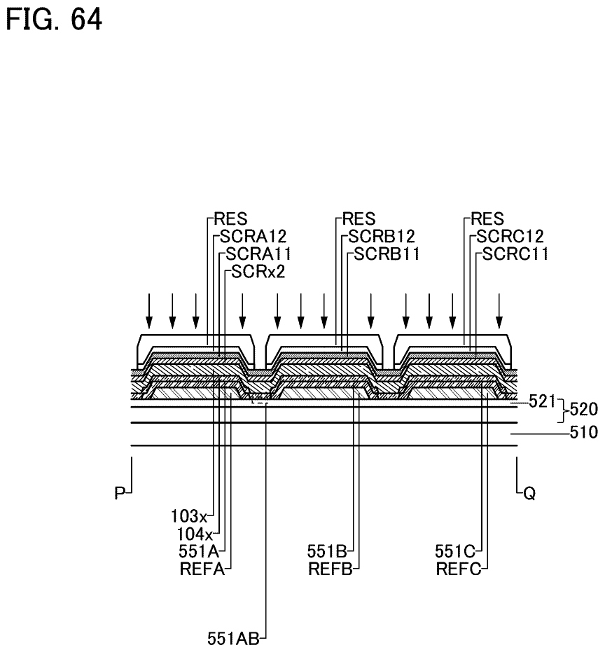

FIG. 64 illustrates a fabrication method of the workpiece WP2 fabricated in this example.

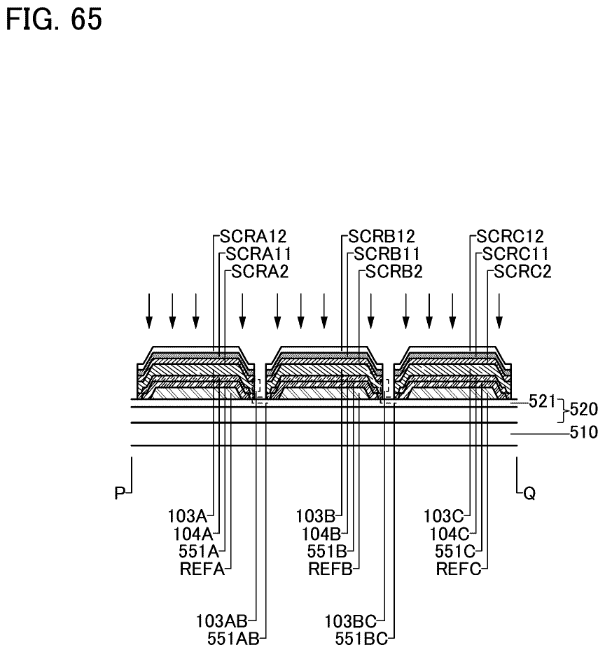

FIG. 65 illustrates a fabrication method of the workpiece WP2 fabricated in this example.

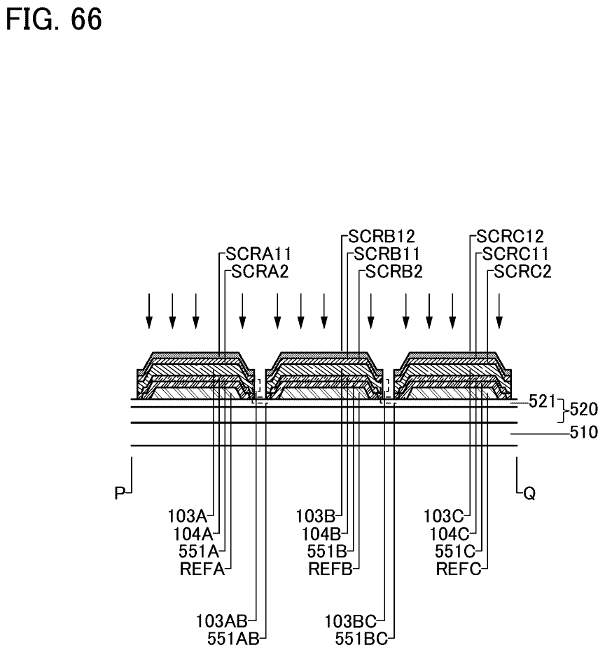

FIG. 66 illustrates a fabrication method of the workpiece WP2 fabricated in this example.

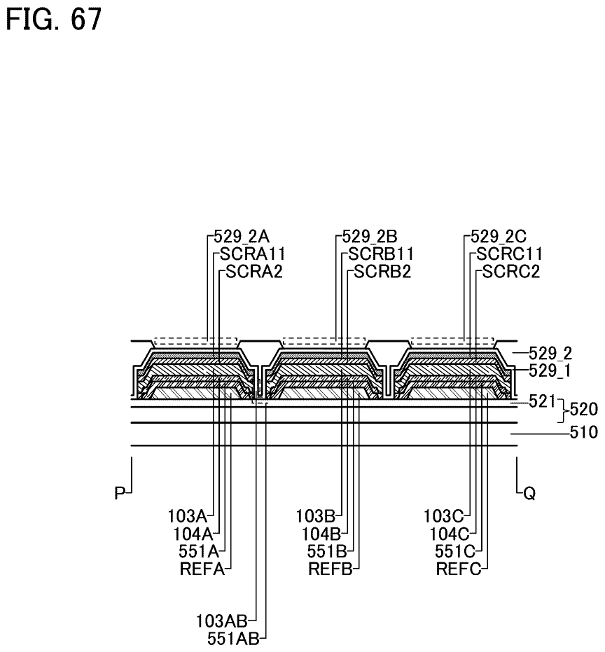

FIG. 67 illustrates a fabrication method of the workpiece WP2 fabricated in this example.

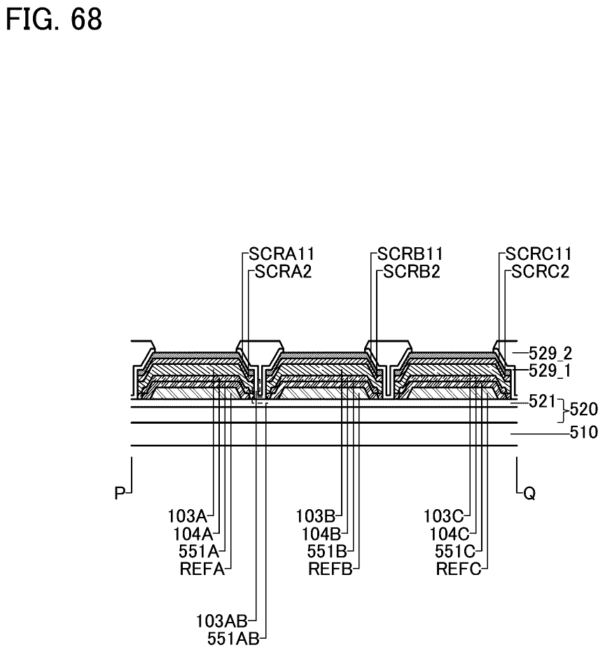

FIG. 68 illustrates a fabrication method of the workpiece WP2 fabricated in this example.

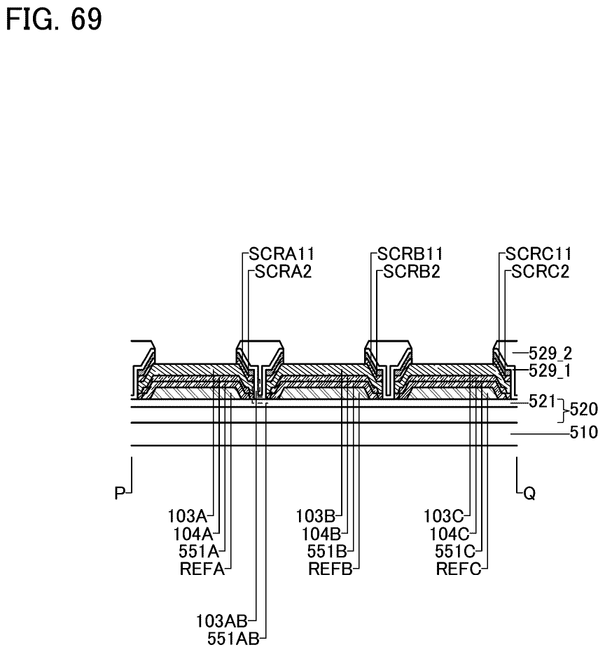

FIG. 69 illustrates a fabrication method of the workpiece WP2 fabricated in this example.

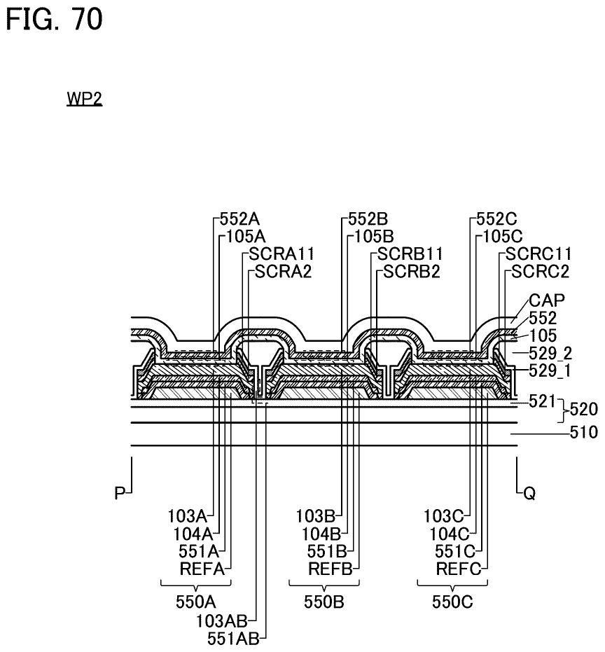

FIG. 70 illustrates a fabrication method of the workpiece WP2 fabricated in this example.

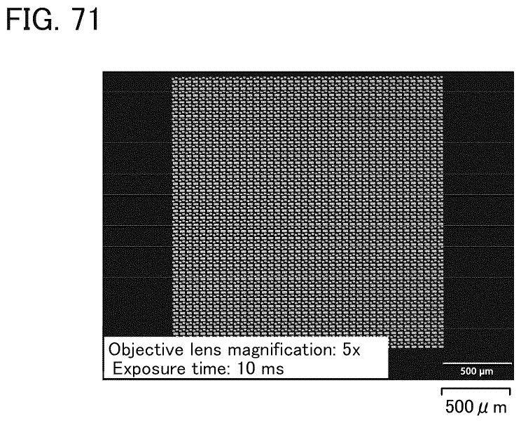

FIG. 71 is an optical micrograph showing a light-emitting state of the workpiece WP2 fabricated in this example.

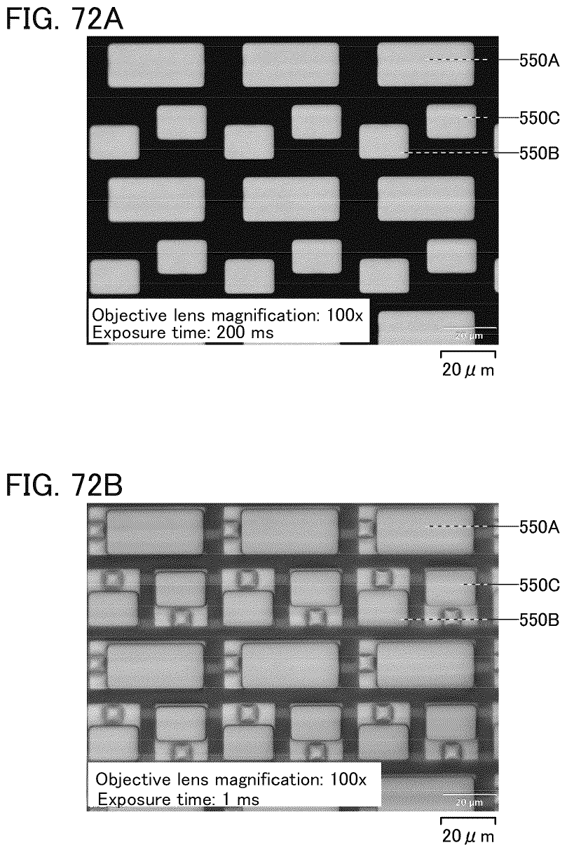

FIG. 72A is an optical micrograph showing a light-emitting state of the workpiece WP2 fabricated in this example, and FIG. 72B is an optical micrograph showing the external appearance of the workpiece.

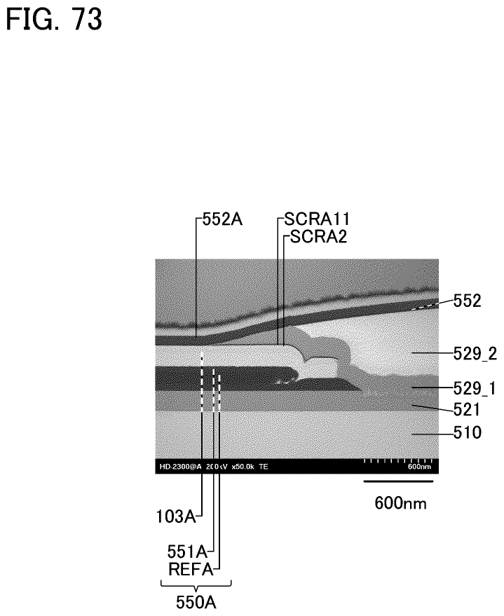

FIG. 73 is a scanning transmission electron microscope (STEM) image showing the structure of the workpiece fabricated in this example.

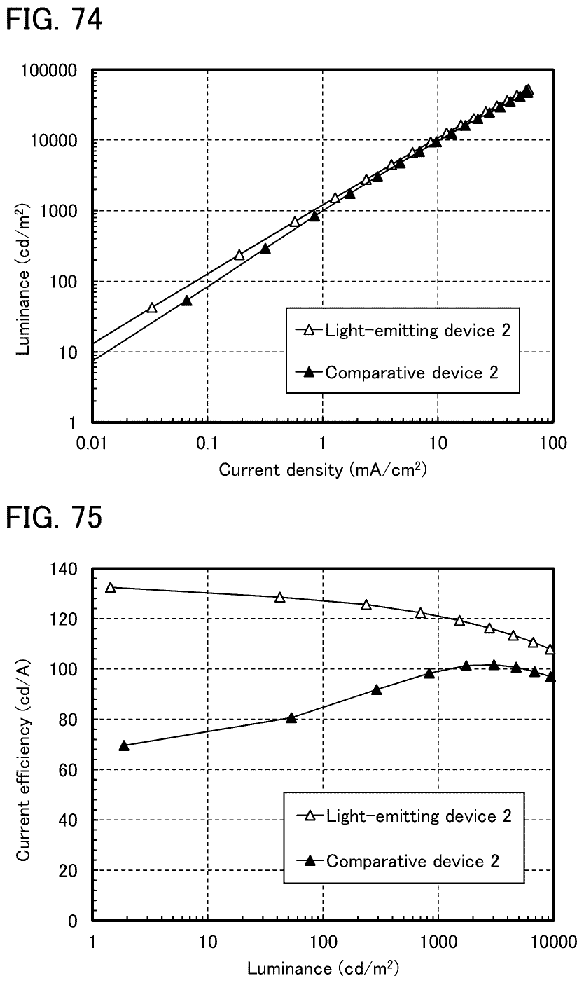

FIG. 74 shows current density-luminance characteristics of light-emitting devices fabricated in this example.

FIG. 75 shows luminance-current efficiency characteristics of the light-emitting devices fabricated in this example.

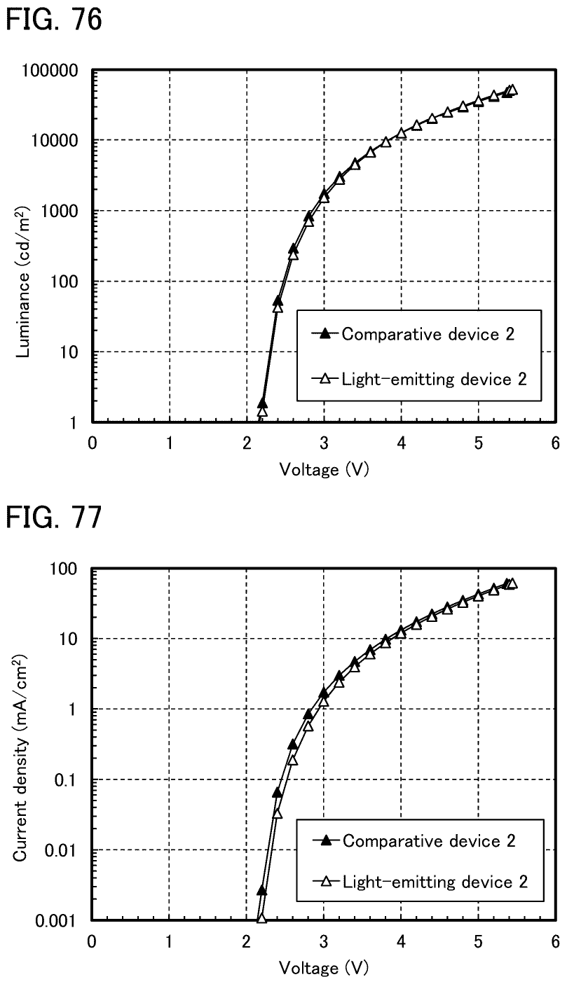

FIG. 76 shows voltage-luminance characteristics of the light-emitting devices fabricated in this example.

FIG. 77 shows voltage-current characteristics of the light-emitting devices fabricated in this example.

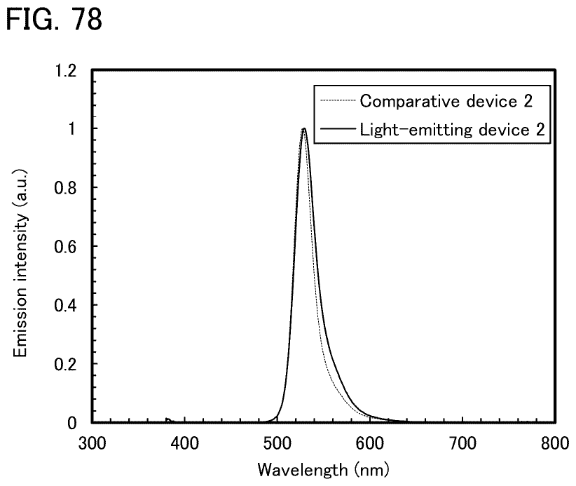

FIG. 78 shows emission spectra of the light-emitting devices fabricated in this example at the time of emitting light with a luminance of 1000 cd/m².

### <Workpiece WP2>

The fabricated workpiece WP2 described in this example includes the pixel set 703 (see FIG. 60A). The pixel set 703 includes the light-emitting device 550A, the light-emitting device 550B, and the light-emitting device 550C (see FIG. 60B). The workpiece WP2 includes the substrate 510, the functional layer 520, and the insulating layer 528, and the functional layer 520 includes the insulating layer 521 (see FIG. 60C).

The light-emitting device 550A has a rectangular front surface with a size of approximately 36 μm long and 16 μm width (see FIG. 60B). The light-emitting device 550A includes the reflective film REFA, the electrode 551A, the layer 104A, the unit 103A, the layer 105A, the electrode 552A, and the layer CAP (see FIG. 60C).

The light-emitting device 550B has a rectangular front surface with a size of approximately 17.75 μm length and 13.25 μm width (see FIG. 60B). The light-emitting device 550B includes the reflective film REFB, the electrode 551B, the layer 104B, the unit 103B, the layer 105B, the electrode 552B, and the layer CAP (see FIG. 60C). Note that the gap 551AB is located between the electrode 551B and the electrode 551A.

The light-emitting device 550C has a rectangular front surface with a size of approximately 17.75 μm length and 13.25 μm width (see FIG. 60B). The light-emitting device 550C includes the reflective film REFC, the electrode 551C, the layer 104C, the unit 103C, the layer 105C, the electrode 552C, and the layer CAP (see FIG. 60C). Note that the gap 551BC is located between the electrode 551C and the electrode 551B.

### <Light-Emitting Device 550A, Light-Emitting Device 550B, and Light-Emitting Device 550C>

Each of the fabricated light-emitting devices 550A, 550B, and 550C that are described in this example has a stacked structure the same as that of the light-emitting device 550X (see FIG. 61).

<<Structure of light-emitting device 2>>

The components of the light-emitting device 550X are assigned to specific materials and specific thicknesses to provide a light-emitting device 2. Each of the fabricated light-emitting devices 550A, 550B, and 550C that are described in this example has the structure of the light-emitting device 2. Thus, when driven with the same condition, the light-emitting devices 550A, 550B, and 550C exhibit the same characteristics.

Table 6 shows the structure of the light-emitting device 2. Structural formulae of materials used in the light-emitting devices described in this example are shown below. Note that in the tables in this example, subscript and superscript characters are written in ordinary size for convenience. For example, a subscript character in an abbreviation and a superscript character in a unit are written in ordinary size in the tables. The corresponding description in the specification gives an accurate reading of such notations in the tables.

TABLE 6

| | Reference | | Composition | |
|---|---|---|---|---|
| Component | numeral | Material | ratio | Thickness/nm |
| Layer | CAP | IGZO | | 70 |
| Electrode | 552X | Ag:Mg | 1:0.1 | 15 |
| Layer | 105X | LiF:Yb | 1:1 | 1 |
| Layer | 113X2 | mPPhen2P | | 10 |
| Layer | 113X1 | 2mPCCzPDBq | | 10 |
| Layer | 111X | 8mpTP-4mDBtPBfpm:βNCCP:Ir(5mppy-d3)2(mbfpypy-d3) | 0.6:0.4:0.1 | 42.4 |
| Layer | 112X | PCBBiF | | 98 |
| Layer | 104X | PCBBiF:OCHD-003 | 1:0.03 | 11.4 |
| Electrode | 551X | ITSO | | 50 |
| Reflective film | REFX | APC | | 100 |

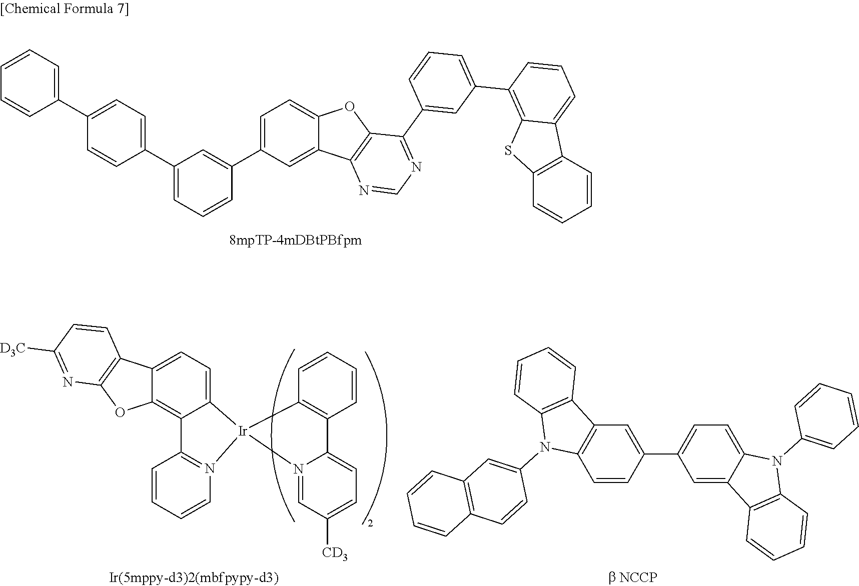

In this example, the light-emitting devices are fabricated using the following materials: an alloy containing silver (Ag), palladium (Pd), and copper (Cu) (abbreviation: APC), indium-tin oxide containing silicon or silicon oxide (abbreviation: ITSO), an electron-accepting material (abbreviation: OCHD-003), 8-(1,1′: 4′,1″-terphenyl-3-yl)-4-[3-(dibenzothiophen-4-yl)phenyl]-[1]benzo[3,2-d]pyrimidine (abbreviation: 8mpTP-4mDBtPBfpm), 9-(2-naphthyl)-9′-phenyl-9H,9′H-3,3′-bicarbazole (abbreviation: #6NCCP), [2-d₃-methyl-8-(2-pyridinyl-AN)benzofuro[2,3-b]pyridine-κC]bis[2-(5-d₃-methyl-2-pyridinyl-κN2)phenyl-κC]iridium(III) (abbreviation: Ir(5mppy-d₃)₂(mbfpypy-d3)), 2-{3-[3-(N-phenyl-9H-carbazol-3-yl)-9H-carbazol-9-yl]phenyl}dibenzo[f,h]quinoxaline (abbreviation: 2mPCCzPDBq), 2,2′-(1,3-phenylene)bis(9-phenyl-1,10-phenanthroline) (abbreviation: mPPhen2P), lithium fluoride (LiF), ytterbium (Yb), silver (Ag), magnesium (Mg), and indium-gallium-tin oxide (abbreviation: IGZO).

### <<Fabrication Method of Light-Emitting Device 2>>

The light-emitting device 2 described in this example was fabricated using a method including the following steps.

### [First Step]

In a first step, the reflective films REFA, REFB, and REFC were formed. Specifically, a film was formed by a sputtering method using APC as a target and then processed into a predetermined shape by an etching method. Note that each of the reflective films REFA, REFB, and REFC contains APC and has a thickness of 100 nm.

### [Second Step]

In a second step, the electrodes 551A, 551B, and 551C were formed over the reflective films REFA, REFB, and REFC, respectively. Specifically, a film was formed by a sputtering method using ITSO as a target and then processed into a predetermined shape by an etching method. Note that each of the electrodes 551A, 551B, and 551C contain ITSO and have a thickness of 50 nm (see FIG. 62).

### [Third Step]

In a third step, a film 104x was formed over the electrodes 551A, 551B, and 551C. Specifically, materials of the film 104x were co-deposited by a resistance-heating method. The film 104x contains PCBBiF and OCHD-003 at 1:0.03 (PCBBiF: OCHD-003) in a weight ratio and has a thickness of 11.4 nm. Note that OCHD-003 contains fluorine, and has a molecular weight of 672.

### [Fourth Step]

In a fourth step, a film 112x was formed over the film 104x. Specifically, a material of the film 112x was deposited by a resistance-heating method. The film 112x contains PCBBiF and has a thickness of 98 nm.

### [Fifth Step]

In a fifth step, a film 111x was formed over the film 112x. Specifically, materials of the film 111x were co-deposited by a resistance-heating method. The film 111x contains 8mpTP-4mDBtPBfpm, βNCCP, and Ir(5mppy-d₃)₂(mbfpypy-d3) at 0.6:0.4:0.1 (8mpTP-4mDBtPBfpm: βNCCP: Ir(5mppy-d₃)₂(mbfpypy-d₃)) in a weight ratio and has a thickness of 42.4 nm.

### [Sixth Step]

In a sixth step, a film 113x1 was formed over the film 111x. Specifically, a material of the film 113x1 was deposited by a resistance-heating method. The film 113x1 contains 2mPCCzPDBq and has a thickness of 10 nm.

### [Seventh Step]

In a seventh step, a film 113x2 was formed over the film 113x1. Specifically, a material of the film 113x2 was deposited by a resistance-heating method. The film 113x2 contains mPPhen2P and has a thickness of 100 nm.

### [Eighth Step: Step 8-1]

In an eighth step (Step 8-1), a film SCRx2 was formed over the film 113x2. Specifically, a material of the film SCRx2 was deposited by a resistance-heating method. The film SCRx2 contains Alq₃ and has a thickness of 10 nm.

### [Eighth Step: Step 8-2]

In the eighth step (Step 8-2), a stacked-layer film was formed over the film SCRx2 (see FIG. 63). Specifically, a film SCRx11 was formed by a sputtering method and a film SCRx12 was formed by a plasma CVD method. The film SCRx11 contains IGZO and has a thickness of 10 nm. The film SCRx12 contains silicon and nitrogen and has a thickness of 200 nm. The process temperature is controlled to 80° C., whereby the impact on materials used for the films 104x, 112x, 111x, 113x1, or 113x2 and the degradation due to heat can be reduced, for example.

### [Eighth Step: Step 8-3]

In the eighth step (Step 8-3), the layers SCRA11, SCRA12, SCRB11, SCRB12, SCRC11, and SCRC12 were formed over the film SCRx2 (see FIG. 64).

The resist RES was formed over the film SCRx12, and an unnecessary portion of the film SCRx12 was removed by an etching method using the resist RES, so that the layers SCRA12, SCRB12, and SCRC12 overlapping with the electrodes 551A, 551B, and 551C, respectively, were formed. A gas containing hexafluoride (SF₆) and oxygen was used as an etching gas.

Next, the resist RES was removed with use of tetramethyl ammonium hydroxide (TMAH), and then an unnecessary portion of the film SCRx2 was removed by an etching method using the layers SCRA12, SCRB12, and SCRC12, so that the layers SCRA11, SCRB11, and SCRC11 were formed. Note that a solution containing phosphoric acid was used as an etchant.

### [Eighth Step: Step 8-4]

In the eighth step (Step 8-4), the layer SCRA2, the unit 103A, and the layer 104A were formed over the electrode 551A. In addition, the layer SCRB2, the unit 103B, and the layer 104B were formed over the electrode 551B. The layer SCRC2, the unit 103C, and the layer 104C were formed over the electrode 551C (see FIG. 65). Furthermore, the gaps 103AB and 103BC were formed.

Specifically, unnecessary portions of a film 103x and the film 104x were processed by an etching method using the layers SCRA12, SCRB12, and SCRC12, so that portions overlapping with the electrodes 551A, 551B, and 551C were left. Each of the layers SCRA12, SCRB12, and SCRC12 serves as a hard mask. Note that unnecessary portions of the films 103x and 104x were removed using an oxygen-containing gas as an etching gas.

### [Ninth Step: Step 9-1]

In a ninth step (Step 9-1), the layers SCRA12, SCRB12, and SCRC12 were removed by an etching method (see FIG. 66). Note that each of the layers SCRA11, SCRB11, and SCRC11 serves as an etching stopper. Specifically, the layers SCRA12, SCRB12, and SCRC12 were removed by a dry etching method. A gas containing hexafluoride (SF₆) and oxygen was used as an etching gas.

### [Ninth Step: Step 9-2]

In the ninth step (Step 9-2), the layer 529_1 was formed to be in contact with the insulating layer 521 in the gap 551AB and cover the units 103A, 103B, and 103C. Specifically, a material of the layer 529_1 was deposited by a plasma CVD method. Note that the layer 529_1 contains silicon and nitrogen and has a thickness of 200 nm. The process temperature is controlled to 80° C., whereby the impact on materials used for the units 103A, 103B, and 103C and the degradation due to heat can be reduced, for example.

### [Tenth Step]

In a tenth step, the layer 529_2 was formed to fill the gaps 551AB and 103AB and have the opening portions 529_2A, the opening portion 529_2B, and an opening portion 529_2C overlapping with the electrodes 551A, 551B, and 551C, respectively (see FIG. 67).

### [Eleventh Step: Step 11-1]

In an eleventh step (Step 11-1), the layers 529_1 in portions overlapping with the opening portions 529_2A, 529_2B, and 529_2C were removed by a dry etching method using the layer 529_2 (see FIG. 68). A gas containing hexafluoride (SF₆) and oxygen was used as an etching gas.

### [Eleventh Step: Step 11-2]

In the eleventh step (Step 11-2), the layers SCRA11 and SCRA2 each in a portion overlapping with the opening portion 529_2A, the layers SCRB11 and SCRB2 each in a portion overlapping with the opening portion 529_2B, and the layers SCRC11 and SCRC2 each in a portion overlapping with the opening portion 529_2C were removed by an etching method using the layer 529_2 (see FIG. 69).

### [Twelfth Step]

In a twelfth step, the layer 105 was formed over the units 103A, 103B, and 103C. Specifically, materials of the layer 105 were co-deposited by a resistance-heating method. The layer 105 contains LiF and Yb at 1:1 in a weight ratio and has a thickness of 1 nm.

### [Thirteenth Step]

In a thirteenth step, the conductive film 552 was formed over the layer 105 (see FIG. 70). Specifically, materials of the conductive film 552 were co-deposited by a resistance-heating method. The conductive film 552 contains Ag and Mg at 1:0.1 in a weight ratio and has a thickness of 15 nm.

### [Fourteenth Step]

In a fourteenth step, the layer CAP was formed over the conductive film 552. Specifically, the layer CAP was formed by a sputtering method using IGZO as a target. The layer CAP contains IGZO and has a thickness of 70 nm.

A cross-sectional structure of the fabricated light-emitting device 550A was observed with a scanning electron microscope. FIG. 73 shows the observation result. The observed structure of the light-emitting device 550A was favorable. For example, a phenomenon where the unit 103A was thinned in the opening portion was not observed. The end portion of the layer 529_1 in the opening portion was able to be tapered. With a tapered shape, a phenomenon in which a cut or a split is generated in the conductive film 552 was prevented, and the conductive film 552 was able to be a continuous film with a gentle slope.

### <<Operating Characteristics of Light-Emitting Device 2>>

When supplied with a voltage of 3.0 V, the light-emitting device 2 emitted the light ELX (see FIG. 61). FIG. 71 shows a light-emitting state of a plurality of light-emitting device formed in the workpiece, and FIGS. 72A and 72B show the light-emitting state and the external appearance of the workpiece. Operating characteristics of the light-emitting device 2 were measured at room temperature (see FIG. 74 to FIG. 78). Note that luminance, CIE chromaticity, and emission spectra were measured with a spectroradiometer (SR-UL1R produced by TOPCON TECHNOHOUSE CORPORATION).

Table 7 shows main initial characteristics of the fabricated light-emitting device emitting light at a current density of approximately 10 mA/cm². Table 7 also shows the characteristics of another light-emitting device having a structure described later.

TABLE 7

| | | | Current | | | Current |
|---|---|---|---|---|---|---|
| | Voltage | Current | density | Chromaticity | Chromaticity | efficiency |
| | (V) | (mA) | (mA/cm2) | x | y | (cd/A) |
| Light-emitting device 2 | 3.9 | 0.16 | 10.0 | 0.24 | 0.72 | 106.7 |
| Comparative device 2 | 3.8 | 0.17 | 10.0 | 0.21 | 0.74 | 96.7 |

The light-emitting device 2 was found to exhibit favorable characteristics. For example, the voltage and current values of the light-emitting device 2 were equal to those of a comparative device 2. Accordingly, it was found that the light-emitting device fabricated by a manufacturing method of a display device of one embodiment of the present invention exhibits favorable characteristics comparable to those of a light-emitting device treated in an apparatus in which the pressure was reduced continuously through the fabrication process.

### <Comparative Device 2>

The comparative device 2 described in this example is different from the light-emitting device 2 in that the layer 104A and the unit 103A are each continuously provided without a gap between the comparative device 2 and another comparative device adjacent to the comparative device 2, that is, the layer 104A and the unit 103A are directly connected to the layer 104B and the unit 103B, respectively, of the adjacent device.

The fabrication method of the comparative device 2 is different from that of the light-emitting device 2 in that the process proceeds to the twelfth step after the seventh step of the fabrication method of the light-emitting device 2. In other words, the comparative device 2 was treated in an apparatus in which the pressure was reduced continuously through the fabrication process.

### <<Operating Characteristics of Comparative Device 2>>

When supplied with electric power, the comparative device 2 emitted light. Operating characteristics of the comparative device 2 were measured at room temperature (see FIGS. 74 to 78). Note that luminance, CIE chromaticity, and emission spectra were measured with a spectroradiometer (SR-UL1R manufactured by TOPCON TECHNOHOUSE CORPORATION).

Table 7 shows the main initial characteristics of the fabricated comparative device 2 emitting light at a current density of approximately 10 mA/cm²

### Example 4

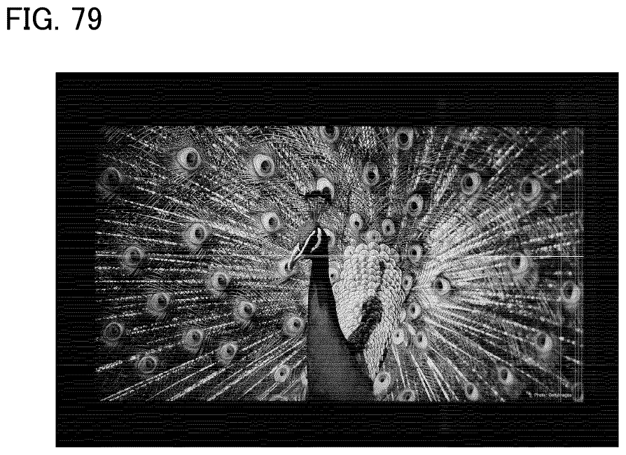

In this example, a display device of one embodiment of the present invention will be described with reference to FIG. 79.

FIG. 79 is an optical photograph showing a state of displaying an image by the display device fabricated in this example.

Table 8 shows specifications of the fabricated display device that is described in this example. Note that a pixel circuit is provided with OS transistors including an oxide semiconductor.

TABLE 8

| | Specifications |
|---|---|
| Screen size | 8.3 inches |
| Driving method | Active Matrix |
| Resolution | 7680 × RGB × 4320 |
| Pixel pitch | 24 μm × 24 μm |
| Pixel density | 1058 ppi |
| Aperture ratio | 22% |
| Pixel Arrangement | RGB stripe |
| Coloring method | SBS (by photolithography) |
| Emission type | Top-emission type |
| Gate driver | Integrated |

The photograph of FIG. 79 shows a display device that is displaying an image. The display device has a high resolution of 1058 ppi and was able to display a clear image. A crosstalk phenomenon was prevented from being generated between adjacent pixels, and a wide color gamut was able to be expressed. Furthermore, a wide viewing angle was able to be achieved. A difference between the chromaticity observed in the front of the display device and the chromaticity observed at a position in an oblique direction of the display device was able to be small.

This application is based on Japanese Patent Application Serial No. 2022-208115 filed with Japan Patent Office on Dec. 26, 2022, the entire contents of which are hereby incorporated by reference.

What is claimed is:

1. A method for manufacturing a display device, comprising the steps of:
forming a first electrode, a second electrode, and a first gap between the first electrode and the second electrode over an insulating film;
forming a first film over the first electrode and the second electrode;
forming a second film over the first film;
forming a third film over the second film by a CVD method;
removing a part of the third film over the second electrode by a first etching method to form a first layer overlapping with the first electrode;
removing a part of the second film and a part of the first film each over the second electrode by a second etching method using the first layer to form a second layer and a first unit each overlapping with the first electrode;
forming a fourth film over the first layer and the second electrode;
forming a fifth film over the fourth film;
forming a sixth film over the fifth film;
removing a part of the sixth film over the first layer by a third etching method to form a third layer overlapping with the second electrode;
removing a part of the fifth film and a part of the fourth film each over the first layer and the first gap by a fourth etching method using the third layer to form a fourth layer and a second unit overlapping with the second electrode and a second gap overlapping with the first gap;
forming a fifth layer configured to be in contact with the insulating film in the first gap and cover the first unit and the second unit;
forming a sixth layer configured to fill the first gap and the second gap and have a first opening portion overlapping with the first electrode and a second opening portion overlapping with the second electrode;
removing the fifth layer and the first layer each in a portion overlapping with the first opening portion and removing the fifth layer and the third layer each in a portion overlapping with the second opening portion, by a fifth etching method using the sixth layer;
removing the second layer in a portion overlapping with the first opening portion and removing the fourth layer in a portion overlapping with the second opening portion, by a sixth etching method using the sixth layer;
forming a seventh layer over the first unit and the second unit; and
forming a conductive film over the seventh layer.

2. The method for manufacturing a display device according to claim 1, wherein the step of forming the first film, the step of forming the second film, and the step of forming the third film are performed in treatment chambers connected to each other with a transfer chamber in which a pressure is reduced.

3. The method for manufacturing a display device according to claim 1, wherein the fifth layer is formed by a second CVD method to be in contact with the insulating film in the first gap and cover the first unit and the second unit.

4. The method for manufacturing a display device according to claim 1,
wherein the fifth etching method is a wet etching method,
wherein the fifth layer and the first layer each in a portion overlapping with the first opening portion and the fifth layer and the third layer each in a portion overlapping with the second opening portion are removed by the wet etching method using the sixth layer, and
wherein the sixth layer is made to have fluidity to be in contact with the second layer after performing the wet etching method.

5. The method for manufacturing a display device according to claim 1,
wherein the first unit comprises a first light-emitting material, and
wherein the second unit comprises a second light-emitting material.

6. A display device comprising:
a first light-emitting device;
a second light-emitting device;
a fifth layer;
a first layer; and
a second layer,
wherein the first light-emitting device comprises a first electrode, a fourth electrode, and a first unit,
wherein the first unit is between the first electrode and the fourth electrode,
wherein the first unit comprises a first light-emitting material,
wherein the second light-emitting device comprises a second electrode, a fifth electrode, and a second unit,
wherein the second electrode is adjacent to the first electrode,
wherein the second electrode and the first electrode are configured to have a first gap therebetween,
wherein the second unit is between the second electrode and the fifth electrode,
wherein the second unit comprises a second light-emitting material,
wherein the second unit and the first unit are configured to have a second gap therebetween,
wherein the second gap overlaps with the first gap,
wherein the fifth layer overlaps with the first gap,
wherein the fifth layer comprises an opening portion overlapping with the first electrode,
wherein the first layer is between the fifth layer and the first unit,
wherein the second layer is between the first layer and the first unit,
wherein distribution of boron ranging from a central plane of the fifth layer to a central plane of the first layer comprises a first concentration profile,
wherein distribution of boron ranging from the central plane of the first layer to a central plane of the second layer comprises a second concentration profile, and
wherein the second concentration profile has a peak lower than a peak in the first concentration profile.

7. The display device according to claim 6, further comprising:
a sixth layer,
wherein the sixth layer is configured to fill the first gap and the second gap,
wherein the sixth layer comprises a first opening portion and a second opening portion,
wherein the first opening portion overlaps with the first electrode,
wherein the second opening portion overlaps with the second electrode, and
wherein the sixth layer is in contact with the second layer.

8. A display module comprising:
the display device according to claim 6; and
at least one of a connector and an integrated circuit.

9. An electronic device comprising:
the display device according to claim 6; and
at least one of a battery, a camera, a speaker, and a microphone.
